(19) United States
(12) Patent Application Publication
(10) Pub. No.: US 2026/0217927 A1
(43) Pub. Date: Jul. 30, 2026

(54) POLYIMIDE FILM, LAMINATED BODY, FLEXIBLE ELECTRONIC DEVICE, AND METHOD FOR PRODUCING FLEXIBLE ELECTRONIC DEVICE

(71) Applicant: TOYOBO CO., LTD., Osaka-shi, Osaka (JP)

(72) Inventors: Makoto NAKAMURA, Otsu (JP); Hiroyuki WAKUI, Otsu (JP)

(73) Assignee: TOYOBO CO., LTD., Osaka-shi, Osaka (JP)

(21) Appl. No.: 19/142,318

(22) PCT Filed: Dec. 21, 2023
(86) PCT No.: PCT/JP2023/045964

§ 371 Date: Jun. 23, 2025

(30) Foreign Application Priority Data
Dec. 23, 2022 (JP) 2022-206688

(51) Int. Cl. C08J 5/18; H05K 1/03; H05K 3/00

(52) U.S. Cl. CPC C08J 5/18; H05K 1/0373; H05K 1/0393; H05K 3/007; C08J 2333/24; H05K 2201/0154

(57) ABSTRACT

The present invention relates to a polyimide film, which includes a polyimide obtained through imidization of a polyamic acid that is a copolymerization reaction product of at least a carboxylic acid, a diamine, and a silsesquioxane derivative, and has a coefficient of static friction of 2.0 or less. In addition to this, the present invention relates to a laminated body including the polyimide film and an inorganic substrate. The present invention also relates to a method for producing a flexible electronic device, which includes a step of forming an electronic device on a polyimide film surface of the laminated body and a step of peeling off the inorganic substrate. The present invention also relates to a flexible electronic device including the polyimide film and an electronic device formed on the polyimide film.

### TECHNICAL FIELD

The present invention relates to a polyimide film, a laminated body, a flexible electronic device, and a method for producing a flexible electronic device.

### BACKGROUND ART

Polyimide films exhibit excellent heat resistance and favorable mechanical properties and are widely used as flexible materials in the electrical and electronic fields. However, general polyimide films are colored yellowish brown, and cannot be applied to the portions required to transmit light, such as display devices.

Meanwhile, display devices are becoming thinner and lighter, and further are required to be flexible. For this reason, it is attempted to change the substrate materials from glass substrates to flexible polymer film substrates. However, colored polyimide films cannot be used as a substrate material for liquid crystal displays, which perform displaying by turning light transmission on and off, and can be only applied to a few portions, such as peripheral circuits such as TAB and COF on which driving circuits of display devices are mounted and the back side of reflective display type or self-luminous display devices.

In view of this, development of colorless and transparent polyimide films has been conducted. In a case where polyimide films are used as flexible electronic circuit boards, in addition to colorless transparency, a low coefficient of linear thermal expansion (CTE), and a low retardation (Rth), the polyimide films need to maintain resistance to bending and have mechanical strength under high temperature conditions during circuit formation, and thus are required to have a high elastic modulus, a mechanical strength, and a high glass transition temperature (Tg).

As representative examples, it is attempted to develop colorless and transparent polyimide films using fluorinated polyimide resins, semi-alicyclic or fully alicyclic polyimide resins, and the like (Patent Documents 1 to 3). These films are less colored and are transparent, but do not have as high mechanical strength as colored polyimide films, and do not necessarily maintain the colorlessness and transparency since thermal decomposition or oxidation reactions take place in a case where these films are assumed to be used in industrial production and for applications where these films are exposed to high temperatures.

From this point of view, a method has been proposed in which heat treatment is performed while a gas having a specified oxygen content is sprayed (Patent Document 4), but the manufacturing cost is high in an environment where the oxygen concentration is less than 18%, and industrial production is extremely difficult.

As a means for further improving the properties of organic materials, there is the so-called organic-inorganic hybridization technology in which organic materials are combined with inorganic materials to impart high heat resistance, chemical resistance, high surface hardness and the like that are properties of the inorganic materials. For example, it is known that CTE, Rth, and Tg can be improved as well as transparency is maintained by combining transparent polyimide with silica nanoparticles. However, there is a problem that the film becomes brittle and the mechanical strength decreases as the amount of silica nanoparticles mixed increases.

Meanwhile, silsesquioxanes having RSiO_{3/21.5} as an elementary unit are being investigated for practical use since an organic-inorganic hybrid cured material can be easily afforded by introducing a substituent that can react with an organic material to R in RSiO_{3/21.5} (for example, Patent Document 5). It is attempted to improve heat resistance and processability by combining a silsesquioxane, which exhibit high heat resistance and flexibility, with polyimide. It is known that the thermal decomposition temperature is improved by charge transfer interaction between the imide moiety of polyimide and silsesquioxane (Non-Patent Document 1).

### PRIOR ART DOCUMENTS

### Patent Documents

Patent Document 1: JP-A-11-106508
Patent Document 2: JP-A-2002-146021
Patent Document 3: JP-A-2002-348374
Patent Document 4: WO 2008/146637
Patent Document 5: JP-B-3653976
Patent Document 6: JP-A-2004-331647
Patent Document 7: JP-A-2006-265243
Patent Document 8: JP-A-2007-302635
Patent Document 9: WO 2003/024870

### Non-Patent Documents

Non-Patent Document 1: Thermochimica Acta 2004, 417, pp. 133-142
Non-Patent Document 2: European Polymer Journal 2011, 47 (6), pp. 1328-1337
Non-Patent Document 3: Chemistry Letters, 2014, Vol. 43, No. 10, pp. 1532-1534
Non-Patent Document 4: Chemistry Letters, 2018, Vol. 47, No. 12, pp. 1530-1533

### SUMMARY OF THE INVENTION

### Problems to be Solved by the Invention

However, the flexible silsesquioxane structure diminishes the rigidity of polyimide and polyimide combined with a silsesquioxane usually has the problem of having a relatively low elastic modulus and a low Tg (Non-Patent Document 2).

As described above, it is extremely difficult to produce a colorless and transparent polyimide film that has a low coefficient of linear thermal expansion, high heat resistance, and high mechanical strength. In the case of semi-alicyclic or fully alicyclic polyimides, when the monomer component having an alicyclic structure is increased, the colorless transparency is improved but the mechanical strength decreases by diminished intermolecular interaction, and it is difficult to produce the polyimides as a film. Meanwhile, when an aromatic monomer is introduced, the toughness increases by the increased intermolecular interaction and the mechanical properties of the film are improved, but coloring is likely to occur and the colorless transparency decreases. By introducing a filler (inorganic component) having a refractive index close to that of the resin component, heat resistance and colorless transparency are improved, the coefficient of linear thermal expansion is lowered, and processing suitability is improved, but the film becomes hard and brittle in terms of resin physical properties and the mechanical properties decrease.

Hence, practical properties such as heat resistance and mechanical properties and colorlessness (transparency or whiteness) are in trade-off relation, and particularly a method for producing polyimide films that have improved toughness while maintaining other main properties is desirable.

When these films are used industrially while maintaining the quality, one of the important practical properties is the slipperiness (easily slipping properties) of the film. As the easily slipping properties between the film support (for example, a roll) and the film or easily slipping properties between the films are secured, the operability in each step and handling properties are improved and further the generation of defects such as wrinkles and scratches on the film can be avoided.

As a technology for imparting easily slipping properties to polyimide films, for example, transparent polyimide films, there are a method in which a lubricant (fine particles), such as alumina and silica, having a volume average particle size in the range of 5 nm to 100 nm are added, and the like, but when the particle size is small, there is a problem that the amount of fine particles added, which is required to attain the required slipperiness, increases and an increase in the amount of fine particles added causes deterioration of optical properties (for example, haze) of the film. Examples of the index for evaluating easily slipping properties include the coefficient of static friction.

An object of the present invention is to provide a polyimide film having improved easily slipping properties. Another object of the present invention is to provide a laminated body obtained using a polyimide film, a flexible electronic device obtained using a polyimide film, and a method for producing a flexible electronic device.

### Means for Solving the Problems

As a result of intensive studies to solve the above problems, the present inventors have found out that the objects (that is, improvement of easily slipping properties) can be achieved by using a polyamic acid containing a silsesquioxane compound as a copolymerization component, and have thus completed the present invention.

In other words, the present invention includes the following.

[1] A polyimide film including a polyimide obtained through imidization of a polyamic acid that is a copolymerization reaction product of at least a carboxylic acid, a diamine, and a silsesquioxane derivative, in which a coefficient of static friction is 2.0 or less.

Here, the coefficient of static friction is the coefficient of static friction between one surface and the other surface of the two surfaces of the polyimide film.

[2] The polyimide film according to [1], in which the silsesquioxane derivative has two or more dicarboxylic anhydride groups.

[3] The polyimide film according to [1], in which the silsesquioxane derivative has two or more amino groups.

[4] The polyimide film according to [3], in which each of the amino groups has a linking group that links the amino group to Si bonded closest to the amino group among Si's that constitute the silsesquioxane derivative, and the linking groups each independently have a substituted or unsubstituted aromatic ring that is bonded to the amino group.

[5] The polyimide film according to any one of [1] to [4], in which the polyamic acid does not have a structural unit derived from 3,3′,4,4′-biphenyltetracarboxylic dianhydride.

[6] The polyimide film according to any one of [1] to [5], in which the silsesquioxane derivative has a double-decker structure, a cage structure, a random structure, a ladder structure, or a chair structure.

[7] The polyimide film according to any one of [1] to [6], in which the silsesquioxane derivative has a structure represented by the following general formula (hereinafter, sometimes referred to as “General Formula AA-D1”):

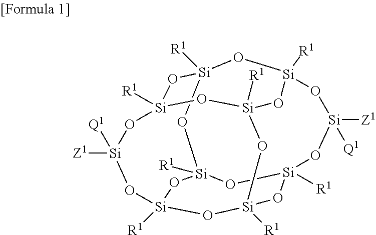

(where R¹'s each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
Q¹'s each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
Z¹'s are each independently a structure represented by General Formula (Z1-1),
X in General Formula (Z1-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these, and
X belonging to Z1 and Si adjacent to Z1 may be connected by a single bond or linked by a linking group).

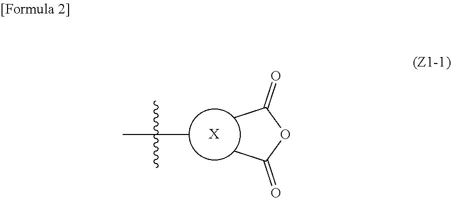

[8] The polyimide film according to [7], in which R¹'s each independently represent a methyl group, an ethyl group, an isobutyl group, an isooctyl group, a trifluoropropyl group, or a phenyl group.

[9] The polyimide film according to [7] or [8], in which R¹ represents a phenyl group.

[10] The polyimide film according to any one of [7] to [9], in which Q¹'s each independently represent a methyl group, an ethyl group, or a phenyl group.

[11] The polyimide film according to any one of [7] to [10], in which Q¹ represents a methyl group.

[12] The polyimide film according to any one of [7] to [11], in which X's in General Formula (Z1-1) are each independently a substituted or unsubstituted aromatic ring or an unsubstituted aliphatic ring having 4 to 10 carbon atoms.

[13] The polyimide film according to any one of [7] to [12], in which X belonging to Z¹ is connected to Si adjacent to Z¹ by a single bond.

[14] The polyimide film according to any one of [7] to [12], in which X belonging to Z¹ is linked to Si adjacent to Z¹ by a linking group.

[15] The polyimide film according to any one of [7] to [14], in which Z1 is any one of the following three structures.

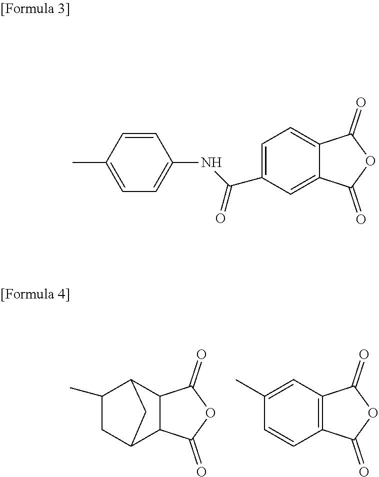

[16] The polyimide film according to any one of [1] to [6], in which the silsesquioxane derivative has a structure represented by the following general formula (hereinafter, sometimes referred to as “General Formula AA-D2”):

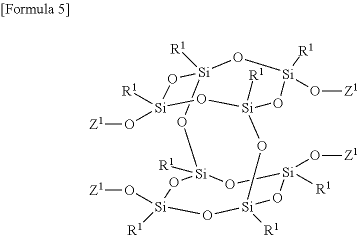

(where R¹'s each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
Z¹'s are independent of each other,
at least two of Z¹'s are structures represented by General Formula (Z1-1),
X in General Formula (Z1-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these, and
X belonging to Z¹ is linked to O adjacent to Z1 by a linking group,
in a case where Z1 other than the structure represented by General Formula (Z1-1) is present, Z1 other than the structure is H or a structure represented by General Formula (Z1-S), and
Q^{S1}'s in General Formula (Z1-S) each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms).

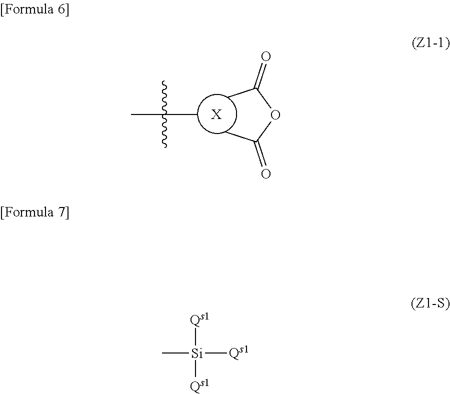

[17] The polyimide film according to [16], in which R¹'s each independently represent a methyl group, an ethyl group, an isobutyl group, an isooctyl group, a trifluoropropyl group, or a phenyl group.

[18] The polyimide film according to or [17], in which R¹ represents a phenyl group.

[19] The polyimide film according to any one of to [18], in which X's in General Formula (Z1-1) are each independently a substituted or unsubstituted aromatic ring.

[20] The polyimide film according to any one of to [19], in which the linking group is a carbonyl group.

[21] The polyimide film according to any one of to [20], in which Z1 is the following structure.

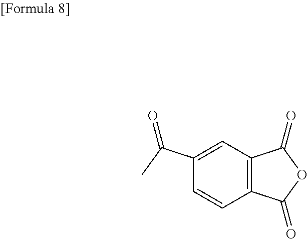

[22] The polyimide film according to any one of to [21], in which Q^{S1}'s in General Formula (Z1-S) each independently represent a methyl group, an ethyl group, or a phenyl group.

[23] The polyimide film according to any one of [1] to [6], in which the silsesquioxane derivative has a structure represented by the following general formula (hereinafter, sometimes referred to as “General Formula AA-C1”):

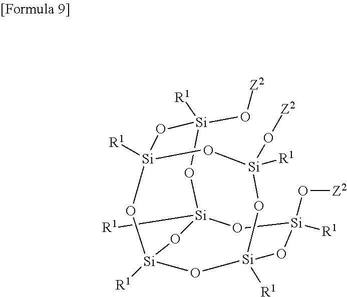

(where R¹'s each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
Z¹'s are independent of each other,
at least two of Z¹'s are structures represented by General Formula (Z1-1),
X in General Formula (Z1-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these, and
X belonging to Z¹ is linked to 0 adjacent to Z¹ by a linking group,
in a case where Z¹ other than the structure represented by General Formula (Z1-1) is present, Z¹ other than the structure is H or a structure represented by General Formula (Z1-S), and
Q^{S1}'s in General Formula (Z1-S) each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms).

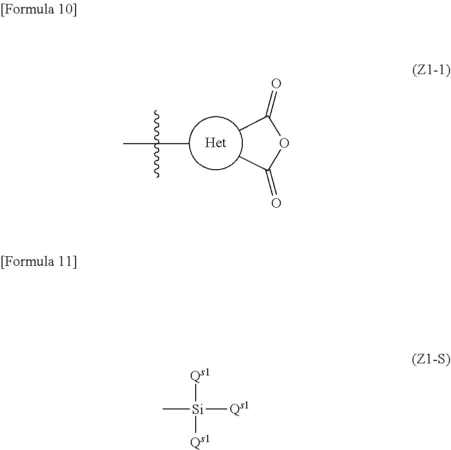

[24] The polyimide film according to [23], in which R¹'s each independently represent a methyl group, an ethyl group, an isobutyl group, an isooctyl group, a trifluoropropyl group, or a phenyl group.

[25] The polyimide film according to [23] or [24], in which R¹ represents a phenyl group.

[26] The polyimide film according to any one of [23] to [25], in which X's in General Formula (Z1-1) are each independently a substituted or unsubstituted aromatic ring.

[27] The polyimide film according to any one of [23] to [26], in which the linking group is a carbonyl group.

[28] The polyimide film according to any one of [23] to [27], in which Z¹ is the following structure.

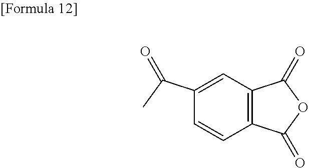

[29] The polyimide film according to any one of [23] to [28], in which Q^{S1}'s in General Formula (Z1-S) each independently represent a methyl group, an ethyl group, or a phenyl group.

[30] The polyimide film according to any one of [1] to [6], in which the silsesquioxane derivative has a structure represented by the following general formula (hereinafter, sometimes referred to as “General Formula AA-Q1”):

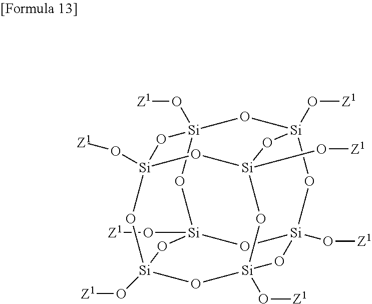

(where Z¹'s are independent of each other,
at least two of Z¹'s are structures represented by General Formula (Z1-1),
X in General Formula (Z1-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these, and
X belonging to Z¹ is linked to 0 adjacent to Z¹ by a linking group,
in a case where Z¹ other than the structure represented by General Formula (Z1-1) is present, Z¹ other than the structure is H or a structure represented by General Formula (Z1-S), and
Q^{S1}'s in General Formula (Z1-S) each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms).

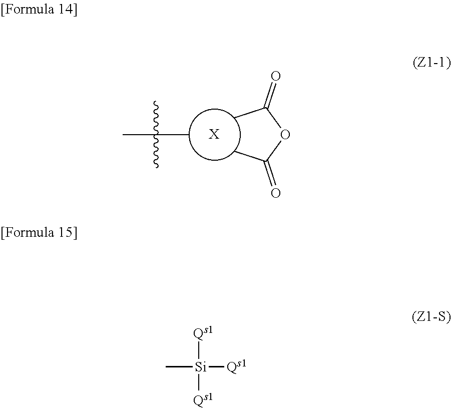

[31] The polyimide film according to [30], in which X's in General Formula (Z1-1) are each independently a substituted or unsubstituted aromatic ring.

[32] The polyimide film according to [30] or [31], in which Q^{S1}'s in General Formula (Z1-S) each independently represent a methyl group, an ethyl group, or a phenyl group.

[33] The polyimide film according to any one of [1] to [6], in which the silsesquioxane derivative has a structure represented by the following general formula (hereinafter, sometimes referred to as “General Formula AM-D1”)

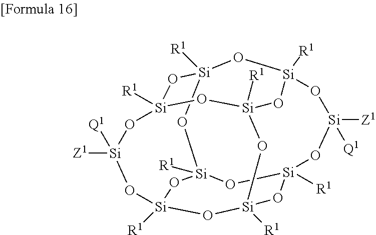

(where R¹'s each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
Q¹'s each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
Z²'s are each independently a structure represented by General Formula (Z2-1) or a structure represented by General Formula (Z2-2),
Y in General Formula (Z2-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these,
Y belonging to Z² and Si adjacent to Z² may be connected by a single bond or linked by a linking group, and
an amino group belonging to General Formula (Z2-2) is linked to Si adjacent to Z² by a linking group).

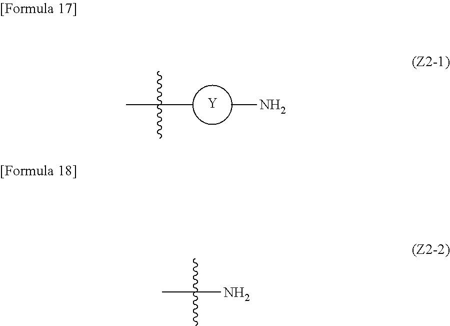

[34] The polyimide film according to [33], in which R¹'s each independently represent a methyl group, an ethyl group, an isobutyl group, an isooctyl group, a trifluoropropyl group, or a phenyl group.

[35] The polyimide film according to [33] or [34], in which R¹ represents a phenyl group.

[36] The polyimide film according to any one of [33] to [35], in which Q¹'s each independently represent a methyl group, an ethyl group, or a phenyl group.

[37] The polyimide film according to any one of [33] to [36], in which Q¹ represents a methyl group.

[38] The polyimide film according to any one of [33] to [37], in which Y's in General Formula (Z2-1) are each independently a substituted or unsubstituted aromatic ring.

[39] The polyimide film according to any one of [33] to [38], in which Y belonging to Z2 is connected to Si adjacent to Z² by a single bond.

[40] The polyimide film according to any one of [33] to [39], in which Y belonging to Z² is linked to Si adjacent to Z² by a linking group.

[41] The polyimide film according to any one of [33] to [40], in which Z² is either of the following two structures.

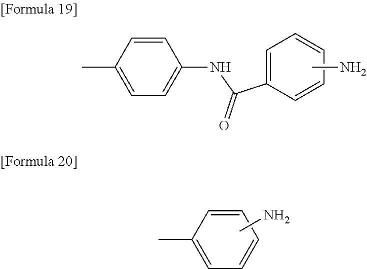

[42] The polyimide film according to any one of [33] to [41], in which Z² is the following structure.

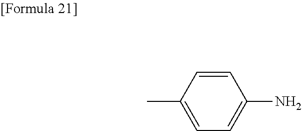

[43] The polyimide film according to any one of [1] to [6], in which the silsesquioxane derivative has a structure represented by the following general formula (hereinafter, sometimes referred to as “General Formula AM-D2”):

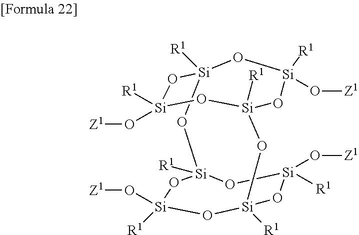

(where R¹'s each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
Z²'s are independent of each other,
at least two of Z²'s are a structure represented by General Formula (Z2-1) or a structure represented by General Formula (Z2-2),
Y in General Formula (Z2-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these,
Y belonging to Z² is linked to 0 adjacent to Z² by a linking group,
an amino group belonging to General Formula (Z2-2) is linked to 0 adjacent to Z² by a linking group,
in a case where Z² other than the structure represented by General Formula (Z2-1) or the structure represented by General Formula (Z2-2) is present, Z² other than these structures is H or a structure represented by General Formula (Z2-S),
and Q^{S1}' in General Formula (Z2-S) each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms).

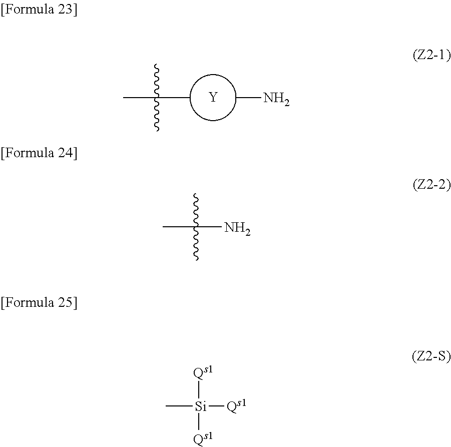

[44] The polyimide film according to [43], in which R's each independently represent a methyl group, an ethyl group, an isobutyl group, an isooctyl group, a trifluoropropyl group, or a phenyl group.

[45] The polyimide film according to [43] or [44], in which R¹ represents a phenyl group.

[46] The polyimide film according to any one of [44] to [46], in which Y's in General Formula (Z2-1) are each independently a substituted or unsubstituted aromatic ring.

[47] The polyimide film according to any one of [43] to [46], in which Q^{S1}'s in General Formula (Z1-S) each independently represent a methyl group, an ethyl group, or a phenyl group.

[48] The polyimide film according to any one of [43] to [47], in which at least two of Z²'s are any one of the following three structures:

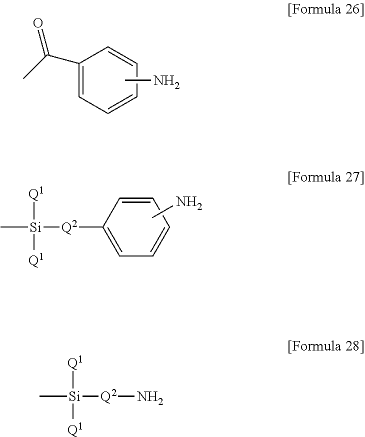

(where Q¹'s each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
and Q² is a single bond, a substituted or unsubstituted, linear or branched alkylene group, or a group formed by substituting carbon adjacent to Y constituting a substituted or unsubstituted arylene group or an alkylene group (specifically, a substituted or unsubstituted, linear or branched alkylene group) with a heteroatom).

[49] The polyimide film according to any one of [1] to [6], in which the silsesquioxane derivative has a structure represented by the following general formula (hereinafter, sometimes referred to as “General Formula AM-C1”)

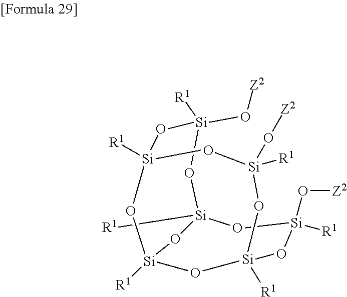

(where R²'s each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
Z2's are independent of each other,
at least two of Z2's are each independently a structure represented by General Formula (Z2-1) or a structure represented by General Formula (Z2-2),
Y in General Formula (Z2-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these,
Y belonging to Z² is linked to 0 adjacent to Z² by a linking group,
an amino group belonging to General Formula (Z2-2) is linked to 0 adjacent to Z² by a linking group,
in a case where Z² other than the structure represented by General Formula (Z2-1) or the structure represented by General Formula (Z2-2) is present, Z² other than these structures is H or a structure represented by General Formula (Z2-S),
and Q^{S1}' in General Formula (Z2-S) each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms).

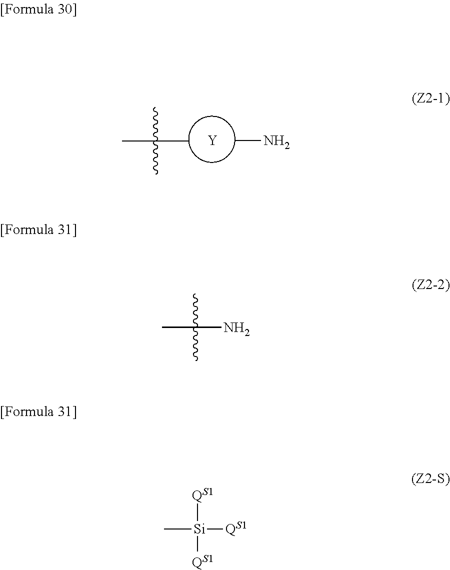

[50] The polyimide film according to [49], in which R¹'s each independently represent a methyl group, an ethyl group, an isobutyl group, an isooctyl group, a trifluoropropyl group, or a phenyl group.

[51] The polyimide film according to [49] or [50], in which R¹ represents a phenyl group.

[52] The polyimide film according to any one of [49] to [51], in which Y's in General Formula (Z2-1) are each independently a substituted or unsubstituted aromatic ring.

[53] The polyimide film according to any one of [49] to [52], in which Q^{S1}'s in General Formula (Z1-S) each independently represent a methyl group, an ethyl group, or a phenyl group.

[54] The polyimide film according to any one of [49] to [53], in which at least two of Z²'s are any one of the following three structures:

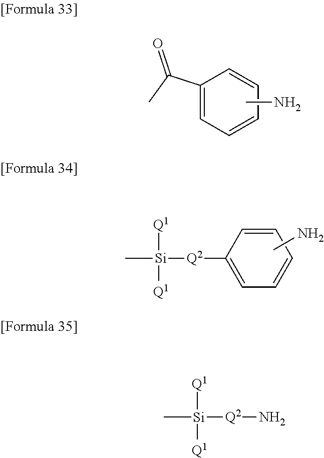

(where Q¹′ₛ each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
and Q² is a single bond, a substituted or unsubstituted, linear or branched alkylene group, or a group formed by substituting carbon adjacent to Y constituting a substituted or unsubstituted arylene group or an alkylene group (specifically, a substituted or unsubstituted, linear or branched alkylene group) with a heteroatom).

[55] The polyimide film according to any one of [1] to [6], in which the silsesquioxane derivative has a structure represented by the following general formula (hereinafter, sometimes referred to as “General Formula AM-Q1”)

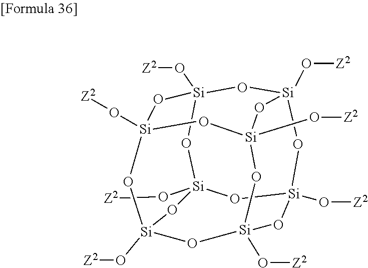

(where Z2's are independent of each other,
at least two of Z2's are each independently a structure represented by General Formula (Z2-1) or a structure represented by General Formula (Z2-2),
Y in General Formula (Z2-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these,
Y belonging to Z2 is linked to O adjacent to Z2 by a linking group,
an amino group belonging to General Formula (Z2-2) is linked to 0 adjacent to Z2 by a linking group,
in a case where Z² other than the structure represented by General Formula (Z2-1) or the structure represented by General Formula (Z2-2) is present, Z² other than these structures is H or a structure represented by General Formula (Z2-S),
and Q^{S1}' in General Formula (Z2-S) each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms).

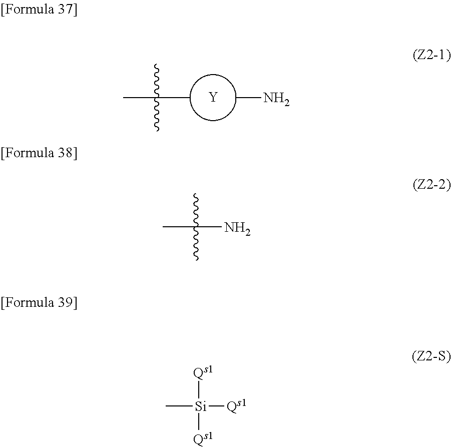

[56] The polyimide film according to any one of [55], in which Y's in General Formula (Z2-1) are each independently a substituted or unsubstituted aromatic ring.

[57] The polyimide film according to [55] or [56], in which Q^{S1}'s in General Formula (Z1-S) each independently represent a methyl group, an ethyl group, or a phenyl group.

[58] The polyimide film according to any one of [1] to [6], in which the silsesquioxane derivative is a silsesquioxane derivative obtained by reacting a thiol group of a condensate B of
a thiol group-containing trialkoxysilane a1 represented by General Formula: R¹Si(OR²)₃:
(where R¹ represents an organic group in which at least one hydrogen atom of an aliphatic hydrocarbon group having 1 to 8 carbon atoms, an alicyclic hydrocarbon group having 4 to 8 carbon atoms, or an aromatic hydrocarbon group having 6 to 8 carbon atoms is substituted with a thiol group and R²'s each independently represent a hydrogen atom, an aliphatic hydrocarbon group having 1 to 8 carbon atoms, an alicyclic hydrocarbon group having 4 to 8 carbon atoms, or an aromatic hydrocarbon group having 6 to 8 carbon atoms), and
a trialkoxysilane a2 not having a thiol group,
with the reactive group of a dicarboxylic anhydride C having at least one reactive group selected from a vinyl group, an alkenyl group, a cycloalkenyl group, an alkynyl group, or an acid chloride group.

[59] The polyimide film according to any one of [1] to [6] and [58], in which the silsesquioxane derivative has structural units represented by the following General Formulas (1) and (2):

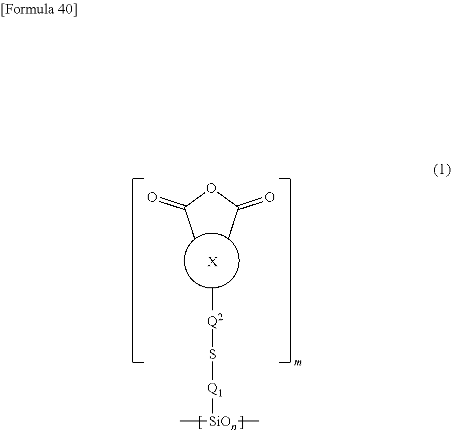

(where Q¹ represents an aliphatic hydrocarbon group, alicyclic hydrocarbon group, or aromatic hydrocarbon group having 1 to 8 carbon atoms, Q² is a single bond, a hydrocarbon group having 1 to 8 carbon atoms, an organic group in which one or more carbon atoms of a hydrocarbon group having 1 to 8 carbon atoms are substituted with oxygen, or a carbonyl group, X is a carbon-carbon bond, or an aliphatic ring having 4 to 10 carbon atoms, an aromatic ring, or a heterocycle formed by substituting some of carbons constituting these with oxygen or sulfur, one or more of hydrogens bonded to these may be substituted with a hydrocarbon group, and 1.0 m 2.0 and 1.4 n 1.6), and

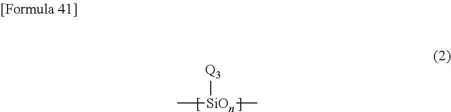

(where Q³ represents an aliphatic hydrocarbon group, alicyclic hydrocarbon group, or aromatic hydrocarbon group having 1 to 8 carbon atoms and 1.4 n 1.6).

[60] The polyimide film according to [59], in which a molar ratio of the trialkoxysilane a2 ([number of moles of a2]/[number of moles of a1+number of moles of a2]) or a molar ratio of the structural unit represented by General Formula (2) ([structural unit (2)]/[structural unit (1)+structural unit (2)]) is 0.1 or more and 0.7 or less.

[61] The polyimide film according to any one of [1]to [60], in which the carboxylic acid is at least one selected from the group consisting of an alicyclic tetracarboxylic anhydride, an aromatic tetracarboxylic anhydride, a tricarboxylic acid, and a dicarboxylic acid.

[62] The polyimide film according to any one of [1] to [61], in which the carboxylic acid includes at least one of pyromellitic dianhydride or 1,2,3,4-cyclobutanetetracarboxylic dianhydride.

[63] The polyimide film according to any one of [1] to [62], in which the carboxylic acid includes pyromellitic dianhydride.

[64] The polyimide film according to any one of [1] to [63], in which the carboxylic acid includes 1,2,3,4-cyclobutanetetracarboxylic dianhydride.

[65] The polyimide film according to any one of [1] to [64], in which the diamine is at least one selected from the group consisting of an aromatic diamine, an aliphatic diamine, and an alicyclic diamine.

[66] The polyimide film according to any one of [1] to [65], in which the diamine includes at least one of 2,2′-ditrifluoromethyl-4,4′-diaminobiphenyl or 4-amino-N-(4-aminophenyl)benzamide.

[67] The polyimide film according to any one of [1] to [66], in which the diamine includes 2,2′-ditrifluoromethyl-4,4′-diaminobiphenyl.

[68] The polyimide film according to any one of [1] to [67], in which the diamine includes 4-amino-N-(4-aminophenyl)benzamide.

[69] The polyimide film according to any one of [1] to [68], in which
the silsesquioxane derivative has two or more dicarboxylic anhydride groups, and
in the silsesquioxane derivative, a number of moles of a structural unit derived from the silsesquioxane derivative (however, in a case where the silsesquioxane derivative has more than two dicarboxylic anhydride groups, this number of moles is the number calculated by dividing the total number of moles of the silsesquioxane derivative by the total number of the dicarboxylic anhydride groups of the silsesquioxane derivative, and multiplying the result by two) is 0.0001 times or more and 0.09 times or less a sum of the number of moles of the structural unit derived from the silsesquioxane derivative and a number of moles of a structural unit derived from the carboxylic acid.

[70] The polyimide film according to any one of [1] to [68], in which
the silsesquioxane derivative has two or more amino groups, and
in the silsesquioxane derivative, a number of moles of a structural unit derived from the silsesquioxane derivative (however, in a case where the silsesquioxane derivative has more than two amino groups, this number of moles is a number calculated by dividing a total number of moles of the silsesquioxane derivative by a total number of the amino groups of the silsesquioxane derivative, and multiplying the result by two) is 0.0001 times or more and 0.09 times or less a sum of the number of moles of the structural unit derived from the silsesquioxane derivative and a number of moles of a structural unit derived from the diamine.

[71]A laminated body including the polyimide film according to any one of [1] to [70] and an inorganic substrate.

[72]A method for producing a flexible electronic device, the method including:
a step of forming an electronic device on a polyimide film surface of the laminated body according to [71]; and
a step of peeling off the inorganic substrate.

[73]A flexible electronic device including the polyimide film according to any one of [1] to [70] and an electronic device formed on the polyimide film.

### Effect of the Invention

According to the present invention, it is possible to provide a polyimide film having improved easily slipping properties. It is also possible to provide a laminated body obtained using a polyimide film, a flexible electronic device obtained using a polyimide film, and a method for producing a flexible electronic device.

### BRIEF DESCRIPTION OF THE DRAWINGS

FIG. 1 is a diagram illustrating the 1H NMR (CDCl₃) spectrum of SQ109 (PGMEA solution) used in Synthesis Example 2-1.

FIG. 2 is a diagram illustrating the ¹H NMR (CDCl₃) spectrum of PGMEA. Incidentally, δ=2.2 is a peak attributed to acetone for instrument cleaning.

FIG. 3 is a diagram illustrating the ¹H NMR (CDCl₃) spectrum of a norbornene acid anhydride used in Synthesis Example 2-1. Incidentally, δ=2.2 is a peak attributed to acetone for instrument cleaning.

FIG. 4 is a diagram illustrating the 1H NMR (CDCl₃) spectrum of a reaction mixture after a reaction in Synthesis Example 2-1.

FIG. 5 is a diagram illustrating the 1H NMR (CDCl₃) spectrum of a silsesquioxane SQ2 having an acid anhydride group, which is obtained in Synthesis Example 2-2.

FIG. 6 is a diagram illustrating the ¹H NMR (DMSO-d₆) spectrum of a silsesquioxane SQ3 having an acid anhydride group, which is obtained in Synthesis Example 2-3.

FIG. 7 is a diagram illustrating the ¹H NMR (DMSO-d₆) spectrum of a silsesquioxane SQ4 having an acid anhydride group, which is obtained in Synthesis Example 2-4.

FIG. 8 is a diagram illustrating the 1H NMR (DMSO-d₆) spectrum of a silsesquioxane SQ5 having an acid anhydride group, which is obtained in Synthesis Example 2-5.

FIG. 9 is a diagram illustrating the 1H NMR (DMSO-d₆) spectrum of a silsesquioxane SQ6 having an acid anhydride group, which is obtained in Synthesis Example 2-6.

FIG. 10 is a diagram illustrating the ¹H NMR (DMSO-d₆) spectrum of a silsesquioxane SQ7 having an acid anhydride group, which is obtained in Synthesis Example 2-7.

FIG. 11 is a diagram illustrating the ¹H NMR (DMSO-d₆) spectrum of a silsesquioxane SQ8 having an acid anhydride group, which is obtained in Synthesis Example 2-8.

### MODE FOR CARRYING OUT THE INVENTION

### Introduction

The polyimide film of the present invention includes a polyimide obtained through imidization of a polyamic acid that is a copolymerization reaction product of at least a carboxylic acid, a diamine, and a silsesquioxane derivative, and has a coefficient of static friction of 2.0 or less.

By a polyimide, specifically a polyimide obtained through imidization of a polyamic acid that is a copolymerization reaction product of at least a carboxylic acid, a diamine, and a silsesquioxane derivative, the coefficient of static friction of the polyimide film can be diminished. In other words, the easily slipping properties can be improved. The mechanism of this is unclear, but by the analysis of the surface components, it has been revealed that components derived from the silsesquioxane derivative tend to precipitate on the polyimide film surface, and it is considered that efficient modification of the surface state has contributed to this.

Moreover, as the coefficient of static friction is 2.0 or less, that is, easily slipping properties are excellent, it is possible to suppress the generation of wrinkles and scratches when the polyimide film is wound into a roll shape.

Hereinafter, the present invention will be described in more detail, but these are an aspect of the present invention and the present invention is not limited to the contents thereof.

Hereinafter, a silsesquioxane derivative is sometimes referred to as a silsesquioxane compound. In other words, the term “silsesquioxane derivative” and the term “silsesquioxane compound” are used as synonyms. Hence, a silsesquioxane derivative can be referred to a silsesquioxane compound.

In the present invention, a polyamic acid is a copolymerization reaction product of at least a carboxylic acid, a diamine, and a silsesquioxane derivative. As described later, the silsesquioxane derivative can have two or more dicarboxylic anhydride groups (hereinafter, simply referred to as “acid anhydride groups” in some cases) or two or more amino groups. Hereinafter, these will be explained.

### <Silsesquioxane Derivative>

The silsesquioxane derivative can have two or more dicarboxylic anhydride groups (that is, acid anhydride groups) or two or more amino groups. Hence, the silsesquioxane derivative can be copolymerized with a carboxylic acid and a diamine, and as a result, the coefficient of static friction of the polyimide film can be diminished. In other words, the easily slipping properties can be improved. The mechanism of this is unclear, but by the analysis of the surface components, it has been revealed that components derived from the silsesquioxane derivative tend to precipitate on the polyimide film surface, and it is considered that efficient modification of the surface state has contributed to this. In this way, the coefficient of static friction can be diminished without use of a lubricant, and thus the generation of wrinkles and scratches when the polyimide film is wound into a roll shape can be suppressed without use of a lubricant. As described later, the polyimide film may or may not contain a lubricant.

Since the silsesquioxane derivative can be copolymerized with a carboxylic acid and a diamine, toughness of the polyimide film can also be improved. The detailed reason of this (that is, the reason why toughness of the polyimide film is improved by copolymerizing the silsesquioxane derivative with a carboxylic acid and a diamine) is not clear, but it is considered that the silsesquioxane skeleton, which is relatively flexible compared to an inorganic filler or the like, becomes a minute domain and this makes it easier to tolerate deformation of the polyimide that is the base material.

A silsesquioxane is a term used to refer to a siloxane composed mainly of T units (for example, T_{O} type composed of 8 T units, T₁₀ type composed of 10 T units, T₁₂ type composed of 12 T units), but is sometimes used in a broader sense than this. Specifically, a silsesquioxane is sometimes used as a term to refer not only to a siloxane composed mainly of T units but also to a siloxane composed mainly of 12 or fewer Q units (for example, Q₈ type composed of 8 Q units and Q₁₀ type composed of 10 Q units). Incidentally, the T unit is a unit represented by RSiO_{1.5}. The Q unit is a unit represented by SiO₂. In these, R can represent an organic group.

In this specification, the “silsesquioxane” in the silsesquioxane derivative is used in a broad sense. In other words, the “silsesquioxane” in the silsesquioxane derivative encompasses not only a siloxane composed mainly of T units but also a siloxane composed mainly of 12 or less Q units. Hence, the “silsesquioxane derivative” also encompasses not only a siloxane derivative composed mainly of T units but also a siloxane derivative composed mainly of 12 or less Q units.

In a case where the silsesquioxane derivative is composed mainly of T units, the silsesquioxane derivative may contain units other than T units, for example, M units (groups represented by R³SiO_{0.5}), D units (groups represented by R₂SiO) and Q units. The “silsesquioxane derivative is composed mainly of T units” means that the number of T units is larger than the number of units other than T units (for example, the total number of M units, D units, and Q units). Hence, for example, a silsesquioxane derivative may be composed of eight T units and two D units. In a case where the silsesquioxane derivative is composed mainly of Q units as well, the silsesquioxane derivative may contain units other than Q units, for example, M units, D units, and T units. The “silsesquioxane derivative is composed mainly of Q units” means that the number of Q units is larger than the number of units other than Q units (for example, the total number of M units, D units, and T units). In the M and D units as well, R can represent an organic group.

The silsesquioxane derivative may have a double-decker structure, a cage structure, a random structure, a ladder structure, or a chair structure. Among these, a double-decker structure, a cage structure, and a random structure are preferable. A fully condensed structure (a structure not containing a silanol group) is preferable for the reason that gelation of the polyamic acid solution can be suppressed. For example, a double-decker structure and a cage structure are more preferable.

The double-decker structure may be either a closed ring or an open ring. Examples of the ring-closed double-decker structure include a structure represented by General Formula AA-D1 described later and a structure represented by General Formula AM-D1 described later. Meanwhile, examples of the ring-opened double-decker structure include a structure represented by General Formula AA-D2 described later and a structure represented by General Formula AM-D2 described later.

The cage structure may be a perfect cage structure or an imperfect cage structure (for example, a corner-open structure). The perfect cage structure is a structure in which a closed space is formed in a cage. For example, the perfect cage structure can be a structure in which a space is formed surrounded by six quadrilateral planes having four sides each composed of siloxane bonds Si—O—Si (hereinafter, this perfect cage structure is sometimes referred to as the “hexahedral perfect cage structure”). Meanwhile, the imperfect cage structure is a structure in which a space that is open to the outside of a cage is formed in the cage.

Examples of the imperfect cage structure include a corner-open structure. Examples of the corner-open structure include a structure represented by General Formula AA-C1 described later and a structure represented by General Formula AM-C1 described later.

The silsesquioxane derivative can have two or more acid anhydride groups. The silsesquioxane derivative has two or more acid anhydride groups and is therefore capable of reacting with a diamine. The number of acid anhydride groups per molecule of the silsesquioxane derivative may be, for example, 3 or more, 4 or more, 5 or more, or 6 or more. The number of acid anhydride groups per molecule may be, for example, 10 or less, or 8 or less. In particular, in a case where the silsesquioxane derivative has a cage structure or a double-decker structure, the number of acid anhydride groups per molecule is, for example, preferably 2 or more and 8 or less, more preferably 2, 3, or 4. Meanwhile, in a case where the silsesquioxane derivative has a random structure, the number of acid anhydride groups per molecule is preferably 2 to 10, more preferably 2.5 to 6. When the number of acid anhydride groups is within this range, the obtained polyimide chains are properly crosslinked, and the toughness of the polyimide film can be further improved.

In a case where the silsesquioxane derivative has two or more acid anhydride groups, the silsesquioxane derivative does not have two or more amino groups described later.

Such a silsesquioxane derivative can be a structure represented by, for example, the following general formula (hereinafter, sometimes referred to as “General Formula AA-D1”):

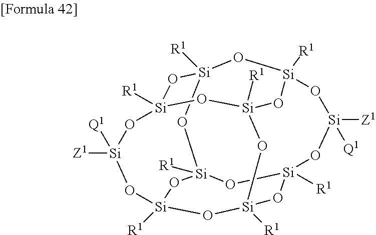

(where R¹'s each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
Q¹'s each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
Z¹'s are each independently a structure represented by General Formula (Z1-1),
X in General Formula (Z1-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these, and
X belonging to Z¹ and Si adjacent to Z¹ may be connected by a single bond or linked by a linking group).

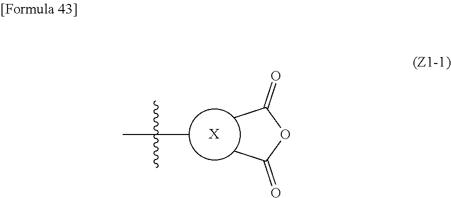

The silsesquioxane derivative represented by General Formula AA-D1 includes all geometric isomers within the scope of General Formula AA-D1. For example, as the geometric isomer represented by General Formula AA-D1, there are geometric isomers in which a pair of Q¹ and Z¹ bonded to Si are bonded to the ring plane in different directions, and the silsesquioxane derivative represented by General Formula AA-D1 includes these.

With regard to R¹, examples of the unsubstituted alkyl group include a methyl group, an ethyl group, a propyl group, a butyl group, a pentyl group, a hexyl group, a heptyl group, an octyl group, and a nonyl group. These (technically, from the propyl group) may be linear or branched. For example, the propyl group may be a n-propyl group (namely, a 1-propyl group) or an isopropyl group (namely, a 1-methylethyl group). For example, the butyl group may be a n-butyl group, an isobutyl group, a sec-butyl group, or a tert-butyl group (namely, a 1,1-dimethylethyl group). The hexyl group may be, for example, a 1,1,2-trimethylpropyl group. The octyl group may be, for example, a 2,2,4-trimethylpentyl group. Examples of the branched, unsubstituted alkyl group include an isopropyl group, an isobutyl group, a sec-butyl group, an isooctyl group, a 1,1,2-trimethylpropyl group, and a 2,2,4-trimethylpentyl group.

With regard to R¹, the substituted alkyl group may be, for example, a group in which an arbitrary number of hydrogen atoms constituting the above-mentioned unsubstituted alkyl group is substituted with a halogen atom. As the halogen atom, a fluorine atom, namely, F, is preferable. Examples of the substituted alkyl group include —CH₂CH₂CF₃, —CH₂CH₂CF₂CF₃, —CH₂CH₂CF₂CF₂CF₃, —CH₂CH₂CF₂CF₂CF₂CF₃, —CH₂CH₂CF₂CF₂CF₂CF₂CF₃, —CH₂CH₂CF₂CF₂CF₂CF₂CF₂CF₃, —CH₂CH₂CF(CF₃)₂, —CH₂CH(CF₃) CF₂CF₃, —CH(CF₃) CH₂CF₂CF₃, —CH₂C(CF₃)₂CF₃, —C(CF₃)₂CH₂CF₃, —CH₂CH₂CF₂CF(CF₃)₂, —CH₂CH₂CF(CF₃) CF₂CF₃, —CH₂CH₂C(CF₃)₂CF₃. In addition to these, examples of the substituted alkyl group include —CF₃, —CF₂CF₃, —CF₂CF₂CF₃, —CF(CF₃)₂, —CF₂CF₂CF₂CF₃, —CF₂CF(CF₃)₂, —C(CF₃)₃, —(CF₂)₄CF₃, —(CF₂)₂CF(CF₃)₂, —CF₂C(CF₃)₃, —CF(CF₃)CF₂CF₂CF₃, —(CF₂)₅CF₃, —(CF₂)₃CF(CF₃)₂, —(CF₂)₄CF(CF₃)₂, —(CF₂)₇CF₃, —(CF₂)₅CF(CF₃)₂, and —(CF₂)₆CF(CF₃)₂. Among these, a trifluoropropyl group, namely, —CH₂CH₂CF₃, is preferable.

The alkyl group of R¹ (specifically, a substituted or unsubstituted, linear or branched alkyl group having 1 to 9 carbon atoms) may have an unsaturated bond. Examples thereof include a vinyl group, a 2-propenyl group, a 3-butenyl group, a 5-hexenyl group, and a 7-octenyl group.

The alkyl group of R¹ (specifically, a substituted or unsubstituted, linear or branched alkyl group having 1 to 9 carbon atoms) has preferably 1 to 8 carbon atoms, more preferably 1, 2, 3, 4, or 8 carbon atoms. Here, this number of carbon atoms means the number of carbon atoms including those of the substituents.

With regard to R¹, examples of the unsubstituted aryl group include a phenyl group, a 1-naphthyl group, a 2-naphthyl group, and a fluorenyl group.

With regard to R¹, the substituted aryl group may be, for example, a group in which an arbitrary number of hydrogen atoms constituting the above-mentioned unsubstituted aryl group is substituted with another atom and/or another atomic group. The substituted aryl group may be, for example, a group in which an arbitrary number of hydrogen atoms constituting the above-mentioned unsubstituted aryl group is substituted with an alkyl group (specifically, a substituted or unsubstituted, linear or branched alkyl group having 1 to 9 carbon atoms). The substituted aryl group may be, for example, a group in which an arbitrary number of hydrogen atoms constituting the above-mentioned unsubstituted aryl group is substituted with a halogen atom. As the halogen atom, a fluorine atom, namely, F, is preferable. Examples of the substituted aryl group include an o-tolyl group, a m-tolyl group, a p-tolyl group, a 4-ethylphenyl group, a 4-propylphenyl group, a 4-butylphenyl group, a 4-pentylphenyl group, a 4-heptylphenyl group, a 4-octylphenyl group, a 4-nonylphenyl group, a 2,4-dimethylphenyl group, a 2,4,6-trimethylphenyl group, a 2,4,6-triethylphenyl group, a 4-(1-methylethyl)phenyl group, a 4-(1,1-dimethylethyl)phenyl group, a 4-(2-ethylhexyl)phenyl group, and a 2,4,6-tris(1-methylethyl)phenyl group. In addition to these, examples of the substituted aryl group include a pentafluorophenyl group, a 4-fluorophenyl group, a 4-chlorophenyl group, and a 4-bromophenyl group. Further examples of the substituted aryl group include a 4-methoxyphenyl group, a 4-ethoxyphenyl group, a 4-propoxyphenyl group, a 4-butoxyphenyl group, a 4-pentyloxyphenyl group, a 4-heptyloxyphenyl group, a 4-(1-methylethoxy)phenyl group, a 4-(2-methylpropoxy)phenyl group, a 4-(1,1-dimethylethoxy)phenyl group, a 4-ethenylphenyl group, a 4-(1-methylethenyl)phenyl group, and a 4-(3-butenyl)phenyl group.

The aryl group (specifically, a substituted or unsubstituted aryl group having 15 or less carbon atoms) of R¹ has preferably 12 or less carbon atoms, more preferably 8 or less carbon atoms, still more preferably 6 or less carbon atoms. This number of carbon atoms means the number of carbon atoms including those of the substituents.

Examples of the arylalkyl group of R¹, particularly an unsubstituted arylalkyl group, include a benzyl group and a phenethyl group. With regard to R¹, the substituted arylalkyl group may be, for example, a group in which an arbitrary number of hydrogen atoms constituting the above-mentioned unsubstituted arylalkyl group is substituted with another atom and/or another atomic group. The substituted arylalkyl group may be, for example, a group in which an arbitrary number of hydrogen atoms constituting the above-mentioned unsubstituted arylalkyl group is substituted with an alkyl group (specifically, a substituted or unsubstituted, linear or branched alkyl group having 1 to 9 carbon atoms). The substituted arylalkyl group may be, for example, a group in which an arbitrary number of hydrogen atoms constituting the above-mentioned unsubstituted arylalkyl group is substituted with a halogen atom. As the halogen atom, a fluorine atom, namely, F, is preferable.

The arylalkyl group (specifically, a substituted or unsubstituted arylalkyl group having 15 or less carbon atoms) of R¹ has preferably 12 or less carbon atoms, more preferably 10 or less carbon atoms, still more preferably 8 or less carbon atoms. This number of carbon atoms means the number of carbon atoms including those of the substituents.

R¹ is preferably a methyl group, an ethyl group, an isobutyl group, an isooctyl group, a trifluoropropyl group, or a phenyl group. Among these, a phenyl group is more preferable since there is an interaction between aromatic rings and high heat resistance is exhibited.

The explanation of Q¹ overlaps with the explanation of R¹ and will be omitted. Hence, the explanation of R¹ can also be treated as the explanation of Q¹. Since there are the most suitable specific examples particular to Q¹, the explanation of the most suitable specific examples will be added. Specifically, Q¹ is preferably a methyl group, an ethyl group, or a phenyl group, more preferably a methyl group for the reason that the production difficulty is relatively not high.

With regard to Z¹, X in General Formula (Z1-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these.

Examples of the unsubstituted aromatic ring include a benzene ring and a naphthalene ring. Among these, a benzene ring is preferable for the reason that the production difficulty is relatively not high. Meanwhile, the substituted aromatic ring may be, for example, a group in which an arbitrary number of hydrogen atoms constituting the above-mentioned unsubstituted aromatic ring is substituted with a substituted or unsubstituted, linear or branched alkyl group having 1 to 9 carbon atoms. The explanation of this alkyl group overlaps with the explanation of R¹ and will be omitted. Hence, the explanation of R¹ can also be treated as the explanation of this alkyl group.

Examples of the heterocycle formed by substituting at least one of carbons constituting an unsubstituted aromatic ring with a heteroatom include a pyridine ring, a pyrrole ring, a furan ring, a thiophene ring, and a thiazole ring (for example, a 1,3-thiazole ring). Examples of the heteroatom include a nitrogen atom, an oxygen atom, and a sulfur atom. Meanwhile, the heterocycle formed by substituting at least one of carbons constituting a substituted aromatic ring with a heteroatom can be, for example, a structure in which an arbitrary number of hydrogen atoms constituting the above-mentioned unsubstituted heterocycle is substituted with a substituted or unsubstituted, linear or branched alkyl group having 1 to 9 carbon atoms. The explanation of this alkyl group overlaps with the explanation of R¹ and will be omitted. Hence, the explanation of R¹ can also be treated as the explanation of this alkyl group.

Examples of the unsubstituted aliphatic ring having 4 to 10 carbon atoms include cyclobutane, cyclopentane, cyclohexane, cycloheptane, cyclooctane, cyclononane, cyclodecane, norbornane (namely, bicyclo[2.2.1]heptane), and bicyclo[2.2.2]octane. Among these, crosslinked aliphatic rings such as norbornane and bicyclo[2.2.2]octane are preferable and norbornane, bicyclo[2.2.2]octane are more preferable, and norbornane is still more preferable for the reason that the thermal stability is relatively high. Meanwhile, the substituted aliphatic ring may be, for example, a group in which an arbitrary number of hydrogen atoms constituting the above-mentioned unsubstituted aliphatic ring is substituted with a substituted or unsubstituted, linear or branched alkyl group having 1 to 6 carbon atoms. The explanation of this alkyl group overlaps with the explanation of R¹ and will be omitted. Hence, the explanation of R¹ can also be treated as the explanation of this alkyl group.

Examples of the heterocycle formed by substituting at least one of carbons constituting an unsubstituted aliphatic ring having 4 to 10 carbon atoms with a heteroatom include a structure in which a carbon atom constituting a methylene group between bridgehead atoms of norbornane, specifically, between bridgehead atoms constituting the shortest bridge of norbornane is substituted with an oxygen atom. In other words, examples of the heterocycle include a structure in which a methylene group between bridgehead atoms of norbornane is substituted with an ether bond. Other examples of the heterocycle include thiane and dithiane (namely, 1,4-dithiane). Examples of the heteroatom include a nitrogen atom, an oxygen atom, and a sulfur atom. Meanwhile, the heterocycle formed by substituting at least one of carbons constituting a substituted aliphatic ring having 4 to 10 carbon atoms with a heteroatom may be, for example, a group in which an arbitrary number of hydrogen atoms constituting the above-mentioned unsubstituted heterocycle is substituted with a substituted or unsubstituted, linear or branched alkyl group having 1 to 6 carbon atoms. The explanation of this alkyl group overlaps with the explanation of R¹ and will be omitted. Hence, the explanation of R¹ can also be treated as the explanation of this alkyl group.

The number of carbon atoms of the aliphatic ring (specifically, a substituted or unsubstituted aliphatic ring having 4 to 10 carbon atoms) may be, for example, 6 or more, 7 or more, or 8 or more. This number of carbon atoms may be 9 or less, or 8 or less. This number of carbon atoms means the number of carbon atoms including those of the substituents.

Examples of a ring formed through condensation of at least two of these rings (specifically, a substituted or unsubstituted aromatic ring, a substituted or unsubstituted aliphatic ring having 4 to 10 carbon atoms, or a heterocycle formed by substituting at least one of carbons constituting these rings with a heteroatom), that is, a condensed ring, include benzofuran (for example, 1-benzofuran), benzothiophene (for example, 1-benzothiophene), and benzothiazole.

X is preferably a substituted or unsubstituted aromatic ring for the reason that the yellowing of polyimide (for example, polyimide film) under a high temperature condition of around 400° C. can be further suppressed. From the viewpoint of production difficulty in addition to this, an unsubstituted aromatic ring is more preferable. A substituted or unsubstituted aliphatic ring having 4 to 10 carbon atoms is preferable, and an unsubstituted aliphatic ring having 4 to 10 carbon atoms is preferable from the viewpoint of being available as a commercial product (for example, DDSQ manufactured by Japan Material Technologies Corporation).

X belonging to Z¹ and Si adjacent to Z¹ may be connected by a single bond or linked by a linking group. Examples of the linking group that links the two include a substituted or unsubstituted, linear or branched alkylene group, a substituted or unsubstituted arylene group, a group represented by the following Structural Formula (C-S), an ester group (namely, an ester bond), an amide group (namely, an amide bond), and a combination of arbitrary two or more thereof. The linking groups can be independent of each other. In other words, each linking group can be a unique structure.

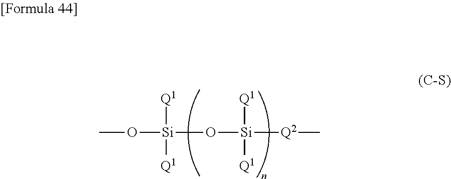

(where Q^{1′}ₛ each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
n is an integer from 0 to 8,
Q² is a single bond, a substituted or unsubstituted, linear or branched alkylene group, a substituted or unsubstituted arylene group, or a group formed by substituting carbon adjacent to X constituting an alkylene group (specifically, a substituted or unsubstituted, linear or branched alkylene group) with a heteroatom, and
O at the edge is connected to Si adjacent to Z¹, and Q² at the edge is connected to X).
“Q² at the edge is connected to X” means that Si adjacent to Q² at the edge is connected to X in a case where Q² at the edge is a single bond, and an alkylene group, an arylene group, or a group in which carbon adjacent to X constituting an alkylene group is substituted with a heteroatom is connected to X in a case where Q² at the edge is an alkylene group, an arylene group, or a group in which carbon adjacent to X constituting an alkylene group is substituted with a heteroatom.

With regard to the linking group, examples of the unsubstituted, linear or branched alkylene group include a methylene group, an ethylene group, an n-propylene group, an n-butylene group, a tert-butylene group, an n-pentylene group, an n-hexylene group, an n-heptylene group, and an n-octylene group.

The substituted, linear or branched alkylene group may be, for example, a group in which an arbitrary number of hydrogen atoms constituting the above-mentioned unsubstituted alkylene group is substituted with a halogen atom. Examples of the halogen atom include a fluorine atom.

The alkylene group (specifically, a substituted or unsubstituted, linear or branched alkylene group) has preferably 10 or less carbon atoms, more preferably 6 or less carbon atoms, still more preferably 3 or less carbon atoms. This number of carbon atoms means the number of carbon atoms including those of the substituents.

With regard to the linking group, examples of the unsubstituted arylene group include an o-phenylene group, a m-phenylene group, a p-phenylene group, and a naphthylene group (for example, a 2,6-naphthylene group).

The substituted arylene group may be, for example, a group in which an arbitrary number of hydrogen atoms constituting the above-mentioned unsubstituted arylene group is substituted with an alkyl group (for example, a methyl group).

The arylene group (specifically, a substituted or unsubstituted arylene group) has preferably 15 or less carbon atoms, more preferably 12 or less carbon atoms, still more preferably 7 or less carbon atoms. This number of carbon atoms means the number of carbon atoms including those of the substituents.

With regard to the linking group represented by Structural Formula (C-S), the explanation of Q¹ overlaps with the explanation of R¹ and will be omitted. Hence, the explanation of R¹ can also be treated as the explanation of Q¹. Since there are the most suitable specific examples particular to Q¹, the explanation of the most suitable specific examples will be added. Specifically, Q¹ is preferably a methyl group, an ethyl group, an isopropyl group, an isobutyl group, a sec-butyl group, a tert-butyl group, or a phenyl group.

n is an integer from 0 to 8. n is preferably 5 or less, more preferably 3 or less, still more preferably 1 or less, that is, 0 or 1 for the reason that the coefficient of linear thermal expansion (CTE) of polyimide (for example, polyimide film) can be lowered.

With regard to the linking group represented by Structural Formula (C-S), the explanation of the alkylene group (specifically, a substituted or unsubstituted, linear or branched alkylene group) of Q² overlaps with the explanation of the alkylene group (specifically, a substituted or unsubstituted, linear or branched alkylene group) described above and will be omitted. Hence, the explanation of the alkylene group described above can also be treated as the explanation of the alkylene group of Q².

With regard to the linking group represented by Structural Formula (C-S), the explanation of the arylene group (specifically, a substituted or unsubstituted arylene group) of Q² overlaps with the explanation of the arylene group (specifically, a substituted or unsubstituted arylene group) described above and will be omitted. Hence, the explanation of the arylene group described above can also be treated as the explanation of the arylene group of Q².

With regard to the linking group represented by Structural Formula (C-S), regarding Q², examples of the group in which carbon adjacent to X constituting a substituted or unsubstituted, linear or branched alkylene group is substituted with a heteroatom include a group in which carbon (specifically, carbon adjacent to X) constituting the specific examples of the alkylene group described above (for example, a methylene group, an ethylene group, a n-propylene group, a n-butylene group, a tert-butylene group, an n-pentylene group, a n-hexylene group, a n-heptylene group, and a n-octylene group) is substituted with a heteroatom. Among these, a n-butylene group, that is, a group in which carbon adjacent to X in a tetramethylene group is substituted with a heteroatom (for example, an oxygen atom or a sulfur atom), is preferable. In this case, this group (that is, Q²) has 3 carbon atoms.

With regard to the linking group represented by Structural Formula (C-S), regarding Q², examples of the heteroatom include a nitrogen atom, an oxygen atom, and a sulfur atom. Among these, an oxygen atom and a sulfur atom are preferable, and an oxygen atom is more preferable.

As the linking group, a combination of a substituted or unsubstituted arylene group with an amide group is preferable, and a combination of a p-phenylene group with an amide group is more preferable. Specifically, the following structure is preferable. In the following structural formula, the p-phenylene group is bonded to Si. The amide group is bonded to X. In other words, carbon constituting the amide group is bonded to X.

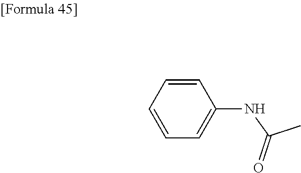

In a case where the two (that is, X belonging to Z¹ and Si adjacent to Z¹) are linked by this linking group, Z¹ is preferably the following structure.

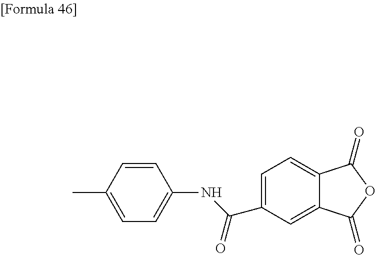 [SMILES: Cc1ccc(NC(=O)c2ccc3c(c2)C(=O)OC3=O)cc1]

It is preferable that the two (that is, X belonging to Z¹ and Si adjacent to Z¹) are connected by a single bond. This is because yellowing of polyimide (for example, polyimide film) under a high temperature condition can be further suppressed as the two are connected by a single bond.

In a case where the two are connected by a single bond, the structure represented by General Formula (Z1-1) is preferably the following structure. In other words, in a case where the two are connected by a single bond, Z¹ is preferably the following structure.

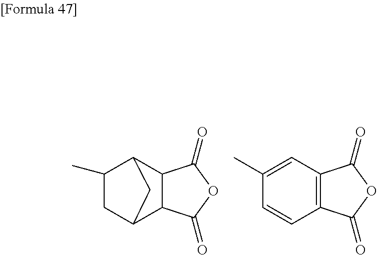

The silsesquioxane derivative represented by General Formula AA-D1 can be produced, for example, based on the methods described in JP-A-2004-331647 (the corresponding patent publication is JP-B-448334), JP-A-2006-265243 (the corresponding patent publication is JP-B-5082258), JP-A-2007-302635 (the corresponding patent publication is JP-B-4946169), and WO 2003/024870.

The silsesquioxane derivative represented by General Formula AA-D1 can be produced, for example, by a procedure in which a compound in which all Z¹'s are hydrogen atoms in General Formula AA-D1 is produced and this compound (that is, a compound having a SiH group containing H as Z¹ and Si adjacent to Z¹) is reacted with a compound having an acid anhydride group based on these documents. In this reaction, for example, hydrosilylation can be utilized. In other words, a reaction in which a compound having a SiH group is added to an unsaturated bond such as a carbon-carbon double bond, accompanied by cleavage of the Si—H bond can be utilized. In a case where hydrosilylation is utilized, the compound having an acid anhydride group can have an unsaturated bond (for example, a vinyl group) such as a carbon-carbon double bond. Meanwhile, in the reaction of a compound having a SiH group with a compound having an acid anhydride group, a coupling reaction, specifically, a coupling reaction of a compound having a SiH group with an aryl halide using a precious metal catalyst such as ruthenium, platinum, palladium, or rhodium can be utilized. In a case of utilizing a coupling reaction, the compound having an acid anhydride group or the compound having a functional group convertible into an acid anhydride group can have an aryl halide structure. Examples of the functional group convertible into an acid anhydride group include a diester group.

Among the silsesquioxane derivatives represented by General Formula AA-D1, for example, the following silsesquioxane derivative is available as a commercial product (for example, DDSQ manufactured by Japan Material Technologies Corporation).

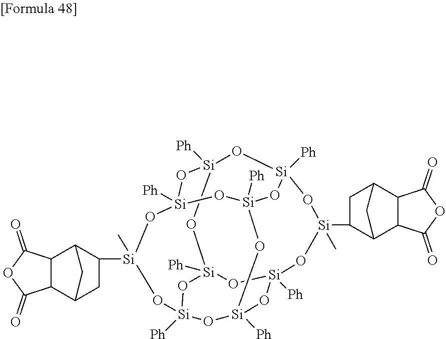

The silsesquioxane derivative can be a structure represented by, for example, the following general formula (hereinafter, sometimes referred to as “General Formula AA-D2”):

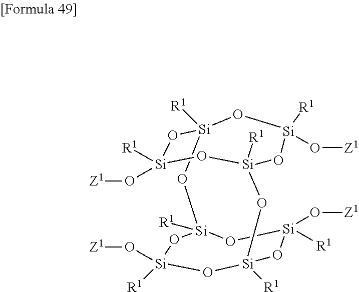

(where R's each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
Z¹'s are independent of each other,
at least two of Z¹'s are structures represented by General Formula (Z1-1),
X in General Formula (Z1-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these, and
X belonging to Z¹ is linked to 0 adjacent to Z¹ by a linking group,
in a case where Z¹ other than the structure represented by General Formula (Z1-1) is present, Z¹ other than the structure is H or a structure represented by General Formula (Z1-S), and
Q^{S1}'s in General Formula (Z1-S) each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms).

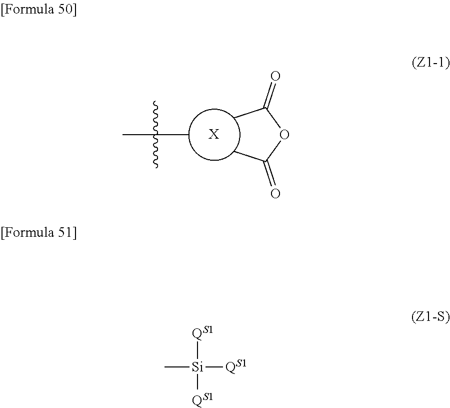

The silsesquioxane derivative represented by General Formula AA-D2 includes all geometric isomers within the scope of General Formula AA-D2. For example, as the geometric isomer represented by General Formula AA-D2, there are geometric isomers in which a pair of R¹ and O—Z¹ bonded to Si are bonded to the ring plane in different directions, and the silsesquioxane derivative represented by General Formula AA-D2 includes these.

The explanation of R¹ in General Formula AA-D2 overlaps with the explanation of R¹ in General Formula AA-D1 and will be omitted. Hence, the explanation of R¹ in General Formula AA-D1 can also be treated as the explanation of R¹ in General Formula AA-D2. Therefore, for example, R¹ is preferably a methyl group, an ethyl group, an isobutyl group, an isooctyl group, a trifluoropropyl group, or a phenyl group, more preferably a phenyl group.

At least two of Z¹'s are structures represented by General Formula (Z1-1). In other words, two of the four Z¹'s may be structures represented by General Formula (Z1-1), three of the four Z¹'s may be structures represented by General Formula (Z1-1), or four of the four Z¹'s may be structures represented by General Formula (Z1-1).

With regard to Z¹, X in General Formula (Z1-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these. The explanation of X in General Formula (Z1-1) in General Formula AA-D2 overlaps with the explanation of X in General Formula (Z1-1) in General Formula AA-D1 and will be omitted. Hence, the explanation of X in General Formula (Z1-1) in General Formula AA-D1 can also be treated as the explanation of X in General Formula (Z1-1) in General Formula AA-D2. Therefore, X is preferably a substituted or unsubstituted aromatic ring, for example, for the reason that the yellowing of polyimide (for example, polyimide film) under a high temperature condition of around 400° C. can be further suppressed. From the viewpoint of production difficulty in addition to this, an unsubstituted aromatic ring is more preferable.

Examples of the linking group that links X belonging to Z¹ to 0 adjacent to Z¹ include a substituted or unsubstituted, linear or branched alkylene group, a carbonyl group, a substituted or unsubstituted arylene group, and a group represented by the following Structural Formula (C). The linking groups can be independent of each other. In other words, each linking group can be a unique structure.

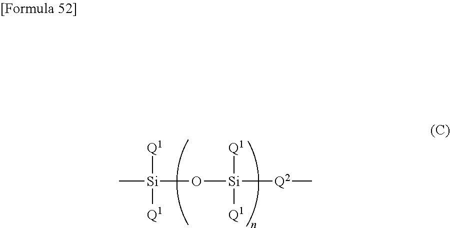

(where Q¹′ₛ each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
n is an integer from 0 to 8,
Q² is a single bond, a substituted or unsubstituted, linear or branched alkylene group, a substituted or unsubstituted arylene group, or a group formed by substituting carbon adjacent to X constituting an alkylene group (specifically, a substituted or unsubstituted, linear or branched alkylene group) with a heteroatom, and
Si at the edge is connected to O adjacent to Z¹, and Q² at the edge is connected to X).
“Q² at the edge is connected to X” means that Si adjacent to Q² at the edge is connected to X in a case where Q² at the edge is a single bond, and an alkylene group, an arylene group, or a group in which carbon adjacent to X constituting an alkylene group is substituted with a heteroatom is connected to X in a case where Q² at the edge is an alkylene group, an arylene group, or a group in which carbon adjacent to X constituting an alkylene group is substituted with a heteroatom.

In a case where the linking group is a substituted or unsubstituted, linear or branched alkylene group, the explanation of the alkylene group as the linking group overlaps with the explanation of the alkylene group (specifically, a substituted or unsubstituted, linear or branched alkylene group) in General Formula AA-D1 and will be omitted. Hence, the explanation of the alkylene group in General Formula AA-D1 can also be treated as the explanation of this alkylene group (that is, the alkylene group in General Formula AA-D2).

In a case where the linking group is a substituted or unsubstituted arylene group, the explanation of the arylene group as the linking group overlaps with the explanation of the arylene group (specifically, a substituted or unsubstituted arylene group) in General Formula AA-D1 and will be omitted. Hence, the explanation of the arylene group in General Formula AA-D1 can also be treated as the explanation of this arylene group (that is, the arylene group in General Formula AA-D2).

With regard to the linking group represented by Structural Formula (C), the explanation of Q¹ overlaps with the explanation of R¹ and will be omitted. Hence, the explanation of R¹ can also be treated as the explanation of Q¹. Since there are the most suitable specific examples particular to Q¹, the explanation of the most suitable specific examples will be added. Specifically, Q¹ is preferably a methyl group, an ethyl group, an isopropyl group, an isobutyl group, a sec-butyl group, a tert-butyl group, or a phenyl group.

n is an integer from 0 to 8. n is preferably 5 or less, more preferably 3 or less, still more preferably 1 or less, that is, 0 or 1 for the reason that the coefficient of linear thermal expansion (CTE) of polyimide (for example, polyimide film) can be lowered.

With regard to the linking group represented by Structural Formula (C), the explanation of the alkylene group (specifically, a substituted or unsubstituted, linear or branched alkylene group) of Q² overlaps with the explanation of the alkylene group (specifically, a substituted or unsubstituted, linear or branched alkylene group) in General Formula AA-D1 and will be omitted. Hence, the explanation of the alkylene group in General Formula AA-D1 can also be treated as the explanation of the alkylene group of Q².

With regard to the linking group represented by Structural Formula (C), the explanation of the arylene group (specifically, a substituted or unsubstituted arylene group) of Q² overlaps with the explanation of the arylene group (specifically, a substituted or unsubstituted arylene group) in General Formula AA-D1 and will be omitted. Hence, the explanation of the arylene group in General Formula AA-D1 can also be treated as the explanation of the arylene group of Q².

With regard to the linking group represented by Structural Formula (C), regarding Q², examples of the group in which carbon adjacent to X constituting a substituted or unsubstituted, linear or branched alkylene group is substituted with a heteroatom include a group in which carbon of the alkylene group exemplified in General Formula AA-D1 (specifically, carbon adjacent to X) constituting the specific examples (for example, a methylene group, an ethylene group, a n-propylene group, a n-butylene group, a tert-butylene group, an n-pentylene group, a n-hexylene group, a n-heptylene group, and a n-octylene group) is substituted with a heteroatom. Among these, a n-butylene group, that is, a group in which carbon adjacent to X in a tetramethylene group is substituted with a heteroatom (for example, an oxygen atom or a sulfur atom), is preferable. In this case, this group (that is, Q²) has 3 carbon atoms.

With regard to the linking group represented by Structural Formula (C), regarding Q², examples of the heteroatom include a nitrogen atom, an oxygen atom, and a sulfur atom. Among these, an oxygen atom and a sulfur atom are preferable, and an oxygen atom is more preferable.

The linking group is preferably a carbonyl group. In a case where the linking group is a carbonyl group, the structure represented by General Formula (Z1-1) is preferably the following structure. In other words, in a case where the linking group is a carbonyl group, Z¹ is preferably the following structure.

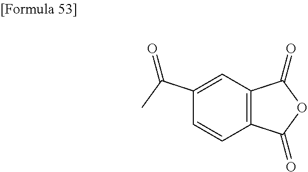

Z¹ other than the structure represented by General Formula (Z1-1) is H, namely, a hydrogen atom, or a structure represented by General Formula (Z1-S). If Z¹ is H, gelation of the polyamic acid solution is likely to occur in some cases. Z¹ is preferably a structure represented by General Formula (Z1-S) for the reason that gelation of the polyamic acid solution can be suppressed.

With regard to Q^{S1} in General Formula (Z1-S), the explanation of Q^{S1}' overlaps with the explanation of R¹ and will be omitted. Hence, the explanation of R¹ can also be treated as the explanation of Q^{S1}. Since there are the most suitable specific examples particular to Q^{S1}, the explanation of the most suitable specific examples will be added. Specifically, Q^{S1}' is preferably a methyl group, an ethyl group, or a phenyl group from the viewpoint of availability of raw materials.

With regard to specific combinations of four Z's, it is preferable that the four Z¹'s are structures represented by General Formula (Z1-1).

The silsesquioxane derivative represented by General Formula AA-D2 can be produced, for example, based on the methods described in the documents cited in the explanation of the production of the silsesquioxane derivative represented by General Formula AA-D1.

The silsesquioxane derivative represented by General Formula AA-D2 can be produced, for example, by a procedure in which a compound in which all Z¹'s are hydrogen atoms or sodium atoms in General Formula AA-D2 is produced and this compound (that is, a compound having a silanol group containing H or Na as Z¹ and O adjacent to Z¹) is reacted with an acid chloride having an acid anhydride group, such as trimellitic anhydride chloride based on these documents. The compound in which all Z¹'s are hydrogen atoms in General Formula AA-D2 is also available as a commercial product (for example, SO1460 manufactured by Hybrid Plastics, Inc.).

Instead of this procedure, the silsesquioxane derivative represented by General Formula AA-D1 can also be produced, for example, by a procedure in which a compound in which all Z¹'s are hydrogen atoms or sodium atoms in General Formula AA-D2 is produced and this compound (that is, a compound having a silanol group containing H or Na as Z¹ and O adjacent to Z¹) is reacted with an organodichlorosilane having a SiH group, such as methyldichlorosilane, and the product (that is, the product having a SiH group) is reacted with a compound having an acid anhydride group.

The silsesquioxane derivative represented by General Formula AA-D1 can also be produced, for example, by producing a compound in which all Z¹'s are hydrogen atoms or sodium atoms in General Formula AA-D2 and conducting a ring-closing reaction (end-capping reaction) of this compound (that is, a compound having a silanol group containing H or Na as Z¹ and O adjacent to Z¹) with a dichlorosilane derivative having an acid anhydride group.

The silsesquioxane derivative represented by General Formula AA-D2 can also be produced, for example, by a procedure in which a compound in which all Z¹'s are hydrogen atoms or sodium atoms in General Formula AA-D2 is produced and this compound (that is, a compound having a silanol group containing H or Na as Z¹ and O adjacent to Z¹) is reacted with an organochlorosilane having a SiH group, such as dimethylchlorosilane, and the product (that is, the product having a SiH group) is reacted with a compound having an acid anhydride group.

Prior to the reaction of a compound having a silanol group (that is, a compound having a silanol group containing H as Z¹ and O adjacent to Z¹) with an acid chloride having an acid anhydride group, such as trimellitic anhydride chloride, or with an organochlorosilane containing a SiH group, some of the silanol groups may be capped. For capping, for example, the compound having a silanol group can be reacted with a triorganochlorosilane such as triphenylchlorosilane. In the reaction of a product having a SiH group with a compound having an acid anhydride group, for example, hydrosilylation can be utilized. In other words, a reaction in which a product having a SiH group is added to an unsaturated bond such as a carbon-carbon double bond, accompanied by cleavage of the Si—H bond can be utilized. In a case where hydrosilylation is utilized, the compound having an acid anhydride group can have an unsaturated bond (for example, a vinyl group) such as a carbon-carbon double bond. Meanwhile, in the reaction of a product having a SiH group with a compound having an acid anhydride group, a coupling reaction, specifically, a coupling reaction of a product having a SiH group with an aryl halide using a precious metal catalyst such as ruthenium, platinum, palladium, or rhodium can be utilized. In a case of utilizing a coupling reaction, the compound having an acid anhydride group or the compound having a functional group convertible into an acid anhydride group can have an aryl halide structure. Examples of the functional group convertible into an acid anhydride group include a diester group.

Needless to say, this explanation (specifically, the explanation of the production of the silsesquioxane derivative represented by General Formula AA-D2, including the explanation of various reactions) can also be treated appropriately as the explanation for producing a silsesquioxane derivative of a structure other than General Formula AA-D2.

The silsesquioxane derivative can be a structure represented by, for example, the following general formula (hereinafter, sometimes referred to as “General Formula AA-C1”)

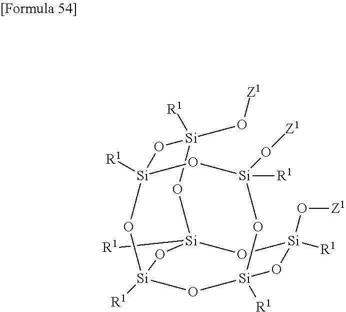

(where R's each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
Z1's are independent of each other,
at least two of Z¹'s are structures represented by General Formula (Z1-1),
X in General Formula (Z1-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these, and
X belonging to Z¹ is linked to 0 adjacent to Z¹ by a linking group,
in a case where Z¹ other than the structure represented by General Formula (Z1-1) is present, Z¹ other than the structure is H or a structure represented by General Formula (Z1-S), and
Q^{S1}'s in General Formula (Z1-S) each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms).

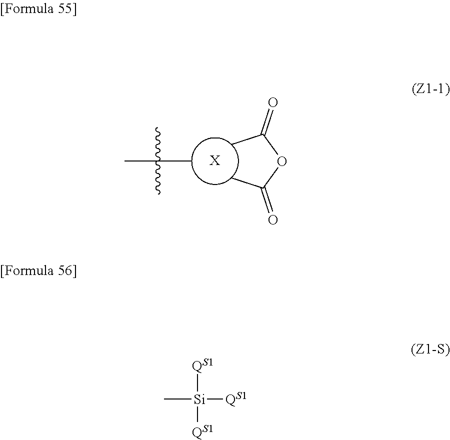

The silsesquioxane derivative represented by General Formula AA-C1 includes all geometric isomers within the scope of General Formula AA-C1. For example, as the geometric isomer represented by General Formula AA-C1, there are geometric isomers in which a pair of R¹ and O—Z¹ bonded to Si are bonded to the ring plane in different directions, and the silsesquioxane derivative represented by General Formula AA-C1 includes these.

The explanation of R¹ in General Formula AA-C1 overlaps with the explanation of R¹ in General Formula AA-D1 and will be omitted. Hence, the explanation of R¹ in General Formula AA-D1 can also be treated as the explanation of R¹ in General Formula AA-C1. Therefore, for example, R¹ is preferably a methyl group, an ethyl group, an isobutyl group, an isooctyl group, a trifluoropropyl group, or a phenyl group, more preferably a phenyl group.

At least two of Z¹'s are structures represented by General Formula (Z1-1). In other words, two of the three Z¹'s may be structures represented by General Formula (Z1-1) or three of the three Z¹'s may be structures represented by General Formula (Z1-1).

With regard to Z¹, X in General Formula (Z1-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these. The explanation of X in General Formula (Z1-1) in General Formula AA-C1 overlaps with the explanation of X in General Formula (Z1-1) in General Formula AA-D1 and will be omitted. Hence, the explanation of X in General Formula (Z1-1) in General Formula AA-D1 can also be treated as the explanation of X in General Formula (Z1-1) in General Formula AA-C1. Therefore, X is preferably a substituted or unsubstituted aromatic ring, for example, for the reason that the yellowing of polyimide (for example, polyimide film) under a high temperature condition of around 400° C. can be further suppressed. From the viewpoint of production difficulty in addition to this, an unsubstituted aromatic ring is more preferable.

Examples of the linking group that links X belonging to Z¹ to 0 adjacent to Z¹ include a substituted or unsubstituted, linear or branched alkylene group, a carbonyl group, a substituted or unsubstituted arylene group, and a group represented by the following Structural Formula (C). The linking groups can be independent of each other. In other words, each linking group can be a unique structure.

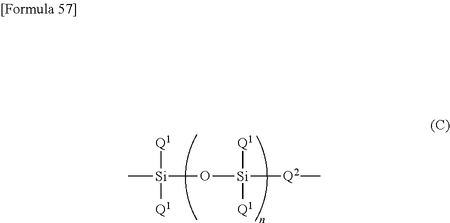

(where Q¹′ₛ each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
n is an integer from 0 to 8,
Q² is a single bond, a substituted or unsubstituted, linear or branched alkylene group, a substituted or unsubstituted arylene group, or a group formed by substituting carbon adjacent to X constituting an alkylene group (specifically, a substituted or unsubstituted, linear or branched alkylene group) with a heteroatom, and
Si at the edge is connected to O adjacent to Z¹, and Q² at the edge is connected to X).
“Q² at the edge is connected to X” means that Si adjacent to Q² at the edge is connected to X in a case where Q² at the edge is a single bond, and an alkylene group, an arylene group, or a group in which carbon adjacent to X constituting an alkylene group is substituted with a heteroatom is connected to X in a case where Q² at the edge is an alkylene group, an arylene group, or a group in which carbon adjacent to X constituting an alkylene group is substituted with a heteroatom.

The explanation of the linking group overlaps with the explanation of the linking group in General Formula AA-D2 and will be omitted. Hence, the explanation of the linking group in General Formula AA-D2 can also be treated as the explanation of the linking group in General Formula AA-C1. Therefore, for example, the linking group is preferably a carbonyl group. In a case where the linking group is a carbonyl group, the structure represented by General Formula (Z1-1) is preferably the following structure. In other words, in a case where the linking group is a carbonyl group, Z¹ is preferably the following structure.

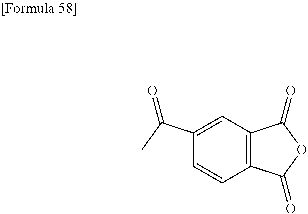

Z¹ other than the structure represented by General Formula (Z1-1) is H, namely, a hydrogen atom, or a structure represented by General Formula (Z1-S). If Z¹ is H, gelation of the polyamic acid solution is likely to occur in some cases. Z¹ is preferably a structure represented by General Formula (Z1-S) for the reason that gelation of the polyamic acid solution can be suppressed.

With regard to Q^{S1}' in General Formula (Z1-S), the explanation of Q^{S1} overlaps with the explanation of R¹ and will be omitted. Hence, the explanation of R¹ can also be treated as the explanation of Q^{S1}. Since there are the most suitable specific examples particular to Q^{S1}, the explanation of the most suitable specific examples will be added. Specifically, Q^{S1} is preferably a methyl group, an ethyl group, or a phenyl group from the viewpoint of availability of raw materials.

With regard to specific combinations of three Z¹'s, it is preferable that two of Z¹'s are the following structure and one of Z¹'s is a structure represented by General Formula (Z1-S).

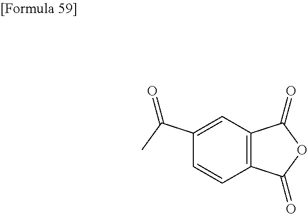

The silsesquioxane derivative represented by General Formula AA-C1 can be produced, for example, by a procedure similar to the procedure described for General Formula AA-D2 except that a compound in which all Z¹'s are hydrogen atoms in General Formula AA-C1 is produced. The compound in which all Z¹'s are hydrogen atoms in General Formula AA-C1 can be produced, for example, based on the method described in the following document.
Chemistry Letters, 2014, Vol. 43, No. 10, pp. 1532-1534

The compound in which all Z¹'s are hydrogen atoms in General Formula AA-C1 is also available as a commercial product (for example, SO1450 and SO1458 manufactured by Hybrid Plastics, Inc.).

The silsesquioxane derivative can be a structure represented by, for example, the following general formula (hereinafter, sometimes referred to as “General Formula AA-Q1”)

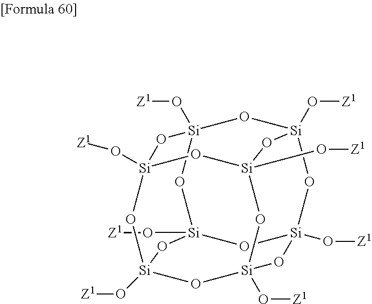

(where Z¹'s are independent of each other,
at least two of Z¹'s are structures represented by General Formula (Z1-1),
X in General Formula (Z1-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these, and
X belonging to Z¹ is linked to 0 adjacent to Z¹ by a linking group,
in a case where Z¹ other than the structure represented by General Formula (Z1-1) is present, Z¹ other than the structure is H or a structure represented by General Formula (Z1-S), and
Q^{S1}'s in General Formula (Z1-S) each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms).

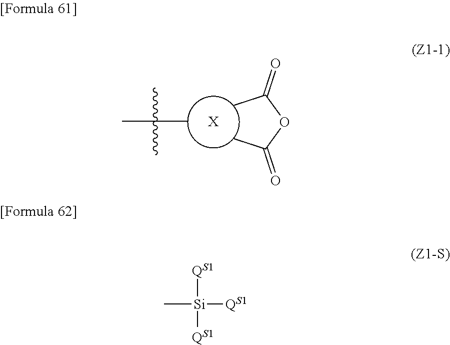

At least two of Z¹'s are structures represented by General Formula (Z1-1). Although all eight Z¹'s may be this structure, it is preferable that two to six of the eight Z¹'s are this structure, it is more preferable that two to four of the eight Z¹'s are this structure, and it is still more preferable that two or three of the eight Z's are this structure.

With regard to Z¹, X in General Formula (Z1-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these. The explanation of X in General Formula (Z1-1) in General Formula AA-Q1 overlaps with the explanation of X in General Formula (Z1-1) in General Formula AA-D1 and will be omitted. Hence, the explanation of X in General Formula (Z1-1) in General Formula AA-D1 can also be treated as the explanation of X in General Formula (Z1-1) in General Formula AA-Q1. Therefore, X is preferably a substituted or unsubstituted aromatic ring, for example, for the reason that the yellowing of polyimide (for example, polyimide film) under a high temperature condition of around 400° C. can be further suppressed. From the viewpoint of production difficulty in addition to this, an unsubstituted aromatic ring is more preferable.

Examples of the linking group that links X belonging to Z¹ to 0 adjacent to Z¹ include a substituted or unsubstituted, linear or branched alkylene group, a carbonyl group, a substituted or unsubstituted arylene group, and a group represented by the following Structural Formula (C). The linking groups can be independent of each other. In other words, each linking group can be a unique structure.

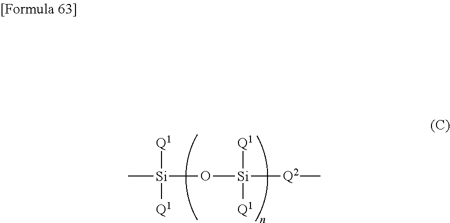

(where Q¹′ₛ each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
n is an integer from 0 to 8,
Q² is a single bond, a substituted or unsubstituted, linear or branched alkylene group, a substituted or unsubstituted arylene group, or a group formed by substituting carbon adjacent to X constituting an alkylene group (specifically, a substituted or unsubstituted, linear or branched alkylene group) with a heteroatom, and
Si at the edge is connected to O adjacent to Z¹, and Q² at the edge is connected to X).
“Q² at the edge is connected to X” means that Si adjacent to Q² at the edge is connected to X in a case where Q² at the edge is a single bond, and an alkylene group, an arylene group, or a group in which carbon adjacent to X constituting an alkylene group is substituted with a heteroatom is connected to X in a case where Q² at the edge is an alkylene group, an arylene group, or a group in which carbon adjacent to X constituting an alkylene group is substituted with a heteroatom.

The explanation of the linking group overlaps with the explanation of the linking group in General Formula AA-D2 and will be omitted. Hence, the explanation of the linking group in General Formula AA-D2 can also be treated as the explanation of the linking group in General Formula AA-Q1.

Z¹ other than the structure represented by General Formula (Z1-1) is H, namely, a hydrogen atom, or a structure represented by General Formula (Z1-S). If Z¹ is H, gelation of the polyamic acid solution is likely to occur in some cases. Z¹ is preferably a structure represented by General Formula (Z1-S) for the reason that gelation of the polyamic acid solution can be suppressed.

With regard to Q^{S1}' in General Formula (Z1-S), the explanation of Q^{S1} overlaps with the explanation of R¹ in General Formula AA-D1 and will be omitted. Hence, the explanation of R¹ in General Formula AA-D1 can also be treated as the explanation of Q^{S1}. Since there are the most suitable specific examples particular to Q^{S1}, the explanation of the most suitable specific examples will be added. Specifically, Q^{S1}' is preferably a methyl group, an ethyl group, or a phenyl group from the viewpoint of availability of raw materials.

The silsesquioxane derivative represented by General Formula AA-Q1 can be produced, for example, by a procedure similar to the procedure described for General Formula AA-D2 except that a compound in which all Z¹'s are hydrogen atoms in General Formula AA-Q1 is produced. The compound in which all Z¹'s are hydrogen atoms in General Formula AA-Q1 can be produced by protonating a tetramethylammonium salt corresponding to the compound in which all Z1's are hydrogen atoms using an acid, for example, based on the method described in the following document.
Chemistry Letters, 2018, Vol. 47, No. 12, pp. 1530-1533

The tetramethylammonium salt corresponding to the compound in which all Z¹'s are hydrogen atoms in General Formula AA-Q1 is also available as a commercial product (for example, MSO860 manufactured by Hybrid Plastics, Inc.).

Examples of the silsesquioxane derivative having a random structure will be described later.

The silsesquioxane derivative can have two or more amino groups. In a case where the silsesquioxane derivative has two or more amino groups, the silsesquioxane derivative can react with a carboxylic acid. The number of amino groups per molecule of the silsesquioxane derivative may be, for example, 3 or more, 4 or more, 5 or more, or 6 or more. The number of amino groups per molecule may be, for example, 10 or less, or 8 or less. In particular, in a case where the silsesquioxane derivative has a cage structure, the number of amino groups per molecule is, for example, preferably 2 or more and 8 or less. Meanwhile, in a case where the silsesquioxane derivative is a random structure, the number of amino groups per molecule is preferably 2 to 10, more preferably 2.5 to 6. When the number of amino groups is within this range, the obtained polyimide chains are properly crosslinked, and the toughness of the polyimide film can be further improved.

In a case where the silsesquioxane derivative has two or more amino groups, the silsesquioxane derivative does not have two or more acid anhydride groups described above.

It is preferable that each amino group has a linking group that links the amino group to Si that is bonded closest to the amino group among Si's constituting the silsesquioxane derivative. The linking group will be described in detail in the explanation of the silsesquioxane derivative represented by General Formula AM-D1 later, and therefore only a brief explanation will be given here in order to avoid duplication. Examples of the linking group include a structure explained in Z² in General Formula AM-D1 described later. In other words, examples of the linking group that links the two (the amino group and Si that is bonded closest to the amino group among Si's constituting the silsesquioxane derivative) include a substituted or unsubstituted, linear or branched alkylene group, a substituted or unsubstituted arylene group, a group represented by Structural Formula (C-S) described later, an ester group (namely, an ester bond), an amide group (namely, an amide bond), and a combination of arbitrary two or more thereof. In addition to this, in a case where an amino group is bonded to the ring represented by Y (see General Formula AM-D1 described later), the linking group can further have a ring represented by Y. In other words, in this case, the linking group can have a substituted or unsubstituted, linear or branched alkylene group, a substituted or unsubstituted arylene group, a group represented by Structural Formula (C-S) described later, an ester group (namely, an ester bond), an amide group (namely, an amide bond), or a combination of arbitrary two or more thereof, as well as can further have a ring represented by Y. Here, in a case where Y is a substituted or unsubstituted aromatic ring, an amino group can be bonded to the substituted or unsubstituted aromatic ring. The linking groups can be independent of each other. In other words, each linking group can be a unique structure.

It is preferable that the linking groups each independently have a substituted or unsubstituted aromatic ring bonded to an amino group. This is because yellowing of polyimide (for example, polyimide film) under a high temperature condition can be further suppressed compared to a case where the linking group has an aliphatic ring instead of an aromatic ring. The substituted or unsubstituted aromatic ring will be described in detail in the explanation of the silsesquioxane derivative represented by General Formula AM-D1 later, and therefore the explanation thereof will be omitted here in order to avoid duplication.

The silsesquioxane derivative can be a structure represented by, for example, the following general formula (hereinafter, sometimes referred to as “General Formula AM-D1”).

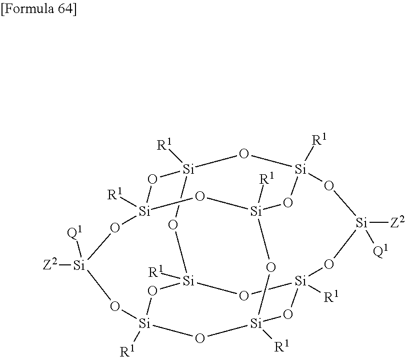

(where R¹'s each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
Q¹'s each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
Z²'s are each independently a structure represented by General Formula (Z2-1) or a structure represented by General Formula (Z2-2),
Y in General Formula (Z2-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these,
Y belonging to Z² and Si adjacent to Z² may be connected by a single bond or linked by a linking group, and
an amino group belonging to General Formula (Z2-2) is linked to Si adjacent to Z² by a linking group).

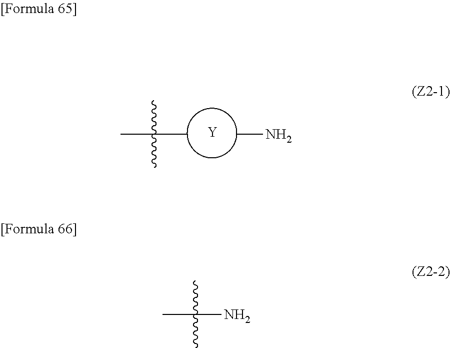

The silsesquioxane derivative represented by General Formula AM-D1 includes all geometric isomers within the scope of General Formula AM-D1. For example, as the geometric isomer represented by General Formula AM-D1, there are geometric isomers in which a pair of Q¹ and Z² bonded to Si are bonded to the ring plane in different directions, and the silsesquioxane derivative represented by General Formula AM-D1 includes these.

The explanation of R¹ in General Formula AM-D1 overlaps with the explanation of R¹ in General Formula AA-D1 and will be omitted. Hence, the explanation of R¹ in General Formula AA-D1 can also be treated as the explanation of R¹ in General Formula AM-D1. Therefore, for example, R¹ is preferably a methyl group, an ethyl group, an isobutyl group, an isooctyl group, a trifluoropropyl group, or a phenyl group, more preferably a phenyl group.

The explanation of Q¹ overlaps with the explanation of R¹ and will be omitted. Hence, the explanation of R¹ can also be treated as the explanation of Q¹. Since there are the most suitable specific examples particular to Q¹, the explanation of the most suitable specific examples will be added. Specifically, Q¹ is preferably a methyl group, an ethyl group, or a phenyl group, more preferably a methyl group for the reason that the production difficulty is relatively not high.

With regard to Z², Y in General Formula (Z2-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these. The explanation of Y in General Formula (Z2-1) in General Formula AM-D1 overlaps with the explanation of X in General Formula (Z1-1) in General Formula AA-D1 and will be omitted. Hence, the explanation of X in General Formula (Z1-1) in General Formula AA-D1 can also be treated as the explanation of Y in General Formula (Z2-1) in General Formula AM-D1. Therefore, Y is preferably a substituted or unsubstituted aromatic ring, for example, for the reason that the yellowing of polyimide (for example, polyimide film) under a high temperature condition of around 400° C. can be further suppressed. From the viewpoint of production difficulty in addition to this, an unsubstituted aromatic ring is more preferable.

Y belonging to Z² and Si adjacent to Z² may be connected by a single bond or linked by a linking group. Examples of the linking group that links the two include a substituted or unsubstituted, linear or branched alkylene group, a substituted or unsubstituted arylene group, a group represented by the following Structural Formula (C-S), an ester group (namely, an ester bond), an amide group (namely, an amide bond), and a combination of arbitrary two or more thereof. The linking groups can be independent of each other. In other words, each linking group can be a unique structure.

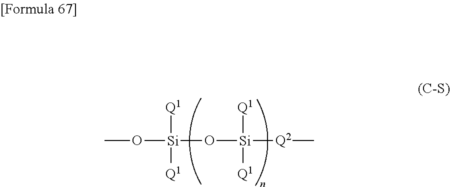

(where Q¹'s each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
n is an integer from 0 to 8,
Q² is a single bond, a substituted or unsubstituted, linear or branched alkylene group, a substituted or unsubstituted arylene group, or a group formed by substituting carbon adjacent to Y constituting an alkylene group (specifically, a substituted or unsubstituted, linear or branched alkylene group) with a heteroatom, and
O at the edge is connected to Si adjacent to Z², and Q² at the edge is connected to Y).
“Q² at the edge is connected to Y” means that Si adjacent to Q² at the edge is connected to Y in a case where Q² at the edge is a single bond, and an alkylene group, an arylene group, or a group in which carbon adjacent to Y constituting an alkylene group is substituted with a heteroatom is connected to Y in a case where Q² at the edge is an alkylene group, an arylene group, or a group in which carbon adjacent to Y constituting an alkylene group is substituted with a heteroatom.

The explanation of the linking group in General Formula AM-D1 overlaps with the explanation of the linking group in General Formula AA-D1 and will be omitted. Hence, the explanation of the linking group in General Formula AA-D1 can also be treated as the explanation of the linking group in General Formula AM-D1.

Therefore, for example, as the linking group, a combination of a substituted or unsubstituted arylene group with an amide group is preferable, and a combination of a p-phenylene group with an amide group is more preferable. Specifically, the following structure is preferable. In the following structural formula, the p-phenylene group is bonded to Si. The amide group is bonded to Y. In other words, carbon constituting the amide group is bonded to Y.

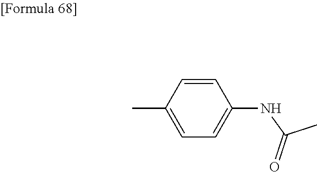

In a case where the two (that is, Y belonging to Z² and Si adjacent to Z²) are linked by this linking group, Z² is preferably the following structure. In this structure, the position of the amino group may be the ortho position, the meta position, or the para position. Among these, the para position is preferable.

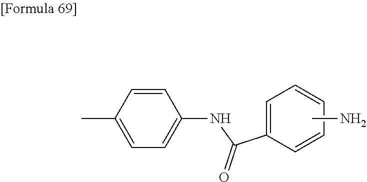

It is preferable that the two (that is, Y belonging to Z² and Si adjacent to Z²) are connected by a single bond. This is because yellowing of polyimide (for example, polyimide film) under a high temperature condition can be further suppressed as the two are connected by a single bond.

In a case where the two are connected by a single bond, the structure represented by General Formula (Z2-1) is preferably the following structure. In other words, in a case where the two are connected by a single bond, Z² is preferably the following structure. In this structure, the position of the amino group may be the ortho position, the meta position, or the para position. Among these, the para position is preferable.

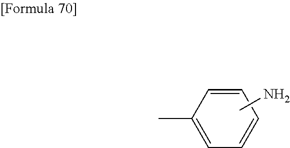

In other words, Z² is more preferably the following structure.

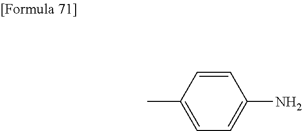

With regard to Z², an amino group belonging to General Formula (Z2-2) is linked to Si adjacent to Z² by a linking group. Examples of the linking group that links the two include a substituted or unsubstituted, linear or branched alkylene group, a substituted or unsubstituted arylene group, a group represented by Structural Formula (C-S) described above, an ester group (namely, an ester bond), an amide group (namely, an amide bond), and a combination of arbitrary two or more thereof. The linking groups can be independent of each other. In other words, each linking group can be a unique structure.

The explanation of the linking group in General Formula (Z2-2) in General Formula AM-D1 overlaps with the explanation of the linking group in General Formula AA-D1 and will be omitted. Hence, the explanation of the linking group in General Formula AA-D1 can also be treated as the explanation of the linking group in General Formula (Z2-2) in General Formula AM-D1. Since there are the most suitable specific examples particular to the linking group in General Formula (Z2-2) in General Formula AM-D1, the explanation of the most suitable specific examples will be added. Specifically, the linking group in General Formula (Z2-2) in General Formula AM-D1 is preferably a substituted or unsubstituted, linear or branched alkylene group, more preferably an unsubstituted linear alkylene group having 6 or less carbon atoms, still more preferably a n-propylene group, namely, a trimethylene group for the reason that the production difficulty is relatively not high.

It is preferable that two Z²'s are both a structure represented by General Formula (Z2-1) or a structure represented by General Formula (Z2-2).

The silsesquioxane derivative represented by General Formula AM-D1 can be produced, for example, based on the methods described in the documents cited in the explanation of the production of the silsesquioxane derivative represented by General Formula AA-D1. The silsesquioxane derivative can be produced, for example, by a procedure similar to the procedure described for General Formula AA-D1 except that a compound having an amino group is used instead of a compound having an acid anhydride group. In the compound having an amino group, the amino group may be protected.

Among the silsesquioxane derivatives represented by General Formula AM-D1, the following silsesquioxane derivative used in Examples described later is described as having been produced in JP-A-2006-265243.

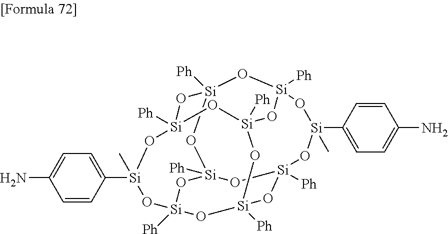

The silsesquioxane derivative can be a structure represented by, for example, the following general formula (hereinafter, sometimes referred to as “General Formula AM-D2”):

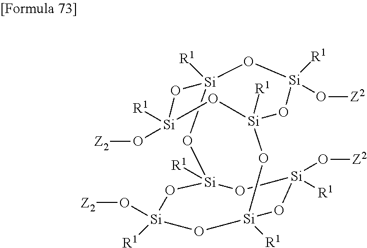

(where R¹'s each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
Z²'s are independent of each other,
at least two of Z²'s are a structure represented by General Formula (Z2-1) or a structure represented by General Formula (Z2-2),
Y in General Formula (Z2-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these,
Y belonging to Z² is linked to 0 adjacent to Z² by a linking group,
an amino group belonging to General Formula (Z2-2) is linked to 0 adjacent to Z² by a linking group,
in a case where Z² other than the structure represented by General Formula (Z2-1) or the structure represented by General Formula (Z2-2) is present, Z² other than these structures is H or a structure represented by General Formula (Z2-S),
and Q^{S1}' in General Formula (Z2-S) each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms).

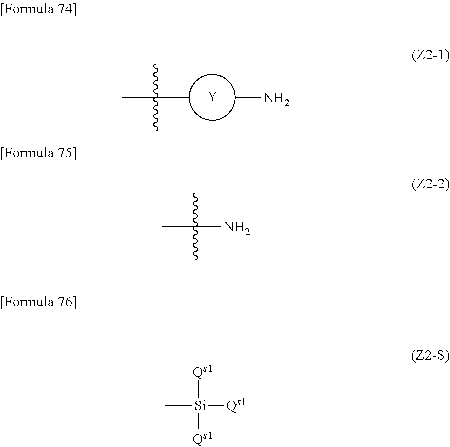

The silsesquioxane derivative represented by General Formula AM-D2 includes all geometric isomers within the scope of General Formula AM-D2. For example, as the geometric isomer represented by General Formula AM-D2, there are geometric isomers in which a pair of R¹ and O—Z² bonded to Si are bonded to the ring plane in different directions, and the silsesquioxane derivative represented by General Formula AM-D2 includes these.

The explanation of R¹ in General Formula AM-D2 overlaps with the explanation of R¹ in General Formula AA-D1 and will be omitted. Hence, the explanation of R¹ in General Formula AA-D1 can also be treated as the explanation of R¹ in General Formula AM-D2. Therefore, for example, R¹ is preferably a methyl group, an ethyl group, an isobutyl group, an isooctyl group, a trifluoropropyl group, or a phenyl group, more preferably a phenyl group.

At least two of Z²'s are each independently a structure represented by General Formula (Z2-1) or a structure represented by General Formula (Z2-2). In other words, two of the four Z²'s may be each independently a structure represented by General Formula (Z2-1) or a structure represented by General Formula (Z2-2), three of the four Z²'s may be each independently a structure represented by General Formula (Z2-1) or a structure represented by General Formula (Z2-2), or four of the four Z²'s may be each independently a structure represented by General Formula (Z2-1) or a structure represented by General Formula (Z2-2).

With regard to Z², Y in General Formula (Z2-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these. The explanation of Y in General Formula (Z2-1) in General Formula AM-D2 overlaps with the explanation of X in General Formula (Z1-1) in General Formula AA-D1 and will be omitted. Hence, the explanation of X in General Formula (Z1-1) in General Formula AA-D1 can also be treated as the explanation of Y in General Formula (Z2-1) in General Formula AM-D2. Therefore, X is preferably a substituted or unsubstituted aromatic ring, for example, for the reason that the yellowing of polyimide (for example, polyimide film) under a high temperature condition of around 400° C. can be further suppressed. From the viewpoint of production difficulty in addition to this, an unsubstituted aromatic ring is more preferable.

Examples of the linking group that links Y belonging to Z² to 0 adjacent to Z² include a substituted or unsubstituted, linear or branched alkylene group, a carbonyl group, a substituted or unsubstituted arylene group, and a group represented by the following Structural Formula (C). The linking groups can be independent of each other. In other words, each linking group can be a unique structure.

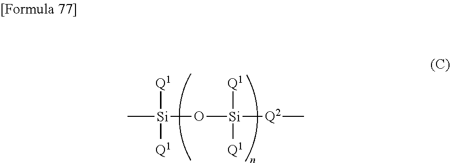

(where Q¹'s each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
n is an integer from 0 to 8,
Q² is a single bond, a substituted or unsubstituted, linear or branched alkylene group, or a group formed by substituting carbon adjacent to Y constituting a substituted or unsubstituted arylene group or an alkylene group (specifically, a substituted or unsubstituted, linear or branched alkylene group) with a heteroatom, and
Si at the edge is connected to O adjacent to Z², and Q² at the edge is connected to Y).
“Q² at the edge is connected to Y” means that Si adjacent to Q² at the edge is connected to Y in a case where Q² at the edge is a single bond, and an alkylene group, an arylene group, or a group in which carbon adjacent to Y constituting an alkylene group is substituted with a heteroatom is connected to Y in a case where Q² at the edge is an alkylene group, an arylene group, or a group in which carbon adjacent to Y constituting an alkylene group is substituted with a heteroatom.

The explanation of the linking group overlaps with the explanation of the linking group in General Formula AA-D2 and will be omitted. Hence, the explanation of the linking group in General Formula AA-D2 can also be treated as the explanation of the linking group in General Formula AM-D2. Therefore, for example, the linking group is preferably a carbonyl group. In a case where the linking group is a carbonyl group, the structure represented by General Formula (Z2-1) is preferably the following structure. In other words, in a case where the linking group is a carbonyl group, Z² is preferably the following structure. In this structure, the position of the amino group may be the ortho position, the meta position, or the para position. Among these, the para position is preferable.

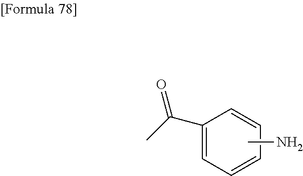

In addition to this, the linking group is also preferably a group represented by Structural Formula (C). In a case where the linking group is a group represented by Structural Formula (C), Z2 is preferably the following structure. In this structure, the position of the amino group may be the ortho position, the meta position, or the para position. Among these, the para position is preferable.

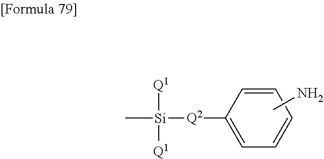

With regard to Z2, examples of the linking group that links the amino group belonging to General Formula (Z2-2) and O adjacent to Z2 include those the same as the examples of the linking group in General Formula (Z2-1). In other words, examples of the linking group include a substituted or unsubstituted, linear or branched alkylene group, a carbonyl group, a substituted or unsubstituted arylene group, and a group represented by Structural Formula (C). The linking groups can be independent of each other. In other words, each linking group can be a unique structure.

The explanation of the linking group in General Formula (Z2-2) in General Formula AM-D2 overlaps with the explanation of the linking group in General Formula AA-D2 and will be omitted. Hence, the explanation of the linking group in General Formula AA-D2 can also be treated as the explanation of the linking group in General Formula (Z2-2) in General Formula AM-D2. Therefore, the linking group is preferably, for example, a group represented by Structural Formula (C). In a case where the linking group is a group represented by Structural Formula (C), Z² is preferably the following structure.

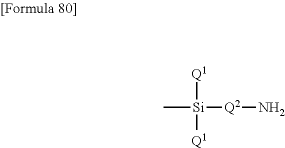

Z² other than the structure represented by General Formula (Z2-1) or the structure represented by General Formula (Z2-2) is H, namely, a hydrogen atom or a structure represented by General Formula (Z2-S). If Z² is H, gelation of the polyamic acid solution is likely to occur in some cases. Z² is preferably a structure represented by General Formula (Z2-S) for the reason that gelation of the polyamic acid solution can be suppressed.

With regard to Q^{S1} in General Formula (Z2-S), the explanation of Q^{S1}' overlaps with the explanation of R¹ and will be omitted. Hence, the explanation of R¹ can also be treated as the explanation of Q^{S1}. Since there are the most suitable specific examples particular to Q^{S1}, the explanation of the most suitable specific examples will be added. Specifically, Q^{S1}' is preferably a methyl group, an ethyl group, or a phenyl group from the viewpoint of availability of raw materials.

With regard to the specific combination of the four Z²'s, it is preferable that four Z²'s are all a structure represented by General Formula (Z2-1) or a structure represented by General Formula (Z2-2).

The silsesquioxane derivative represented by General Formula AM-D2 can be produced, for example, by a procedure similar to the procedure described for General Formula AA-D2 except that a compound having an amino group is used instead of a compound having an acid anhydride group. In the compound having an amino group, the amino group may be protected.

The silsesquioxane derivative can be a structure represented by, for example, the following general formula (hereinafter, sometimes referred to as “General Formula AM-C1”)

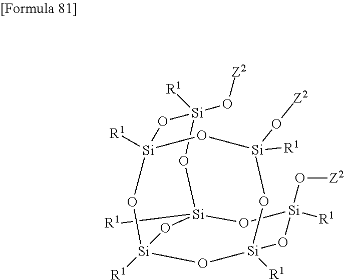

(where R¹ s each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
Z²'s are independent of each other,
at least two of Z²'s are each independently a structure represented by General Formula (Z2-1) or a structure represented by General Formula (Z2-2),
Y in General Formula (Z2-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these,
Y belonging to Z² is linked to 0 adjacent to Z² by a linking group,
an amino group belonging to General Formula (Z2-2) is linked to 0 adjacent to Z² by a linking group,
in a case where Z² other than the structure represented by General Formula (Z2-1) or the structure represented by General Formula (Z2-2) is present, Z² other than these structures is H or a structure represented by General Formula (Z2-S),
and Q^{S1}' in General Formula (Z2-S) each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms).

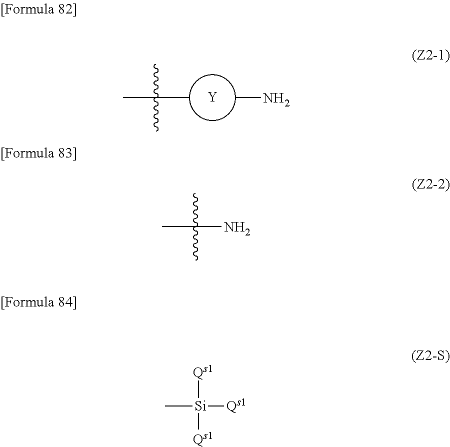

The silsesquioxane derivative represented by General Formula AM-C1 includes all geometric isomers within the scope of General Formula AM-C1. For example, as the geometric isomer represented by General Formula AM-C1, there are geometric isomers in which a pair of R¹ and O—Z² bonded to Si are bonded to the ring plane in different directions, and the silsesquioxane derivative represented by General Formula AM-C1 includes these.

The explanation of R¹ in General Formula AM-C1 overlaps with the explanation of R¹ in General Formula AA-D1 and will be omitted. Hence, the explanation of R¹ in General Formula AA-D1 can also be treated as the explanation of R¹ in General Formula AM-C1. Therefore, for example, R¹ is preferably a methyl group, an ethyl group, an isobutyl group, an isooctyl group, a trifluoropropyl group, or a phenyl group, more preferably a phenyl group.

At least two of Z²'s are each independently a structure represented by General Formula (Z2-1) or a structure represented by General Formula (Z2-2). In other words, two of the three Z²'s may be each independently a structure represented by General Formula (Z2-1) or a structure represented by General Formula (Z2-2) or three of the three Z²'s may be each independently a structure represented by General Formula (Z2-1) or a structure represented by General Formula (Z2-2).

With regard to Z², Y in General Formula (Z2-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these. The explanation of Y in General Formula (Z2-1) in General Formula AM-C1 overlaps with the explanation of X in General Formula (Z1-1) in General Formula AA-D1 and will be omitted. Hence, the explanation of X in General Formula (Z1-1) in General Formula AA-D1 can also be treated as the explanation of Y in General Formula (Z2-1) in General Formula AM-C1. Therefore, Y is preferably a substituted or unsubstituted aromatic ring, for example, for the reason that the yellowing of polyimide (for example, polyimide film) under a high temperature condition of around 400° C. can be further suppressed. From the viewpoint of production difficulty in addition to this, an unsubstituted aromatic ring is more preferable.

Examples of the linking group that links Y belonging to Z² to 0 adjacent to Z² include a substituted or unsubstituted, linear or branched alkylene group, a carbonyl group, a substituted or unsubstituted arylene group, and a group represented by the following Structural Formula (C). The linking groups can be independent of each other. In other words, each linking group can be a unique structure.

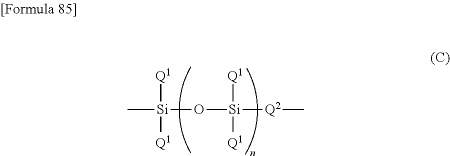

(where Q¹'s each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
n is an integer from 0 to 8, Q² is a single bond, a substituted or unsubstituted, linear or branched alkylene group, or a group formed by substituting carbon adjacent to Y constituting a substituted or unsubstituted arylene group or an alkylene group (specifically, a substituted or unsubstituted, linear or branched alkylene group) with a heteroatom, and
Si at the edge is connected to O adjacent to Z2, and Q² at the edge is connected to Y).
“Q² at the edge is connected to Y” means that Si adjacent to Q² at the edge is connected to Y in a case where Q² at the edge is a single bond, and an alkylene group, an arylene group, or a group in which carbon adjacent to Y constituting an alkylene group is substituted with a heteroatom is connected to Y in a case where Q² at the edge is an alkylene group, an arylene group, or a group in which carbon adjacent to Y constituting an alkylene group is substituted with a heteroatom.

The explanation of the linking group overlaps with the explanation of the linking group in General Formula AA-D2 and will be omitted. Hence, the explanation of the linking group in General Formula AA-D2 can also be treated as the explanation of the linking group in General Formula AM-C1. Therefore, for example, the linking group is preferably a carbonyl group. In a case where the linking group is a carbonyl group, the structure represented by General Formula (Z2-1) is preferably the following structure. In other words, in a case where the linking group is a carbonyl group, Z² is preferably the following structure. In this structure, the position of the amino group may be the ortho position, the meta position, or the para position. Among these, the para position is preferable.

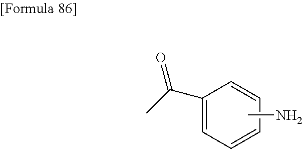

In addition to this, the linking group is also preferably a group represented by Structural Formula (C). In a case where the linking group is a group represented by Structural Formula (C), Z2 is preferably the following structure. In this structure, the position of the amino group may be the ortho position, the meta position, or the para position. Among these, the para position is preferable.

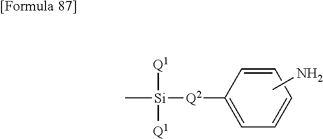

With regard to Z2, examples of the linking group that links the amino group belonging to General Formula (Z2-2) and O adjacent to Z2 include those the same as the examples of the linking group in General Formula (Z2-1). In other words, examples of the linking group include a substituted or unsubstituted, linear or branched alkylene group, a carbonyl group, a substituted or unsubstituted arylene group, and a group represented by Structural Formula (C). The linking groups can be independent of each other. In other words, each linking group can be a unique structure.

The explanation of the linking group in General Formula (Z2-2) in General Formula AM-C1 overlaps with the explanation of the linking group in General Formula AA-D2 and will be omitted. Hence, the explanation of the linking group in General Formula AA-D2 can also be treated as the explanation of the linking group in General Formula (Z2-2) in General Formula AM-C1. Therefore, the linking group is preferably, for example, a group represented by Structural Formula (C). In a case where the linking group is a group represented by Structural Formula (C), Z² is preferably the following structure.

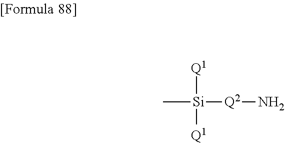

It is preferable that at least two Z²'s are a structure represented by General Formula (Z2-1) or a structure represented by General Formula (Z2-2).

Z² other than the structure represented by General Formula (Z2-1) or the structure represented by General Formula (Z2-2) is H, namely, a hydrogen atom or a structure represented by General Formula (Z2-S). If Z² is H, gelation of the polyamic acid solution is likely to occur in some cases. Z² is preferably a structure represented by General Formula (Z2-S) for the reason that gelation of the polyamic acid solution can be suppressed.

With regard to Q^{S1}' in General Formula (Z2-S), the explanation of Q^{S1} overlaps with the explanation of R¹ and will be omitted. Hence, the explanation of R¹ can also be treated as the explanation of Q^{S1}. Since there are the most suitable specific examples particular to Q^{S1}, the explanation of the most suitable specific examples will be added. Specifically, Q^{S1} is preferably a methyl group, an ethyl group, or a phenyl group from the viewpoint of availability of raw materials.

With regard to specific combinations of three Z²'s, it is preferable that two of Z²'s are the following structure and one of Z²'s is a structure represented by General Formula (Z2-S). In the following structure, the position of the amino group may be the ortho position, the meta position, or the para position. Among these, the para position is preferable.

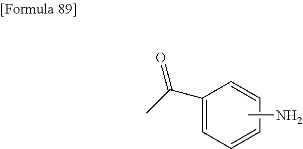

With regard to specific combinations of three Z²'s, it is also preferable that two of Z²'s are the following structure and one of Z²'s is a structure represented by General Formula (Z2-S). In the following structure, the position of the amino group may be the ortho position, the meta position, or the para position. Among these, the para position is preferable.

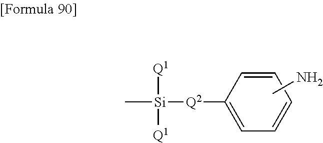

With regard to specific combinations of three Z²'s, it is also preferable that two of Z²'s are the following structure and one of Z²'s is a structure represented by General Formula (Z2-S).

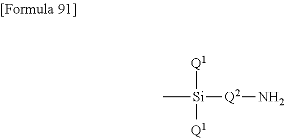

The silsesquioxane derivative represented by General Formula AM-C1 can be produced, for example, by a procedure similar to the procedure described for General Formula AA-C1 except that a compound having an amino group is used instead of a compound having an acid anhydride group. In the compound having an amino group, the amino group may be protected.

The silsesquioxane derivative can be a structure represented by, for example, the following general formula (hereinafter, sometimes referred to as “General Formula AM-Q1”):

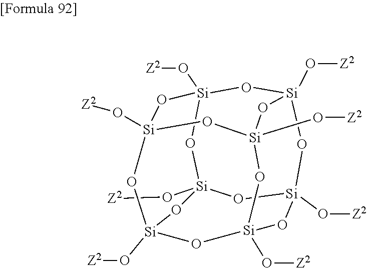

(where Z2's are independent of each other,
at least two of Z2's are each independently a structure represented by General Formula (Z2-1) or a structure represented by General Formula (Z2-2),
Y in General Formula (Z2-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these,
Y belonging to Z2 is linked to 0 adjacent to Z2 by a linking group,
an amino group belonging to General Formula (Z2-2) is linked to 0 adjacent to Z² by a linking group,
in a case where Z² other than the structure represented by General Formula (Z2-1) or the structure represented by General Formula (Z2-2) is present, Z² other than these structures is H or a structure represented by General Formula (Z2-S),
and Q^{S1}' in General Formula (Z2-S) each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms).

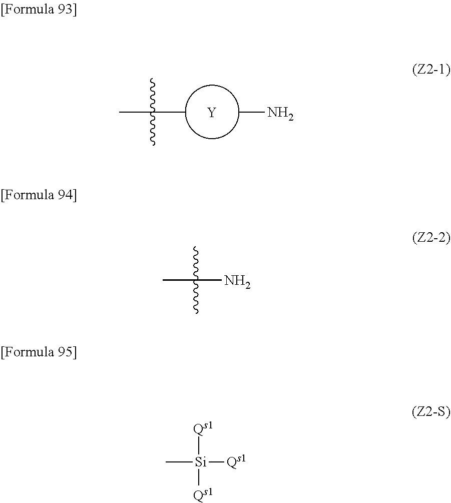

At least two of Z2's are each independently a structure represented by General Formula (Z2-1) or a structure represented by General Formula (Z2-2). All of the eight Z2's may be each independently a structure represented by General Formula (Z2-1) or a structure represented by General Formula (Z2-2), two to six of the eight Z2's may be each independently a structure represented by General Formula (Z2-1) or a structure represented by General Formula (Z2-2), two to four of the eight Z2's may be each independently a structure represented by General Formula (Z2-1) or a structure represented by General Formula (Z2-2), or two or three of the eight Z2's may be each independently a structure represented by General Formula (Z2-1) or a structure represented by General Formula (Z2-2).

With regard to Z2, Y in General Formula (Z2-1) is a substituted or unsubstituted aromatic ring, a substituted or unsubstituted aliphatic ring having 4 to 10 carbon atoms, a heterocycle formed by substituting at least one of carbons constituting these rings with a heteroatom, or a ring formed through condensation of at least two of these. The explanation of Y in General Formula (Z2-1) in General Formula AM-Q1 overlaps with the explanation of X in General Formula (Z1-1) in General Formula AA-D1 and will be omitted. Hence, the explanation of X in General Formula (Z1-1) in General Formula AA-D1 can also be treated as the explanation of Y in General Formula (Z2-1) in General Formula AM-Q1. Therefore, Y is preferably a substituted or unsubstituted aromatic ring, for example, for the reason that the yellowing of polyimide (for example, polyimide film) under a high temperature condition of around 400° C. can be further suppressed. From the viewpoint of production difficulty in addition to this, an unsubstituted aromatic ring is more preferable.

Examples of the linking group that links Y belonging to Z² to 0 adjacent to Z² include a substituted or unsubstituted, linear or branched alkylene group, a carbonyl group, a substituted or unsubstituted arylene group, and a group represented by the following Structural Formula (C). The linking groups can be independent of each other. In other words, each linking group can be a unique structure.

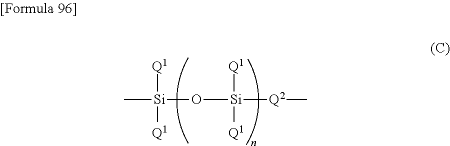

(where Q¹'s each independently represent a substituted or unsubstituted, linear or branched alkyl group having 1 to 9 carbon atoms,
a substituted or unsubstituted aryl group having 15 or less carbon atoms, or
a substituted or unsubstituted arylalkyl group having 15 or less carbon atoms,
n is an integer from 0 to 8, Q² is a single bond, a substituted or unsubstituted, linear or branched alkylene group, a substituted or unsubstituted arylene group, or a group formed by substituting carbon adjacent to Y constituting an alkylene group (specifically, a substituted or unsubstituted, linear or branched alkylene group) with a heteroatom, and Si at the edge is connected to O adjacent to Z2, and
Q² at the edge is connected to Y). “Q² at the edge is connected to Y” means that Si adjacent to Q² at the edge is connected to Y in a case where Q² at the edge is a single bond, and an alkylene group, an arylene group, or a group in which carbon adjacent to Y constituting an alkylene group is substituted with a heteroatom is connected to Y in a case where Q² at the edge is an alkylene group, an arylene group, or a group in which carbon adjacent to Y constituting an alkylene group is substituted with a heteroatom.

The explanation of the linking group overlaps with the explanation of the linking group in General Formula AA-D2 and will be omitted. Hence, the explanation of the linking group in General Formula AA-D2 can also be treated as the explanation of the linking group in General Formula AM-Q1.

With regard to Z², examples of the linking group that links the amino group belonging to General Formula (Z2-2) and O adjacent to Z² include those the same as the examples of the linking group in General Formula (Z2-1). In other words, examples of the linking group include a substituted or unsubstituted, linear or branched alkylene group, a carbonyl group, a substituted or unsubstituted arylene group, and a group represented by Structural Formula (C). The linking groups can be independent of each other. In other words, each linking group can be a unique structure.

The explanation of the linking group in General Formula (Z2-2) in General Formula AM-Q1 overlaps with the explanation of the linking group in General Formula AA-D2 and will be omitted. Hence, the explanation of the linking group in General Formula AA-D2 can also be treated as the explanation of the linking group in General Formula (Z2-2) in General Formula AM-Q1.

Z² other than the structure represented by General Formula (Z2-1) or the structure represented by General Formula (Z2-2) is H, namely, a hydrogen atom or a structure represented by General Formula (Z2-S). If Z² is H, gelation of the polyamic acid solution is likely to occur in some cases. Z² is preferably a structure represented by General Formula (Z2-S) for the reason that gelation of the polyamic acid solution can be suppressed.

With regard to Q^{S1}' in General Formula (Z2-S), the explanation of Q^{S1} overlaps with the explanation of R¹ in General Formula AA-D1 and will be omitted. Hence, the explanation of R¹ in General Formula AA-D1 can also be treated as the explanation of Q^{S1}. Since there are the most suitable specific examples particular to Q^{S1}, the explanation of the most suitable specific examples will be added. Specifically, Q^{S1}' is preferably a methyl group, an ethyl group, or a phenyl group from the viewpoint of availability of raw materials.

The silsesquioxane derivative represented by General Formula AM-Q1 can be produced, for example, by a procedure similar to the procedure described for General Formula AA-Q1 except that a compound having an amino group is used instead of a compound having an acid anhydride group. In the compound having an amino group, the amino group may be protected.

### <Example of Silsesquioxane Derivative Having Random Structure: Silsesquioxane Compound A>

Example of the silsesquioxane derivative having a random structure include a silsesquioxane compound A having two or more acid anhydride groups, which will be described below. The silsesquioxane compound A is a novel silsesquioxane compound.

The novel silsesquioxane compound A is a silsesquioxane compound obtained by reacting a thiol group of a condensate B, which is a thiol group-containing silsesquioxane compound, with a reactive group of a dicarboxylic anhydride C having at least one reactive group selected from a vinyl group, an alkenyl group, a cycloalkenyl group, an alkynyl group, or an acid chloride group.

The condensate B is a condensate B of a thiol group-containing trialkoxysilane a1 represented by General Formula: R¹Si(OR²)₃:
(where R¹ represents an organic group in which at least one hydrogen atom of an aliphatic hydrocarbon group, alicyclic hydrocarbon group, or aromatic hydrocarbon group having 1 to 8 carbon atoms is substituted with a thiol group and R²'s each independently represent a hydrogen atom or an aliphatic hydrocarbon group, alicyclic hydrocarbon group, or aromatic hydrocarbon group having 1 to 8 carbon atoms),
and a trialkoxysilane a2 not having a thiol group.

The structure of the silsesquioxane compound A can also be partly identified as two repeating units. In other words, the novel silsesquioxane compound A preferably has structural units represented by the following General Formulas (1) and (2).

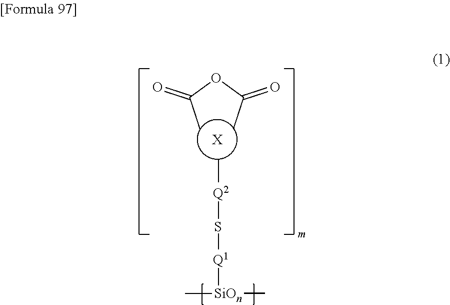

(where Q¹ represents an aliphatic hydrocarbon group, alicyclic hydrocarbon group, or aromatic hydrocarbon group having 1 to 8 carbon atoms, Q² is a single bond, a hydrocarbon group having 1 to 8 carbon atoms, an organic group in which one or more carbon atoms of a hydrocarbon group having 1 to 8 carbon atoms are substituted with oxygen, or a carbonyl group, X is a carbon-carbon bond, or an aliphatic ring having 4 to 10 carbon atoms, an aromatic ring, or a heterocycle formed by substituting some of carbons constituting these with oxygen or sulfur, one or more of hydrogens bonded to these may be substituted with a hydrocarbon group, and 1.0 m 2.0 and 1.4 n 1.6), and

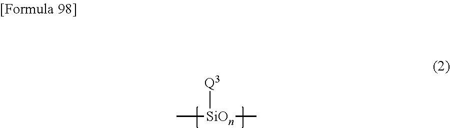

(where Q³ represents an aliphatic hydrocarbon group, alicyclic hydrocarbon group, or aromatic hydrocarbon group having 1 to 8 carbon atoms and 1.4≤n≤1.6).

The novel silsesquioxane compound A can be suitably produced, for example, by a production method including the following steps in order.

A first step of subjecting a thiol group-containing trialkoxysilane a1, a trialkoxysilane a2 not having a thiol group, and water to a hydrolysis reaction in the presence of an acid catalyst to obtain a reaction mixture x, wherein the thiol group-containing trialkoxysilane a1 is represented by General Formula: R¹Si(OR²)₃:
(where R¹ represents an organic group in which at least one hydrogen atom of an aliphatic hydrocarbon group, alicyclic hydrocarbon group, or aromatic hydrocarbon group having 1 to 8 carbon atoms is substituted with a thiol group and R²'s each independently represent a hydrogen atom or an aliphatic hydrocarbon group, alicyclic hydrocarbon group, or aromatic hydrocarbon group having 1 to 8 carbon atoms);
a second step of removing the acid catalyst from the reaction mixture x to obtain a reaction mixture y;
a third step of mixing the reaction mixture y with a polar solvent containing a base catalyst and conducting condensation to obtain a condensate B having a thiol group; and
a fourth step of reacting the condensate B with a dicarboxylic anhydride C having at least one reactive group selected from a vinyl group, an alkenyl group, a cycloalkenyl group, an alkynyl group, or an acid chloride group.

The novel silsesquioxane compound A can also be obtained by reacting a commercially available thiol group-containing silsesquioxane compound (condensate B) with the dicarboxylic anhydride C having at least one reactive group selected from a vinyl group, an alkenyl group, a cycloalkenyl group, an alkynyl group, or an acid chloride group.

### <Condensate B (Thiol Group-Containing Silsesquioxane Compound)>

The condensate B is a condensate of a thiol group-containing trialkoxysilane a1 and a trialkoxysilane a2 not having a thiol group. As the condensate B, for example, organic-inorganic hybrid resin COMPOCERAN SQ (product name: SQ107 or SQ109, ARAKAWA CHEMICAL INDUSTRIES, LTD.) can be used. Alternatively, the condensate B synthesized by a method including the steps 1 to 3 can be used.

### First Step

The first step is a step of subjecting a thiol group-containing trialkoxysilane a1 represented by General Formula: R¹Si(OR²)₃, a trialkoxysilane a2 not having a thiol group, and water to a hydrolysis reaction in the presence of an acid catalyst to obtain a reaction mixture x:
(where R¹ represents an organic group in which at least one hydrogen atom of an aliphatic hydrocarbon group, alicyclic hydrocarbon group, or aromatic hydrocarbon group having 1 to 8 carbon atoms is substituted with a thiol group and R²'s each independently represent a hydrogen atom or an aliphatic hydrocarbon group, alicyclic hydrocarbon group, or aromatic hydrocarbon group having 1 to 8 carbon atoms).

Here, “1 to 8 carbon atoms” qualify the aliphatic hydrocarbon group, alicyclic hydrocarbon group, and aromatic hydrocarbon group, but in relation to the minimum number of carbon atoms, more accurately mean an aliphatic hydrocarbon group having 1 to 8 carbon atoms, an alicyclic hydrocarbon group having 4 to 8 carbon atoms, or an aromatic hydrocarbon group having 6 to 8 carbon atoms. The limitation of the number of carbon atoms, such as “1 to 8 carbon atoms”, refers to the total number of carbon atoms in an organic group including a substituent.

In more detail, in the general formula, R¹ represents an organic group in which at least one hydrogen atom of a linear or branched or aliphatic ring-containing hydrocarbon group having 1 to 8 carbon atoms or an aromatic hydrocarbon group having 6 to 8 carbon atoms, which may have a hydrocarbon group, is substituted with a thiol group. R¹ is preferably a linear hydrocarbon group from the viewpoint of imparting flexibility to the polymer chain and is preferably an alicyclic hydrocarbon group or an aromatic hydrocarbon group from the viewpoint of enhancing heat resistance.

R²'s each independently represent a hydrogen atom, a linear or branched or aliphatic ring-containing hydrocarbon group having 1 to 8 carbon atoms, or an aromatic hydrocarbon group having 6 to 8 carbon atoms, which may have a hydrocarbon group. R² is preferably an alkyl group having 1 to 4 carbon atoms from the viewpoint of reactivity in the hydrolysis reaction. R² is particularly preferably a methyl group or an ethyl group.

Specific examples of the thiol group-containing trialkoxysilane a1 (hereinafter referred to as component (a1)) include 3-mercaptopropyltrimethoxysilane, 3-mercaptopropyltriethoxysilane, 3-mercaptopropyltripropoxysilane, 3-mercaptopropyltributoxysilane, 1,4-dimercapto-2-(trimethoxysilyl)butane, 1,4-dimercapto-2-(triethoxysilyl)butane, 1,4-dimercapto-2-(tripropoxysilyl)butane, 1,4-dimercapto-2-(tributoxysilyl)butane, 2-mercaptomethyl-3-mercaptopropyltrimethoxysilane, 2-mercaptomethyl-3-mercaptopropyltriethoxysilane, 2-mercaptomethyl-3-mercaptopropyltripropoxysilane, 2-mercaptomethyl-3-mercaptopropyltributoxysilane, 1,2-dimercaptoethyltrimethoxysilane, 1,2-dimercaptoethyltriethoxysilane, 1,2-dimercaptoethyltripropoxysilane, and 1,2-dimercaptoethyltributoxysilane. The exemplified compounds can be used singly or in appropriate combination. Among the exemplified compounds, 3-mercaptopropyltrimethoxysilane is particularly preferable since this compound exhibits high reactivity in the hydrolysis reaction and is easily available.

Examples of the trialkoxysilane a2 not having a thiol group (hereinafter referred to as component (a2)) include a compound represented by General Formula: R³Si(OR²)₃: (where R³ represents an aliphatic hydrocarbon group, alicyclic hydrocarbon group, or aromatic hydrocarbon group having 1 to 8 carbon atoms and R²'s each independently represent a hydrogen atom or an aliphatic hydrocarbon group, alicyclic hydrocarbon group, or aromatic hydrocarbon group having 1 to 8 carbon atoms).

In more detail, R³ represents a linear or branched or aliphatic ring-containing hydrocarbon group having 1 to 8 carbon atoms or an aromatic hydrocarbon group having 6 to 8 carbon atoms, which may have a hydrocarbon group. R² is as described for the component (a1), and may be the same as or different from R² in the component (a1).

Specific examples of the component (a2) that can be used include methyltrimethoxysilane, methyltriethoxysilane, ethyltrimethoxysilane, ethyltriethoxysilane, phenyltrimethoxysilane, and phenyltriethoxysilane. The component (a2) may be used singly or in combination of two or more kinds. The amount of thiol groups can be adjusted by using these, and this makes it possible to adjust the degree of crosslinking in the finally obtained polyimide or to increase the proportion of inorganic components in the polyimide.

The molar ratio of the trialkoxysilane a2 ([number of moles of a2]/[number of moles of a1+number of moles of a2]) in the alkoxysilane is preferably 0.1 or more and 0.7 or less, more preferably 0.2 or more and 0.7 or less. The amount of thiol groups contained per molecule is smaller as this molar ratio is larger, and the amount of thiol groups is larger as the value is smaller. As the molar ratio is within this range, the obtained polyimide chains are properly crosslinked, and the effect of improving physical properties also becomes sufficient.

The condensate B, which is a thiol group-containing silsesquioxane, can be obtained using the components (a1) and (a2) through hydrolysis of these and then condensation. In the first step, the alkoxy groups contained in the components (a1) and (a2) are converted into silanol groups by the hydrolysis reaction, and an alcohol is produced as a by-product.

The amount of water required for the hydrolysis reaction is preferably 0.4 to 10 in terms of molar ratio ([number of moles of water used in hydrolysis reaction]/[total number of moles of alkoxy groups contained in components (a1) and (a2)]). In a case where this molar ratio is 0.4 or more and less than 0.5, some alkoxy groups remain in the obtained thiol group-containing silsesquioxane, but the close contact property to inorganic materials can be improved. In a case where this molar ratio is 0.5 to 10, alkoxy groups substantially do not remain in the obtained thiol group-containing silsesquioxane, and a thick-film cured product is likely to be produced.

In addition to the components (a1) and (a2), dialkoxysilanes and/or tetraalkoxysilanes can also be further used within a range (for example, 50 mol % or less) in which the effects of the present invention are not impaired.

As the catalyst used in the hydrolysis reaction, an acid catalyst capable of functioning as a conventionally known catalyst for hydrolysis can be arbitrarily used. However, since it is necessary to substantially remove the acid catalyst after the hydrolysis reaction, the acid catalyst is preferably one that is easily removable. Examples of such an acid catalyst include formic acid that has a low boiling point and can be removed by pressure reduction and solid acid catalysts that can be easily removed by methods such as filtration.

Examples of the solid acid catalysts include cation exchange resins, activated clay, and carbon-based solid acids. Among these, cation exchange resins exhibit high catalytic activity and are easily available, and are thus preferable. As the cation exchange resins, a strongly acidic cation exchange resin and a weakly acidic cation exchange resin can be used. Examples of the strongly acidic ion exchange resin include the DIAION SK series, DIAION UBK series, DIAION PK series, and DIAION HPK25 and PCP series (all trade names manufactured by Mitsubishi Chemical Group Corporation); Amberlite IR120B, Amberlite IR124, Amberlite 200CT, Amberlite 252, Amberjet 1020, Amberjet 1024, Amberjet 1060, Amberjet 1220, Amberlyst 15DRY, Amberlyst 15JWET, Amberlyst 16WET, Amberlyst 31WET, and Amberlyst 35WET (all trade names manufactured by ORGANO CORPORATION). Examples of the weakly acidic ion exchange resin include DIAION WK series and DIAION WK40 (all trade names manufactured by Mitsubishi Chemical Group Corporation) and Amberlite FPC3500 and Amberlite IRC76 (all trade names manufactured by ORGANO CORPORATION). The type of ion exchange resin to be used can be selected arbitrarily depending on the reaction rate, suppression of side reactions, and the like, but a strongly acidic ion exchange resin is particularly preferable from the viewpoint of reactivity.

The amount of the acid catalyst added is preferably 0.1 to 25 parts by mass, more preferably 1 to 10 parts by mass with respect to 100 parts by mass of the sum of the components (a1) and (a2). When the amount of the acid catalyst added is 25 parts by mass or less, it is easy to remove the acid catalyst in a later step, and this tends to be economically advantageous. Meanwhile, when the amount of the acid catalyst added is 0.1 parts by mass or more, the reaction can proceed properly and the reaction time tends not to be too long.

The reaction temperature and time can be set arbitrarily depending on the reactivity of the components (a1) and (a2), but are usually about 0° C. to 100° C., preferably 20° C. to 60° C. and about 1 minute to 2 hours. The hydrolysis reaction can be conducted in the presence or absence of a solvent, but it is preferable not to use a solvent. In a case of using a solvent, the kind of solvent is not particularly limited, and one or more kinds of arbitrary solvents can be selected and used, but it is preferable to use the same solvent as that used in the condensation reaction described later.

### Second Step

The second step is a step of removing the acid catalyst from the reaction mixture x to obtain a reaction mixture y. In other words, after the completion of the hydrolysis reaction in the first step, it is necessary to substantially remove the acid catalyst from the system. In a case where the acid catalyst is not removed, the condensation reaction described later may not proceed, the silanol groups may not be completely consumed, or the system gels because of an abnormal increase in the molecular weight, and the desired thiol group-containing silsesquioxane (condensate B) cannot be obtained.

The method for removing the acid catalyst can be appropriately selected from various known methods depending on the catalyst used. For example, as described above, formic acid can be easily removed by pressure reduction in a case of using formic acid, and the solid acid catalyst can be easily removed by a method such as filtration after the completion of the condensation reaction in a case of using a solid acid catalyst.

After the hydrolysis reaction is completed and the acid catalyst is removed from the system or at the same time as removal of the acid catalyst, the alcohol produced as a by-product and excess water may be removed by a method such as pressure reduction. As dilution with the solvent used in the condensation reaction is performed after removal, the addition of the hydrolysis reaction product in the subsequent condensation reaction can also be facilitated.

### Third Step

The third step is a step of mixing the reaction mixture y with a polar solvent containing a base catalyst and conducting condensation to obtain a condensate B having a thiol group. In the condensation reaction, water is produced as a by-product by the silanol groups, alcohol is produced as a by-product and a siloxane bond is formed by the silanol group and the alkoxy group. In the condensation reaction, a base catalyst capable of functioning as a conventionally known catalyst for dehydration condensation can be arbitrarily used.

The base catalyst is preferably one exhibiting high basicity, and specific examples thereof include alkali salts such as sodium hydroxide (NaOH), potassium hydroxide (KOH), and calcium hydroxide (Ca(OH)₂), organic amines such as 1,8-diazabicyclo[5.4.0]undec-7-ene and 1,5-diazabicyclo[4.3.0]non-5-ene, and ammonium hydroxides such as tetramethylammonium hydroxide and tetrabutylammonium hydroxide. The exemplified compounds can be used singly or in appropriate combination. Among the exemplified compounds, tetramethylammonium hydroxide exhibits high catalytic activity and is easily available, and is thus particularly preferable. In a case of using these base catalysts in the form of an aqueous solution, the hydrolysis reaction proceeds during the step of condensation reaction as well, and it is necessary to appropriately adjust the amount of water used during hydrolysis, for example, by decreasing the amount of water in advance by the amount of water contained in the base catalyst.

The amount of the base catalyst added is preferably 0.01 to 5 parts by mass, more preferably 0.1 to 2 parts by mass with respect to 100 parts by mass of the sum of the components (a1) and (a2). When the amount of the base catalyst added is 5 parts by mass or less, the cured product produced using the obtained thiol group-containing silsesquioxane (condensate B) is less likely to be colored, and the step of performing the removal tends to be facilitated in a case of removing the catalyst. Meanwhile, when the amount of the base catalyst added is 0.01 parts by mass or more, the reaction can proceed properly and the reaction time tends not to be too long.

The reaction temperature can be set arbitrarily depending on the reactivity of the components (a1) and (a2), but is usually about 40° C. to 150° C., preferably 60° C. to 100° C. The condensation reaction is preferably conducted in the presence of a polar solvent, and it is more preferable not to contain a non-polar solvent such as toluene from the viewpoint of stability of the obtained silsesquioxane compound A and an amic acid solution that is a copolymer thereof, and the quality of the obtained film.

As the polar solvent, a polar solvent that is compatible with water is preferable, and glycol ethers are particularly preferable. Among the glycol ethers, dialkyl glycol ether-based solvents are particularly preferable. Examples of the dialkyl glycol ether-based solvents compatible with water include ethylene glycol dimethyl ether, diethylene glycol dimethyl ether, triethylene glycol dimethyl ether, diethylene glycol methyl ethyl ether, and diethylene glycol diethyl ether. It is also possible to use glycol ether acetate-based solvents such as propylene glycol monomethyl ether acetate (PGMEA), dipropylene glycol monomethyl ether acetate, and propylene glycol monoethyl ether acetate.

The condensation reaction can be conducted by a method in which the reaction temperature is set and a solution containing the hydrolysate obtained in the hydrolysis reaction is sequentially added to a polar solvent to which the catalyst for dehydration condensation is added. The method of addition can be appropriately selected from various known methods. The time required for addition can be set arbitrarily depending on the reactivity of the components (a1) and (a2), but is usually about 30 minutes to 12 hours.

When the condensation reaction is conducted by the method, it is preferable to conduct the reaction until unreacted silanol groups are substantially eliminated. It is not preferable that unreacted silanol groups remain since the storage stability of the obtained thiol group-containing silsesquioxane (condensate B) and the composition containing the condensate B decreases or the heat resistance decreases.

It is preferable to conduct the reaction so that the total molar ratio of unreacted alkoxy groups ([total number of moles of unreacted alkoxy groups]/[total number of moles of alkoxy groups contained in components (a1) and (a2)]) is 0.2 or less, and it is still more preferable to conduct the reaction so that the total molar ratio is substantially 0. It is preferable that this molar ratio is more than 0 and 0.2 or less since some alkoxy groups remain in the obtained thiol group-containing silsesquioxane (condensate B) but the close contact property to inorganic materials is improved. It is particularly preferable to set the molar ratio to 0 since alkoxy groups substantially do not remain and a thick-film cured product is likely to be produced, and since the cage structure contained in the obtained thiol group-containing silsesquioxane (condensate B) is maximized and the heat resistance of the cured product is improved. In a case where the molar ratio is not 0, there is a tendency that the amount of random silsesquioxane contained in the obtained condensate B is large and the molecular weight (Mw) of the condensate B is large.

The condensation reaction is conducted after the components (a1) and (a2) are diluted with a solvent so that the total concentration thereof is preferably about 2% to 80% by mass, more preferably 15% to 75% by mass. It is preferable to use a solvent having a boiling point higher than the boiling points of water and alcohol produced by the condensation reaction since it it possible to distill off these from the reaction system. It is preferable that the concentration is 2% by mass or more since the amount of thiol group-containing silsesquioxane (condensate B) contained in the obtained curable composition is sufficient. In a case where the concentration is 80% by mass or less, gelation during the reaction is less likely to occur, and the molecular weight of the produced condensate B tends to be proper.

It is preferable to remove the catalyst used after the completion of the condensation reaction since the stability of the thiol group-containing silsesquioxane (condensate B) and the polyimide containing the condensate B is improved. The method of removal can be appropriately selected from various known methods depending on the catalyst used. For example, in a case of using tetramethylammonium hydroxide, tetramethylammonium hydroxide can be removed by a method such as adsorption with a cation exchange resin and removal after the completion of the condensation reaction.

### Fourth Step

The fourth step is a step of reacting the condensate B with a dicarboxylic anhydride C having at least one reactive group selected from a vinyl group, an alkenyl group, a cycloalkenyl group, an alkynyl group, or an acid chloride group.

As the dicarboxylic anhydride C (hereinafter referred to as component (C)), a dicarboxylic anhydride having a functional group capable of reacting with a thiol group is used. For example, a dicarboxylic anhydride having a vinyl group, an acrylic group, a methacrylic group, an allyl group, an alkenyl group, a cycloalkenyl group, an alkynyl group, or an acid chloride group can be used. Still more preferably, a dicarboxylic anhydride having a vinyl group, an alkenyl group, a cycloalkenyl group, an alkynyl group, or an acid chloride group can be used. In particular, as the dicarboxylic anhydride C, the following structure is desirable.

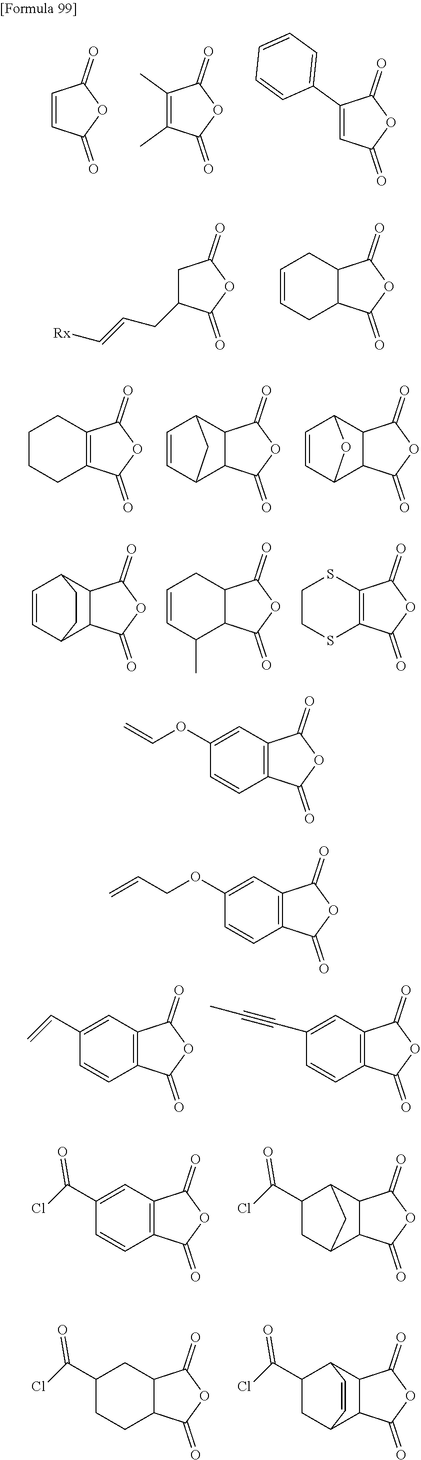

Among these, the following compounds and compounds having an acid chloride group exhibit high reactivity and are particularly preferable. In a case of using a dicarboxylic anhydride C exhibiting low reactivity, it is preferable to use a catalyst for oxidation such as oxygen or iron chloride concurrently since it is difficult to completely proceed with the reaction using only UV light.

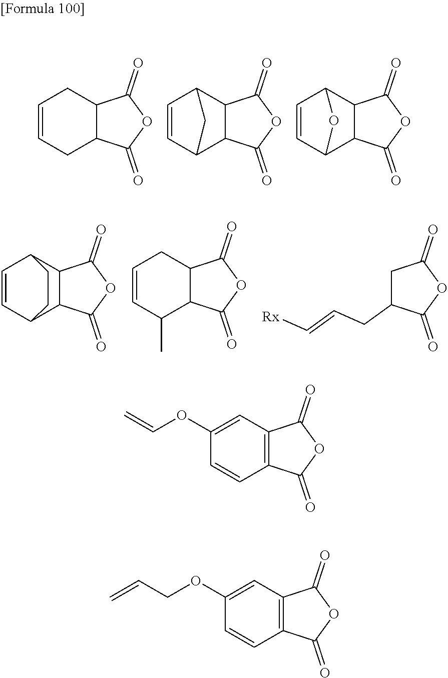

Among the dicarboxylic anhydrides C, a phthalic anhydride compound having an aromatic ring structure is desirable from the viewpoint of enhancing the heat resistance of the obtained polyimide and suppressing yellowing under a high temperature condition, and maleic anhydride and cyclohexanedicarboxylic anhydride, which have an alicyclic structure in the structure, are desirable from the viewpoint of enhancing colorless transparency.

For the reaction of the thiol group-containing silsesquioxane (condensate B) with the dicarboxylic anhydride C, the thiol-ene reaction, or the reaction between a thiol group and an acid chloride group, can be utilized.

In the case of the thiol-ene reaction, it is known that the reaction mechanism varies depending on the kind of carbon-carbon double bond and the presence or absence of a radical polymerization initiator. In other words, it is preferable to use a compound having low radically polymerizable vinyl group or allyl group as the component (C) since only the ene-thiol reaction proceeds, and the thiol group in the condensate B reacts with the carbon-carbon double bond in the component (C) at a molar ratio of approximately 1:1. Meanwhile, in a case of using a compound having a highly radically polymerizable acrylic group or methacrylic group as the component (C), particularly in a case of using a radical polymerization initiator concurrently, the polymerization reaction of the carbon-carbon double bond in the component (C) also proceeds in parallel, the thiol group in the condensate B reacts with the carbon-carbon double bond in the component (C) at a molar ratio of about 1:1 to 100, and therefore the effects of the invention may not be fully achieved. From the viewpoints, in a case of using a compound having low radically polymerizable vinyl group or allyl group as the component (C), the component (C) is blended so that the molar ratio ([number of moles of thiol group contained in condensate B]/[number of moles of carbon-carbon double bond contained in component (C)]) is preferably 0.9 to 2.5, more preferably 1.0. In a case where this molar ratio is 0.9 or more, carbon-carbon double bonds are less likely to remain after ultraviolet curing, and the weather resistance tends to be improved. In a case where this molar ratio is 2.5 or less, the crosslink density of the cured product becomes sufficient, and the heat resistance tends to be improved.

As the initiator for the thiol-ene reaction, an ultraviolet light source, an organic material, an inorganic material, and oxygen can be used. As the ultraviolet light source, for example, a high-pressure mercury lamp, a halogen lamp, a xenon lamp, or an ultraviolet LED can be used.

The initiator that can be used is not particularly limited, and conventionally known photocationic initiators, photoradical initiators, oxidizing agents, and the like can be arbitrarily selected. Examples of the photocationic initiators include sulfonium salts, iodonium salts, metallocene compounds, and benzoin tosylates, which are compounds that generate acids by being irradiated with ultraviolet light, and examples of commercially available products thereof include CYRACURE UVI-6970, CYRACURE UVI-6974, and CYRACURE UVI-6990 (all trade names manufactured by Union Carbide Corporation, USA), Irgacure 264 (manufactured by BASF), and CIT-1682 (manufactured by Nippon Soda Co., Ltd.). The amount of the photocationic polymerization initiator used is usually about 10 parts by mass or less, preferably 1 to 5 parts by mass with respect to 100 parts by mass of the composition.

Examples of the photoradical initiators include Darocur 1173, Irgacure 651, Irgacure 184, and Irgacure 907 (all trade names manufactured by BASF SE), and benzophenone, and the amount of the photoradical initiator is about 5 parts by mass or less, preferably 0.1 to 2 parts by mass with respect to 100 parts by mass of the composition. The reaction can be accelerated by adding an oxidizing agent such as iron oxide or iron chloride. However, for base film applications required to exhibit high heat resistance and transparency, it is desirable to conduct the reaction using an ultraviolet light source and oxygen without using a photoreaction initiator and a photosensitizer.

In the case of the reaction between a thiol group and an acid chloride group, it is preferable to add a dicarboxylic anhydride having an acid chloride group with an equivalent that is equal to or more than the sum of the amount of thiol groups and the amount of silanol groups in the silsesquioxane (condensate B). When the amount of dicarboxylic anhydride having an acid chloride group added is small, hydrochloric acid that is produced as a by-product acts as a catalyst to cause condensation between silanol groups, and there is a tendency that gelation is likely to occur, and this harmful effect is likely to be diminished when the amount of dicarboxylic anhydride added is more. In that case, the unreacted acid chloride groups may be copolymerized into the polyamic acid to produce a polyamideimide.

In the case of the reaction between a thiol group and an acid chloride group, hydrochloric acid is generated as a by-product, so a base may be added as a pH adjuster. As the base, organic bases, tertiary amines and inorganic bases can be used. Examples of the organic bases include N,N-dimethylacetamide, N,N-diethylacetamide, N,N-dimethylformamide, N,N-diethylformamide, N-methyl-2-pyrrolidone, 1,3-dimethyl-2-imidazolidinone, imidazole, N-methylcaprolactam, imidazole, N,N-dimethylaniline, and N,N-diethylaniline. Examples of the tertiary amines include pyridine, collidine, lutidine and triethylamine. Examples of the inorganic bases include potassium hydroxide, sodium hydroxide, potassium carbonate, sodium carbonate, potassium bicarbonate and sodium bicarbonate. However, for base film applications required to exhibit high heat resistance and transparency, it is desirable to conduct the reaction using a volatile base. By removing hydrochloric acid by the addition of a base or heating of the solution, gelation due to the overreaction of silsesquioxane can be suppressed.

Examples of the solvent that is used in the reaction include the following substances. Benzene, toluene, xylene, mesitylene, pentane, hexane, heptane, octane, nonane, decane, N,N-dimethylacetamide, N,N-diethylacetamide, N,N-dimethylformamide, N,N-diethylformamide, N-methyl-2-pyrrolidone, 1,3-dimethyl-2-imidazolidinone, imidazole, N-methylcaprolactam, dimethyl sulfoxide, diethyl sulfoxide, dimethyl sulfone, diethyl sulfone, hexamethylsulfonamide, cresol, phenol, xylenol, diethylene glycol dimethyl ether (diglyme), triethylene glycol dimethyl ether (triglyme), tetraglyme, propylene glycol monomethyl ether acetate (PGMEA), dioxane, tetrahydrofuran, and γ-butyrolactone. At least two of these may be used in mixture. In particular, when the productivity and optical properties of the film are taken into consideration, it is preferable to use N,N-dimethylacetamide, or N-methyl-2-pyrrolidone, or γ-butyrolactone as the main component of the organic solvent. In addition to these organic solvents, poor solvents such as toluene and xylene may be used to the extent to which the polyimide-based resin or its precursor is not precipitated.

The silsesquioxane compound A having an acid anhydride group, which is obtained in the fourth step, can be used as a solution after the reaction, but can be used as a powder after foreign matter and gel-like matter are filtered out or the solvent is distilled off.

### <Structure of Silsesquioxane Compound a Having Acid Anhydride Group>

The silsesquioxane compound A that can be obtained as described above preferably has structural units represented by the following General Formulas (1) and (2), and more preferably has only structural units represented by General Formulas (1) and (2).

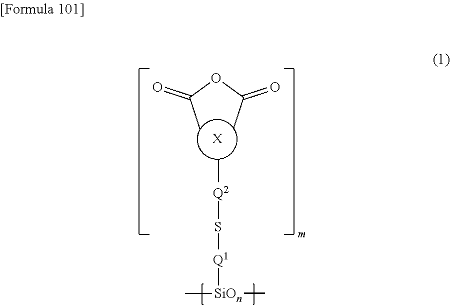

(where Q¹ represents an aliphatic hydrocarbon group, alicyclic hydrocarbon group, or aromatic hydrocarbon group having 1 to 8 carbon atoms, Q² is a single bond, a hydrocarbon group having 1 to 8 carbon atoms, an organic group in which one or more carbon atoms of a hydrocarbon group having 1 to 8 carbon atoms are substituted with oxygen, or a carbonyl group, X is a carbon-carbon bond, or an aliphatic ring having 4 to 10 carbon atoms, an aromatic ring, or a heterocycle formed by substituting some of carbons constituting these with oxygen or sulfur, one or more of hydrogens bonded to these may be substituted with a hydrocarbon group, and 1.0 m 2.0 and 1.4 n 1.6), and

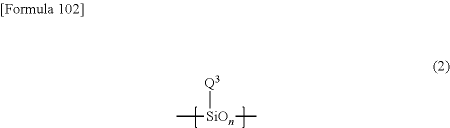

(where Q³ represents an aliphatic hydrocarbon group, alicyclic hydrocarbon group, or aromatic hydrocarbon group having 1 to 8 carbon atoms and 1.4 n 1.6).

In more detail, Q¹ in General Formula (1) represents a linear or branched or aliphatic ring-containing hydrocarbon group having 1 to 8 carbon atoms, or an aromatic hydrocarbon group having 6 to 8 carbon atoms, which may have a hydrocarbon group. Q¹ is preferably a linear hydrocarbon group from the viewpoint of imparting flexibility to the polymer chain and is preferably an alicyclic hydrocarbon group or an aromatic hydrocarbon group from the viewpoint of enhancing heat resistance.

Specific examples of Q¹ include a hydrocarbon group or aromatic hydrocarbon group to which the Si atom and the S atom of the compound exemplified as the thiol group-containing trialkoxysilane a1 are bonded.

Q² is a single bond, a linear or branched hydrocarbon group having 1 to 8 carbon atoms, an oxygen-containing hydrocarbon group formed by substituting one or more carbon atoms of the hydrocarbon group with oxygen, or a carbonyl group. Q² is preferably a linear hydrocarbon group from the viewpoint of imparting flexibility to the polymer chain and is preferably a single bond, an alicyclic hydrocarbon group, or an aromatic hydrocarbon group from the viewpoint of enhancing heat resistance.

X is a carbon-carbon bond or an aliphatic ring having 4 to 10 carbon atoms, an aromatic ring having 6 to 10 carbon atoms, or a heterocycle formed by substituting some of carbons constituting these with oxygen or sulfur, and one or more of hydrogens bonded to these may be substituted with a hydrocarbon group. X is preferably a carbon-carbon bond from the viewpoint of imparting flexibility to the polymer chain and is preferably a single bond, an alicyclic hydrocarbon group, or an aromatic hydrocarbon group from the viewpoint of enhancing heat resistance. In particular, it is preferable that X is an aromatic hydrocarbon group from the viewpoints of enhancing heat resistance as well as suppressing discoloration under a high temperature condition.

Specific examples of Q² and X include moieties of the reactive residues of the compounds exemplified as the dicarboxylic anhydride C excluding the dicarboxylic anhydride group. The following chemical formulas show examples in a case where X is a heterocycle formed by substituting some of carbons constituting an aliphatic ring or aromatic ring with oxygen or sulfur.

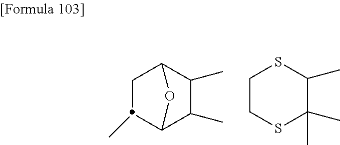

With regard to m, 1.0≤m≤2.0 is satisfied, and m is preferably 1 from the viewpoint of diminishing steric hindrance and enhancing the reactivity of the dicarboxylic anhydride group. In a case where m is 1.0≤m≤2.0 (that is, other than an integer), a compound having one thiol group and a compound having two thiol groups are used concurrently as the component (a1).

With regard to n, 1.4≤n≤1.6 is satisfied, and n is preferably 1.5 from the viewpoint of forming a more uniform three-dimensional structure. The reason why n is assumed to be other than 1.5 is that it is permitted for the raw material to contain not only trialkoxysilanes, but also small amounts of dialkoxysilanes and tetraalkoxysilanes.

Q³ in General Formula (2) represents a linear or branched or aliphatic ring-containing hydrocarbon group having 1 to 8 carbon atoms or an aromatic hydrocarbon group having 6 to 8 carbon atoms, which may have a hydrocarbon group. Q³ is preferably a short-chain or branched hydrocarbon group or an aromatic hydrocarbon group from the viewpoint of suppressing crystallization and improving heat resistance. Specific examples of Q³ include a hydrocarbon group or aromatic hydrocarbon group, which is bonded to the Si atom of the compound exemplified as the trialkoxysilane a2.

In the silsesquioxane compound A having structural units represented by General Formulas (1) and (2), the molar ratio of the structural unit represented by General Formula (2) ([structural unit (2)]/[structural unit (1)+structural unit (2)]) is preferably 0.1 or more and 0.7 or less, more preferably 0.2 or more and 0.7 or less. The amount of thioether or thioester groups contained per molecule is smaller as this molar ratio is larger, and the amount of thioether or thioester groups is larger as the value is smaller. As the molar ratio is within this range, the obtained polyimide chains are properly crosslinked, and the effect of improving physical properties also becomes sufficient.

The number of acid anhydride groups (number of functional groups) per molecule of the silsesquioxane compound A is preferably 2 to 10, more preferably 2.5 to 6. As the number of functional groups is within this range, the obtained polyimide chains are properly crosslinked, and the effect of improving physical properties also becomes sufficient.

The molecular weight of the silsesquioxane compound A is preferably 400 to 5,000, more preferably 600 to 3,000. When the molecular weight is within this range, the obtained polyimide is less likely to become ununiform and a uniform crosslinked structure is likely to be attained.

General Formulas (1) and (2) tend to be randomly bonded, but as General Formulas (1) and (2) are bonded regularly, a silsesquioxane compound of a cage type (including a double-decker type), a partly opened cage type, or a ladder type can be obtained.

Examples of the method for obtaining the silsesquioxane compound A of such a structure include a method in which a cage-type or partly opened cage-type, or ladder-type silsesquioxane compound is obtained in advance at the stage of the condensate B (thiol group-containing silsesquioxane compound), and a method in which a commercially available thiol group-containing silsesquioxane compound having such a structure is used.

The condensate B can be synthesized by dehydration condensation of dialkylsilanediol or by dehydrochlorination reaction of dialkylsilanediol and dialkyldichlorosilane.

By adjusting the used catalyst and solvent and the matrix concentration, the production ratio of a specific structure can be increased. The specific structure can be isolated by purifying the obtained product by methods such as recrystallization, solvent washing, and column separation. The method is not particularly limited, and for example, the methods described in the review literatures ((1) “Silicon Expanding Application Fields and Technical Trends” written by Yoshiaki Ono, published by The Chemical Daily; (2) “Science of Silicon” written by Nobuo Matsumoto, published by Institute of Electronics, Information and Communication Engineers; (3) “Latest Application Technology of Silicon”, edited by Makoto Kumada and Tadashi Wada, published by CMC Publishing; (4) “Selection and Optimal Use Technology of Silicon Compounds”, edited by the Technical Information Association; (5) “Organic Silicon Science in the 21st Century”, supervised by Kohei Tamao, published by CMC Publishing; (6) “Chemistry and Applications of Silsesquioxane Materials”, edited by Masaki Ito, published by CMC Publishing; and the like can be adopted. T^{H}₈, a kind of cage structure, can be synthesized, for example, by hydrolysis of trichlorosilane in the presence of iron chloride (Bull. Chem. Soc. Jpn., 73, 215 (2000)). Various derivatives can be synthesized by further chemically modifying T^{H}₈ as a starting material. For example, in the case of introducing an organic group by hydrosilylation of T^{H}₈, the organic group is introduced by reacting T^{H}s with an alkenyl compound in the presence of a platinum catalyst. The reaction of T^{H}₈ with chlorine gives T^{C1}₈, which can be further reacted with methyl orthoformate to introduce a methoxy group. T^{Ph}₄T^{Ph}₃(ONa)₃ that is a double-decker structure is produced almost quantitatively by hydrolysis of trimethoxy(phenyl)silane in the presence of sodium hydroxide. Examples of the method for synthesizing the condensate B having a ladder structure include a method in which the condensate B is synthesized by hydrolysis of trichloro(phenyl)silane and then an alkaline equilibration reaction using potassium hydroxide as a catalyst (Chem. Rev., 95, 1409 (1995)), and a method in which the condensate B is synthesized by hydrolytic polycondensation of trichloro(phenyl)silane using a phase transfer catalyst (Bulletin of the Society of Silicon Chemistry, Japan, (8), 16 (1997)).

### <Polyamic Acid>

In the present invention, the polyamic acid is a copolymerization reaction product of at least a silsesquioxane derivative (that is, a silsesquioxane compound), a carboxylic acid, and a diamine as described above.

In particular, in a case wherein a silsesquioxane compound having more than two acid anhydride groups is used as the silsesquioxane compound, the silsesquioxane compound as a copolymerization component can form a crosslinked structure in the polyimide.

By using a polyamic acid containing a silsesquioxane compound as a copolymerization component, a polyimide film having improved easily slipping properties can be produced. The polyimide film can be obtained, for example, by a process including a step of synthesizing polyamic acid in a solution, a step of forming the polyamic acid solution into a film, and a step of imidizing the polyamic acid.

### <Synthesis of Polyamic Acid>

The synthesis of polyamic acid can be carried out, for example, by reacting at least a carboxylic acid, a diamine, and a silsesquioxane compound in a solvent. In other words, at least a carboxylic acid and a diamine can be used as monomer components other than the silsesquioxane compound.

The carboxylic acid is not particularly limited, and examples thereof include alicyclic tetracarboxylic anhydrides and aromatic tetracarboxylic anhydrides, tricarboxylic acids, and dicarboxylic acids, which are commonly used in polyimide synthesis, polyamideimide synthesis, and polyamide synthesis, and the like can be used. Aromatic tetracarboxylic anhydrides are preferable from the viewpoint of heat resistance, and alicyclic tetracarboxylic anhydrides are preferable from the viewpoint of transparency. These may be used singly or two or more kinds thereof may be used concurrently.

Examples of the alicyclic tetracarboxylic anhydrides in the present invention include tetracarboxylic acids such as 1,2,3,4-cyclobutanetetracarboxylic acid, 1,2,3,4-cyclopentanetetracarboxylic acid, 1,2,3,4-cyclohexanetetracarboxylic acid, 1,2,4,5-cyclohexanetetracarboxylic acid, 3,3′,4,4′-bicyclohexyltetracarboxylic acid, bicyclo[2,2,1]heptane-2,3,5,6-tetracarboxylic acid, bicyclo[2,2,2]octane-2,3,5,6-tetracarboxylic acid, bicyclo[2,2,2]oct-7-ene-2,3,5,6-tetracarboxylic acid, tetrahydroanthracene-2,3,6,7-tetracarboxylic acid, tetradecahydro-1,4:5,8:9,10-trimethanoanthracene-2,3,6,7-tetracarboxylic acid, decahydronaphthalene-2,3,6,7-tetracarboxylic acid, decahydro-1,4:5,8-dimethanonaphthalene-2,3,6,7-tetracarboxylic acid, decahydro-1,4-ethano-5,8-methanonaphthalene-2,3,6,7-tetracarboxylic acid, norbornane-2-spiro-α-cyclopentanone-α′-spiro-2″-norbornane-5,5″,6,6″-tetracarboxylic acid (also known as “norbornane-2-spiro-2′-cyclopentanone-5′-spiro-2″-norbornane-5,5″,6,6″-tetracarboxylic acid”), methylnorbornane-2-spiro-α-cyclopentanone-α′-spiro-2″-(methylnorbornane)-5,5″,6,6″-tetracarboxylic acid, norbornane-2-spiro-α-cyclohexanone-α′-spiro-2″-norbornane-5,5″,6,6″-tetracarboxylic acid (also known as “norbornane-2-spiro-2′-cyclohexanone-6′-spiro-2″-norbornane-5,5″,6,6″-tetracarboxylic acid”), methylnorbornane-2-spiro-α-cyclohexanone-α′-spiro-2″-(methylnorbornane)-5,5″,6,6″-tetracarboxylic acid, norbornane-2-spiro-α-cyclopropanone-α′-spiro-2″-norbornane-5,5″,6,6″-tetracarboxylic acid, norbornane-2-spiro-α-cyclobutanone-α′-spiro-2″-norbornane-5,5″,6,6″-tetracarboxylic acid, norbornane-2-spiro-α-cycloheptanone-α′-spiro-2″-norbornane-5,5″,6,6″-tetracarboxylic acid, norbornane-2-spiro-α-cyclooctanone-α′-spiro-2″-norbornane-5,5″,6,6″-tetracarboxylic acid, norbornane-2-spiro-α-cyclononanone-α′-spiro-2″-norbornane-5,5″,6,6″-tetracarboxylic acid, norbornane-2-spiro-α-cyclodecanone-α′-spiro-2″-norbornane-5,5″,6,6″-tetracarboxylic acid, norbornane-2-spiro-α-cycloundecanone-α′-spiro-2″-norbornane-5,5″,6,6″-tetracarboxylic acid, norbornane-2-spiro-α-cyclododecanone-α′-spiro-2″-norbornane-5,5″,6,6″-tetracarboxylic acid, norbornane-2-spiro-α-cyclotridecanone-α′-spiro-2″-norbornane-5,5″,6,6″-tetracarboxylic acid, norbornane-2-spiro-α-cyclotetradecanone-α′-spiro-2″-norbornane-5,5″,6,6″-tetracarboxylic acid, norbornane-2-spiro-α-cyclopentadecanone-α′-spiro-2″-norbornane-5,5″,6,6″-tetracarboxylic acid, norbornane-2-spiro-α-(methylcyclopentanone)-α′-spiro-2″-norbornane-5,5″,6,6″-tetracarboxylic acid, and norbornane-2-spiro-α-(methylcyclohexanone)-α′-spiro-2″-norbornane-5,5″,6,6′-tetracarboxylic acid, and anhydrides thereof.

Among these, dianhydrides having two acid anhydride structures are suitable, particularly 1,2,3,4-cyclobutanetetracarboxylic dianhydride, 1,2,3,4-cyclohexanetetracarboxylic dianhydride, and 1,2,4,5-cyclohexanetetracarboxylic dianhydride are preferable, 1,2,3,4-cyclobutanetetracarboxylic dianhydride and 1,2,4,5-cyclohexanetetracarboxylic dianhydride are more preferable, and 1,2,3,4-cyclobutanetetracarboxylic dianhydride is still more preferable. These may be used singly or two or more kinds thereof may be used concurrently.

Examples of the aromatic tetracarboxylic anhydrides in the present invention include tetracarboxylic acids such as 4,4′-(2,2-hexafluoroisopropylidene)diphthalic acid, 4,4′-oxydiphthalic acid, bis(1,3-dioxo-1,3-dihydro-2-benzofuran-5-carboxylic acid)1,4-phenylene, bis(1,3-dioxo-1,3-dihydro-2-benzofuran-5-yl)benzene-1,4-dicarboxylate, 4,4′-[4,4′-(3-oxo-1,3-dihydro-2-benzofuran-1,1-diyl)bis(benzene-1,4-diyloxy)]dibenzene-1,2-dicarboxylic acid, 3,3′,4,4′-benzophenonetetracarboxylic acid, 4,4′-[(3-oxo-1,3-dihydro-2-benzofuran-1,1-diyl)bis(toluene-2,5-diyloxy)]dibenzene-1,2-dicarboxylic acid, 4,4′-[(3-oxo-1,3-dihydro-2-benzofuran-1,1-diyl)bis(1,4-xylene-2,5-diyloxy)]dibenzene-1,2-dicarboxylic acid, 4,4′-[4,4′-(3-oxo-1,3-dihydro-2-benzofuran-1,1-diyl)bis(4-isopropyl-toluene-2,5-diyloxy)]dibenzene-1,2-dicarboxylic acid, 4,4′-[4,4′-(3-oxo-1,3-dihydro-2-benzofuran-1,1-diyl)bis(naphthalene-1,4-diyloxy)]dibenzene-1,2-dicarboxylic acid, 4,4′-[4,4′-(3H-2,1-benzoxathiol-1,1-dioxide-3,3-diyl)bis(benzene-1,4-diyloxy)]dibenzene-1,2-dicarboxylic acid, 4,4′-benzophenonetetracarboxylic acid, 4,4′-[(3H-2,1-benzoxathiol-1,1-dioxide-3,3-diyl)bis(toluene-2,5-diyloxy)]dibenzene-1,2-dicarboxylic acid, 4,4′-[(3H-2,1-benzoxathiol-1,1-dioxide-3,3-diyl)bis(1,4-xylene-2,5-diyloxy)]dibenzene-1,2-dicarboxylic acid, 4,4′-[4,4′-(3H-2,1-benzoxathiol-1,1-dioxide-3,3-diyl)bis(4-isopropyl-toluene-2,5-diyloxy)]dibenzene-1,2-dicarboxylic acid, 4,4′-[4,4′-(3H-2,1-benzoxathiol-1,1-dioxide-3,3-diyl)bis(naphthalene-1,4-diyloxy)]dibenzene-1,2-dicarboxylic acid, 3,3′,4,4′-benzophenonetetracarboxylic acid, 3,3′,4,4′-benzophenonetetracarboxylic acid, 3,3′,4,4′-diphenylsulfonetetracarboxylic acid, 3,3′,4,4′-biphenyltetracarboxylic acid, 2,3,3′,4′-biphenyltetracarboxylic acid, pyromellitic acid, 4,4′-[spiro(xanthene-9,9′-fluorene)-2,6-diylbis(oxycarbonyl)]diphthalic acid, and 4,4′-[spiro(xanthene-9,9′-fluorene)-3,6-diylbis(oxycarbonyl)]diphthalic acid; and anhydrides thereof. The aromatic tetracarboxylic acids may be used singly or two or more kinds thereof may be used concurrently.

Examples of the tricarboxylic acids include aromatic tricarboxylic acids such as trimellitic acid, 1,2,5-naphthalenetricarboxylic acid, diphenyl ether-3,3′,4′-tricarboxylic acid, and diphenylsulfone-3,3′,4′-tricarboxylic acid, or hydrogenated products of the aromatic tricarboxylic acids such as hexahydrotrimellitic acid, and alkylene glycol bistrimellitates such as ethylene glycol bistrimellitate, propylene glycol bistrimellitate, 1,4-butanediol bistrimellitate, and polyethylene glycol bistrimellitate and monoanhydrides and esterified products thereof. Among these, monoanhydrides having one acid anhydride structure are suitable, and particularly trimellitic anhydride and hexahydrotrimellitic anhydride are preferable. These may be used singly or a plurality of these may be used in combination.

Examples of the dicarboxylic acids include aromatic dicarboxylic acids such as terephthalic acid, isophthalic acid, orthophthalic acid, naphthalenedicarboxylic acid, and 4,4′-oxydibenzenecarboxylic acid, or hydrogenated products of the aromatic dicarboxylic acids such as 1,6-cyclohexanedicarboxylic acid, and oxalic acid, succinic acid, glutaric acid, adipic acid, heptanedioic acid, octanedioic acid, azelaic acid, sebacic acid, undecanedioic acid, dodecanedioic acid, and 2-methylsuccinic acid and acid chlorides or esterified products thereof. Among these, aromatic dicarboxylic acids and hydrogenated products thereof are suitable, and particularly terephthalic acid, 1,6-cyclohexanedicarboxylic acid, and 4,4′-oxydibenzenecarboxylic acid are preferable. The dicarboxylic acids may be used singly or a plurality of these may be used in combination.

The carboxylic acids are particularly preferably one or more compounds represented by chemical formulas selected from the following.

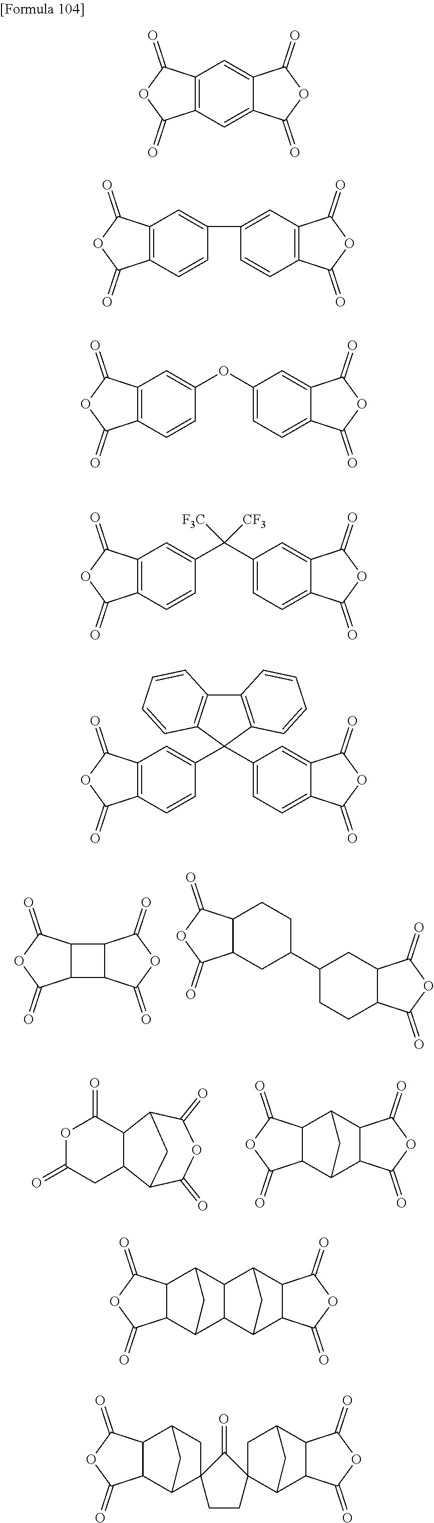

In other words, it is preferable that the polyamic acid has structural units derived from one or more compounds among these. The polyamic acid may not have a structural unit derived from 3,3′,4,4′-biphenyltetracarboxylic dianhydride, namely, BPDA.

The diamine in the present invention is not particularly limited, and aromatic diamines, aliphatic diamines, and alicyclic diamines, which are commonly used in polyimide synthesis, polyamideimide synthesis, and polyamide synthesis, can be used. Aromatic diamines are preferable from the viewpoint of heat resistance, and alicyclic diamines are preferable from the viewpoint of transparency. The diamines can be used singly or two or more kinds thereof may be used concurrently.

Examples of the aromatic diamines include 2,2′-dimethyl-4,4′-diaminobiphenyl, 1,4-bis[2-(4-aminophenyl)-2-propyl]benzene, 1,4-bis(4-amino-2-trifluoromethylphenoxy)benzene, 2,2′-ditrifluoromethyl-4,4′-diaminobiphenyl, 4,4′-bis(4-aminophenoxy)biphenyl, 4,4′-bis(3-aminophenoxy)biphenyl, bis[4-(3-aminophenoxy)phenyl]ketone, bis[4-(3-aminophenoxy)phenyl]sulfide, bis[4-(3-aminophenoxy)phenyl]sulfone, 2,2-bis[4-(3-aminophenoxy)phenyl]propane, 2,2-bis[4-(3-aminophenoxy)phenyl]-1,1,1,3,3,3-hexafluoropropane, m-phenylenediamine, o-phenylenediamine, p-phenylenediamine, m-aminobenzylamine, p-aminobenzylamine, 4-amino-N-(4-aminophenyl)benzamide, 3,3′-diaminodiphenyl ether, 3,4′-diaminodiphenyl ether, 4,4′-diaminodiphenyl ether, 2,2′-trifluoromethyl-4,4′-diaminodiphenyl ether, 3,3′-diaminodiphenyl sulfide, 3,4′-diaminodiphenyl sulfide, 4,4′-diaminodiphenyl sulfide, 3,3′-diaminodiphenyl sulfoxide, 3,4′-diaminodiphenyl sulfoxide, 4,4′-diaminodiphenyl sulfoxide, 3,3′-diaminodiphenyl sulfone, 3,4′-diaminodiphenyl sulfone, 4,4′-diaminodiphenyl sulfone, 3,3′-diaminobenzophenone, 3,4′-diaminobenzophenone, 4,4′-diaminobenzophenone, 3,3′-diaminodiphenylmethane, 3,4′-diaminodiphenylmethane, 4,4′-diaminodiphenylmethane, bis[4-(4-aminophenoxy)phenyl]methane, 1,1-bis[4-(4-aminophenoxy)phenyl]ethane, 1,2-bis[4-(4-aminophenoxy)phenyl]ethane, 1,1-bis[4-(4-aminophenoxy)phenyl]propane, 1,2-bis[4-(4-aminophenoxy)phenyl]propane, 1,3-bis[4-(4-aminophenoxy)phenyl]propane, 2,2-bis[4-(4-aminophenoxy)phenyl]propane, 1,1-bis[4-(4-aminophenoxy)phenyl]butane, 1,3-bis[4-(4-aminophenoxy)phenyl]butane, 1,4-bis[4-(4-aminophenoxy)phenyl]butane, 2,2-bis[4-(4-aminophenoxy)phenyl]butane, 2,3-bis[4-(4-aminophenoxy)phenyl]butane, 2-[4-(4-aminophenoxy)phenyl]-2-[4-(4-aminophenoxy)-3-methylphenyl]propane, 2,2-bis[4-(4-aminophenoxy)-3-methylphenyl]propane, 2-[4-(4-aminophenoxy)phenyl]-2-[4-(4-aminophenoxy)-3,5-dimethylphenyl]propane, 2,2-bis[4-(4-aminophenoxy)-3,5-dimethylphenyl]propane, 2,2-bis[4-(4-aminophenoxy)phenyl]-1,1,1,3,3,3-hexafluoropropane, 1,4-bis(3-aminophenoxy)benzene, 1,3-bis(3-aminophenoxy)benzene, 1,4-bis(4-aminophenoxy)benzene, 4,4′-bis(4-aminophenoxy)biphenyl, bis[4-(4-aminophenoxy)phenyl]ketone, bis[4-(4-aminophenoxy)phenyl]sulfide, bis[4-(4-aminophenoxy)phenyl]sulfoxide, bis[4-(4-aminophenoxy)phenyl]sulfone, bis[4-(3-aminophenoxy)phenyl]ether, bis[4-(4-aminophenoxy)phenyl]ether, 1,3-bis[4-(4-aminophenoxy)benzoyl]benzene, 1,3-bis[4-(3-aminophenoxy)benzoyl]benzene, 1,4-bis[4-(3-aminophenoxy)benzoyl]benzene, 4,4′-bis[(3-aminophenoxy)benzoyl]benzene, 1,1-bis[4-(3-aminophenoxy)phenyl]propane, 1,3-bis[4-(3-aminophenoxy)phenyl]propane, 3,4′-diaminodiphenyl sulfide, 2,2-bis[3-(3-aminophenoxy)phenyl]-1,1,1,3,3,3-hexafluoropropane, bis[4-(3-aminophenoxy)phenyl]methane, 1,1-bis[4-(3-aminophenoxy)phenyl]ethane, 1,2-bis[4-(3-aminophenoxy)phenyl]ethane, bis[4-(3-aminophenoxy)phenyl]sulfoxide, 4,4′-bis[3-(4-aminophenoxy)benzoyl]diphenyl ether, 4,4′-bis[3-(3-aminophenoxy)benzoyl]diphenyl ether, 4,4′-bis[4-(4-amino-α,α-dimethylbenzyl)phenoxy]benzophenone, 4,4′-bis[4-(4-amino-α,α-dimethylbenzyl)phenoxy]diphenyl sulfone, bis[4-{4-(4-aminophenoxy)phenoxy}phenyl]sulfone, 1,4-bis[4-(4-aminophenoxy)phenoxy-α,α-dimethylbenzyl]benzene, 1,3-bis[4-(4-aminophenoxy)phenoxy-α,α-dimethylbenzyl]benzene, 1,3-bis[4-(4-amino-6-trifluoromethylphenoxy)-α,α-dimethylbenzyl]benzene, 1,3-bis[4-(4-amino-6-fluorophenoxy)-α,α-dimethylbenzyl]benzene, 1,3-bis[4-(4-amino-6-methylphenoxy)-α,α-dimethylbenzyl]benzene, 1,3-bis[4-(4-amino-6-cyanophenoxy)-α,α-dimethylbenzyl]benzene, 3,3′-diamino-4,4′-diphenoxybenzophenone, 4,4′-diamino-5,5′-diphenoxybenzophenone, 3,4′-diamino-4,5′-diphenoxybenzophenone, 3,3′-diamino-4-phenoxybenzophenone, 4,4′-diamino-5-phenoxybenzophenone, 3,4′-diamino-4-phenoxybenzophenone, 3,4′-diamino-5′-phenoxybenzophenone, 3,3′-diamino-4,4′-diphenylphenoxybenzophenone, 4,4′-diamino-5,5′-diphenylphenoxybenzophenone, 3,4′-diamino-4,5′-diphenylphenoxybenzophenone, 3,3′-diamino-4-biphenoxybenzophenone, 4,4′-diamino-5-biphenoxybenzophenone, 3,4′-diamino-4-biphenoxybenzophenone, 3,4′-diamino-5′-biphenoxybenzophenone, 1,3-bis(3-amino-4-phenoxybenzoyl)benzene, 1,4-bis(3-amino-4-phenoxybenzoyl)benzene, 1,3-bis(4-amino-5-phenoxybenzoyl)benzene, 1,4-bis(4-amino-5-phenoxybenzoyl)benzene, 1,3-bis(3-amino-4-biphenoxybenzoyl)benzene, 1,4-bis(3-amino-4-biphenoxybenzoyl)benzene, 1,3-bis(4-amino-5-biphenoxybenzoyl)benzene, 1,4-bis(4-amino-5-biphenoxybenzoyl)benzene, 2,6-bis[4-(4-amino-α,α-dimethylbenzyl)phenoxy]benzonitrile, 4,4′-[9H-fluorene-9,9-diyl]bisaniline (also known as “9,9-bis(4-aminophenyl)fluorene”), spiro(xanthene-9,9′-fluorene)-2,6-diylbis(oxycarbonyl)]bisaniline, 4,4′-[spiro(xanthene-9,9′-fluorene)-2,6-diylbis(oxycarbonyl)]bisaniline, 4,4′-[spiro(xanthene-9,9′-fluorene)-3,6-diylbis(oxycarbonyl)]bisaniline, 5-amino-2-(p-aminophenyl)benzoxazole, 6-amino-2-(p-aminophenyl)benzoxazole, 5-amino-2-(m-aminophenyl)benzoxazole, 6-amino-2-(m-aminophenyl)benzoxazole, 2,2′-p-phenylenebis(5-aminobenzoxazole), 2,2′-p-phenylenebis(6-aminobenzoxazole), 1-(5-aminobenzoxazolo)-4-(6-aminobenzoxazolo)benzene, 2,6-(4,4′-diaminodiphenyl)benzo[1,2-d:5,4-d′]bisoxazole, 2,6-(4,4′-diaminodiphenyl)benzo[1,2-d:4,5-d′]bisoxazole, 2,6-(3,4′-diaminodiphenyl)benzo[1,2-d:5,4-d′]bisoxazole, 2,6-(3,4′-diaminodiphenyl)benzo[1,2-d:4,5-d′]bisoxazole, 2,6-(3,3′-diaminodiphenyl)benzo[1,2-d:5,4-d′]bisoxazole, and 2,6-(3,3′-diaminodiphenyl)benzo[1,2-d:4,5-d′]bisoxazole. A part or all of hydrogen atoms on an aromatic ring of the above-described aromatic diamines may be substituted with halogen atoms; alkyl groups or alkoxyl groups having 1 to 3 carbon atoms; or cyano groups, and further a part or all of hydrogen atoms of the alkyl groups or alkoxyl groups having 1 to 3 carbon atoms may be substituted with halogen atoms.

Examples of the alicyclic diamines include 1,4-diaminocyclohexane, 1,4-diamino-2-methylcyclohexane, 1,4-diamino-2-ethylcyclohexane, 1,4-diamino-2-n-propylcyclohexane, 1,4-diamino-2-isopropylcyclohexane, 1,4-diamino-2-n-butylcyclohexane, 1,4-diamino-2-isobutylcyclohexane, 1,4-diamino-2-sec-butylcyclohexane, 1,4-diamino-2-tert-butylcyclohexane, 4,4′-methylenebis(2,6-dimethylcyclohexylamine), 9,10-bis(4-aminophenyl)adenine, and dimethyl 2,4-bis(4-aminophenyl)cyclobutane-1,3-dicarboxylate.

As the diamine, in particular, 4,4′-diamino-2,2′-bis(trifluoromethyl)biphenyl (TFMB) or 4,4′-diaminobenzanilide (DABA) is preferably contained, and the diamine is more preferably 4,4′-diamino-2,2′-bis(trifluoromethyl)biphenyl (TFMB) or 4,4′-diaminobenzanilide (DABA).

In a case where the silsesquioxane compound, that is, the silsesquioxane derivative, has two or more acid anhydride groups, the number of moles of the structural unit derived from the silsesquioxane derivative (however, in a case where the silsesquioxane derivative has more than two dicarboxylic anhydride groups, this number of moles is the number calculated by dividing the total number of moles of the silsesquioxane derivative by the total number of the dicarboxylic anhydride groups of the silsesquioxane derivative, and multiplying the result by two) is preferably 0.0001 times or more the sum of the number of moles of the structural unit derived from the silsesquioxane derivative and the number of moles of the structural unit derived from the carboxylic acid. Here, the “total number of acid anhydride groups in the silsesquioxane derivative” refers to the number of acid anhydride groups per molecule of the silsesquioxane derivative.

In other words, the molar content of the structural unit derived from the silsesquioxane derivative (specifically, the molar content based on the divalent monomer, that is, the molar content in terms of divalence) is preferably 0.0001 mol % or more. The molar content is a value determined by the following calculation.

$$( n A / ( n A + nD ) ) \times 100$$

(where nA is the number calculated by dividing the total number of moles of structural units derived from a silsesquioxane derivative by the total number of acid anhydride groups and multiplying the result by two, and nD is the number of moles of a structural unit derived from a carboxylic acid).

Here too, the “total number of acid anhydride groups” refers to the number of acid anhydride groups per molecule of the silsesquioxane derivative.

As the number of moles of the structural unit derived from the silsesquioxane derivative is 0.0001 or more, the coefficient of static friction of the polyimide film can be further diminished. In addition to this, the toughness of the polyimide film can be effectively improved. The number of moles of the structural unit derived from the silsesquioxane derivative is more preferably 0.001 times or more, still more preferably 0.005 times or more, still more preferably 0.01 times or more.

Meanwhile, the number of moles of the structural unit derived from the silsesquioxane derivative is preferably 0.09 times or less. In other words, the molar content of the structural unit derived from the silsesquioxane derivative is preferably 0.09 mol % or less. As the number of moles of the structural unit is 0.09 times or less, several main properties of the polyimide film can be maintained. For example, the degree of increase in CTE cause by the silsesquioxane derivative can be suppressed. In other words, the CTE can be maintained. In other words, a large increase in CTE can be suppressed. Furthermore, the thermal decomposition temperature and the glass transition temperature can be maintained. In other words, large decreases in the thermal decomposition temperature and glass transition temperature can be suppressed. Moreover, the toughness of the polyimide film can be effectively improved. In addition to this, in a case where the silsesquioxane derivative has a SiOH group (for example, a residual SiOH group), there is a tendency that gelation of the polyamic acid solution is likely to occur (this tendency is particularly strong in a silsesquioxane derivative of a random structure), and as the number of moles of the structural unit derived from the silsesquioxane derivative is 0.09 times or less, gelation of the polyamic acid solution can be suppressed or diminished. In other words, the time-dependent stability of the polyamic acid solution can be improved. The number of moles of the structural unit derived from the silsesquioxane derivative is more preferably 0.08 times or less. The number of moles of the structural unit derived from the silsesquioxane derivative may be 0.07 times or less, or 0.06 times or less.

In a case where the silsesquioxane compound, that is, the silsesquioxane derivative, has two or more amino groups, the number of moles of the structural unit derived from the silsesquioxane derivative (however, in a case where the silsesquioxane derivative has more than two amino groups, this number of moles is the number calculated by dividing the total number of moles of the silsesquioxane derivative by the total number of the amino groups of the silsesquioxane derivative, and multiplying the result by two) is preferably 0.0001 times or more the sum of the number of moles of the structural unit derived from the silsesquioxane derivative and the number of moles of the structural unit derived from the diamine. Here, the “total number of amino groups in the silsesquioxane derivative” refers to the number of amino groups per molecule of the silsesquioxane derivative.

In other words, the molar content of the structural unit derived from the silsesquioxane derivative (specifically, the molar content based on the divalent monomer, that is, the molar content in terms of divalence) is preferably 0.0001 mol % or more. The molar content is a value determined by the following calculation.

$$( n A / ( n A + nD ) ) \times 100$$

(where nA is the number calculated by dividing the total number of moles of structural units derived from a silsesquioxane derivative by the total number of amino groups and multiplying the result by two, and nD is the number of moles of a structural unit derived from a diamine).

Here too, the “total number of amino groups” refers to the number of amino groups per molecule of the silsesquioxane derivative.

As the number of moles of the structural unit derived from the silsesquioxane derivative is 0.0001 or more, the coefficient of static friction of the polyimide film can be further diminished. In addition to this, the toughness of the polyimide film can be effectively improved. The number of moles of the structural unit derived from the silsesquioxane derivative is more preferably 0.001 times or more, still more preferably 0.005 times or more, still more preferably 0.01 times or more.

Meanwhile, the number of moles of the structural unit derived from the silsesquioxane derivative is preferably 0.09 times or less. In other words, the molar content of the structural unit derived from the silsesquioxane derivative is preferably 0.09 mol % or less. As the number of moles of the structural unit is 0.09 times or less, several main properties of the polyimide film can be maintained. For example, the degree of increase in CTE cause by the silsesquioxane derivative can be suppressed. In other words, the CTE can be maintained. In other words, a large increase in CTE can be suppressed. Furthermore, the thermal decomposition temperature and the glass transition temperature can be maintained. In other words, large decreases in the thermal decomposition temperature and glass transition temperature can be suppressed. Moreover, the toughness of the polyimide film can be effectively improved. In addition to this, in a case where the silsesquioxane derivative has a SiOH group (for example, a residual SiOH group), there is a tendency that gelation of the polyamic acid solution is likely to occur (this tendency is particularly strong in a silsesquioxane derivative of a random structure), and as the number of moles of the structural unit derived from the silsesquioxane derivative is 0.09 times or less, gelation of the polyamic acid solution can be suppressed or diminished. In other words, the time-dependent stability of the polyamic acid solution can be improved. The number of moles of the structural unit derived from the silsesquioxane derivative is more preferably 0.08 times or less. The number of moles of the structural unit derived from the silsesquioxane derivative may be 0.07 times or less, or 0.06 times or less.

As the solvent used in the synthesis of polyamic acid, any solvent that dissolves polyamic acid and its monomers can be used, and examples of the solvent include aprotic solvents, phenolic solvents, ether and glycol-based solvents.

Specifically, examples of the aprotic solvents include amide-based solvents such as N,N-dimethylformamide, N,N-dimethylacetamide, N-methyl-2-pyrrolidone, N-methylcaprolactam, 1,3-dimethylimidazolidinone, and tetramethylurea; lactone-based solvents such as γ-butyrolactone and γ-valerolactone; phosphorus-containing amide-based solvents such as hexamethylphosphoric amide and hexamethylphosphine triamide; sulfur-containing solvents such as dimethyl sulfone, dimethyl sulfoxide, and sulfolane; ketone-based solvents such as cyclohexanone and methylcyclohexanone; tertiary amine-based solvents such as picoline and pyridine; and ester-based solvents such as (2-methoxy-1-methylethyl) acetate.

Examples of the phenolic solvents include phenol, o-cresol, m-cresol, p-cresol, 2,3-xylenol, 2,4-xylenol, 2,5-xylenol, 2,6-xylenol, 3,4-xylenol, and 3,5-xylenol. Examples of the ether and glycol-based solvents include 1,2-dimethoxyethane, bis(2-methoxyethyl)ether, 1,2-bis(2-methoxyethoxy)ethane, bis[2-(2-methoxyethoxy)ethyl]ether, tetrahydrofuran, and 1,4-dioxane.

Among these, from the viewpoint of solubility and film forming properties, it is preferable that the solvent contains N-methyl-2-pyrrolidone, N,N′-dimethylacetamide, or γ-butyrolactone as a main component. The solvents may be used singly or in mixture of two or more kinds thereof.

As the conditions for the synthesis, the reaction temperature is preferably −30° C. to 200° C., more preferably 20° C. to 180° C., particularly preferably 20° C. to 100° C. Stirring is continuously performed at room temperature (20° C. to 25° C.) or an appropriate reaction temperature, and the reaction can be terminated when the viscosity of the polyimide precursor is constant. The reaction can usually be completed in 3 to 100 hours.

### <Polyamic Acid Composition>

In the present invention, the polyamic acid composition contains polyamic acid as described above and a solvent. The polyamic acid composition can contain a solvent different from the solvent used during synthesis, but it is preferable that the solvent used during synthesis is contained from the viewpoint of avoiding complication of the production process. Hence, the main component of the solvent contained in the polyamic acid composition is preferably N-methyl-2-pyrrolidone, N,N′-dimethylacetamide, or γ-butyrolactone.

The content of the polyamic acid in the polyamic acid composition is preferably 5% to 30% by mass, more preferably 10% to 20% by mass from the viewpoint of the film thickness during film formation. When the content is within this range, a thin film having a thickness that is excellent in handling can be obtained.

The polyamic acid composition may further contain arbitrary components such as an adhesive property imparting agent, a surfactant, a leveling agent, an antioxidant, a UV absorber, a chemical imidizing agent, a coloring agent, and a bluing agent. The polyamic acid composition may further contain a filler or the like that may be contained in a polyimide film.

### <Polyimide>

In the present invention, the polyimide is one obtained by imidizing the polyamic acid described above. The polyimide can be obtained, for example, by heating the polyamic acid. As heating is performed, the carboxy groups of the polyamic acid each undergo dehydration cyclization, and the polyamic acid is imidized to form a polyimide structure.

The polyimide can be obtained by heating the polyamic acid in a solvent. The heating temperature during the imidization of polyamic acid is preferably 150° C. to 220° C. in a solvent.

As described below, the polyimide can be provided as a membrane-like or film-like formed article by applying the polyamic acid composition containing a solvent to the base and performing heating. The heating temperature during the imidization of polyamic acid is preferably 250° C. to 400° C. in a state where the solvent is dried to a certain extent or more. Coloration due to oxidation of the terminal amino groups can be suppressed by adding a terminal amino group capping agent to the polyamic acid composition containing a solvent and performing heat treatment. The terminal amino group capping agent is not particularly limited as long as it is a compound that reacts with an amino group to form a chemical bond, and for example, acetic anhydride can be used.

It is also possible to obtain a polyimide by chemical imidization instead of thermal imidization. In this case, it is preferable to use a tertiary amine as the imidization promoter. A heterocyclic tertiary amine is still more preferable as the tertiary amine. Preferred specific examples of the heterocyclic tertiary amine include pyridine, 2,5-diethylpyridine, picoline, quinoline, and isoquinoline.

### <Polyimide Film>

The polyimide film of the present invention contains a polyimide as described above. In a case where the polyimide film is composed of two or more layers, it is only required that the layer constituting at least one of the two surfaces of the polyimide film contains the polyimide described above (specifically, polyimide obtained by imidizing polyamic acid, which is a copolymerization reaction product of at least a carboxylic acid, a diamine, and a silsesquioxane derivative).

The polyimide film can be obtained, for example, by casting a polyamic acid solution on a substrate, performing heating to volatilize the solvent to form a uniform green film having a thickness of 1 to 100 μm, and then imidizing this. Examples of the substrate used in a case of forming a film by such a casting method include a polymer film, a glass plate, a silicone rubber plate, and a metal plate.

As the polymer film, for example, a polyethylene terephthalate film A4100 (manufactured by TOYOBO CO., LTD.) can be used. When a green film having a predetermined thickness is obtained, a method in which the concentration of the polyamic acid solution is adjusted, a method in which the gap interval of the coater is adjusted, and a method in which lamination is performed by repeating casting so that a desired film thickness is obtained can be adopted, and a substrate having the desired film thickness can be thus produced. The obtained green film can be further thermally imidized by heat treatment to obtain a polyimide film.

The polyimide film may have a single-layer configuration or a laminated configuration of two or more layers. For the physical strength of the polyimide film and the ease of peeling off of the polyimide film from the inorganic substrate, the polyimide film preferably has a laminated configuration of two or more layers and may have a laminated configuration of three or more layers. In the present specification, the physical properties (yellowness index, total light transmittance, haze, and the like) of the polyimide film in the case of having a laminated configuration of two or more layers refer to the values for the entire polyimide film unless otherwise stated.

The thickness of the polyimide film is preferably 5 μm or more, more preferably 7 μm or more. The upper limit of the thickness of the polyimide film is not particularly limited but is preferably 200 μm or less, more preferably 90 μm or less, still more preferably 50 μm or less for use as a flexible electronic device. It is difficult to form and transport the film when the thickness is too thin, and it is difficult to transport the roll when the thickness is too thick.

The polyimide film has a coefficient of static friction of 2.0 or less, preferably 1.8 or less, more preferably 1.5 or less, still more preferably 1.0 or less. As the coefficient of static friction is 2.0 or less, it is possible to suppress the generation of wrinkles and scratches when the polyimide film is wound into a roll shape. In addition to this, the transportability of the polyimide film is also favorable during continuous production of the polyimide film, so that the generation of wrinkles and scratches can be further suppressed. The lower limit of the coefficient of static friction is not particularly limited, and may be 0.1 or more, or 0.2 or more, industrially. The coefficient of static friction is the coefficient of static friction between one surface and the other surface of the two surfaces of the polyimide film. The coefficient of static friction is a value measured by the measuring method described in Examples.

The polyimide film of the present invention contains the polyimide described above (specifically, polyimide obtained by imidizing a polyamic acid, which is a copolymerization reaction product of at least a carboxylic acid, a diamine, and a silsesquioxane derivative), and thus has a favorable coefficient of static friction (for example, 2.0 or less) without the addition of a lubricant (that is, fine particles) as well, but a lubricant may be added for the purpose of adjusting the coefficient of static friction. In a case of adding a lubricant as well, the coefficient of static friction can be easily adjusted with a small amount. In a case where a lubricant is contained in the polyimide film, the content of the lubricant is preferably 50 ppm by mass or more, more preferably 100 ppm by mass or more, still more preferably 200 ppm by mass or more with respect to the polyimide film. When the content of the lubricant is in this range, an effect of improving the coefficient of static friction is achieved, and the easily slipping properties are excellent. The content of the lubricant is preferably 1.0% by mass or less, more preferably 0.8% by mass or less, still more preferably 0.5% by mass or less. When the content of the lubricant is within the above range, the optical properties of the film are not significantly affected, and the optical properties become favorable.

The lubricant may be an inorganic lubricant (inorganic filler) or an organic lubricant (organic filler). The average particle size of the lubricant is preferably 0.05 μm or more, more preferably 0.1 μm or more. When the content of the lubricant is in this range, an effect of improving the coefficient of static friction is achieved, and the easily slipping properties are excellent. The formation of coarse particles due to secondary aggregation can be suppressed. The average particle size of the lubricant is preferably 1 μm or less, more preferably 0.5 μm or less. When the average particle size of the lubricant is within the above range, the optical properties of the film are not significantly affected, and the optical properties become favorable. The average particle size of the lubricant is expressed as the average of particle sizes determined from the particle size distribution that is acquired by analyzing the diffraction pattern when a suspension containing the lubricant (for example, polyamic acid containing the lubricant) is irradiated with laser light. Specifically, the average particle size of the lubricant is the weight average particle size (that is, volume average particle size) calculated after the particle size distribution of a suspension (that is, a dispersion solution of the lubricant) is determined using a laser scattering particle size distribution analyzer LB-500 (manufactured by HORIBA, Ltd.).

The total light transmittance of the polyimide film in the present invention is preferably 75% or more, more preferably 85% or more, still more preferably 87% or more, yet still more preferably 88% or more. The upper limit of the total light transmittance of the polyimide film is not particularly limited, but is preferably 98% or less, more preferably 97% or less for use as a flexible electronic device.

The haze of the polyimide film in the present invention is preferably 1.0 or less, more preferably 0.8 or less, still more preferably 0.5 or less, yet still more preferably 0.3 or less.

The yellowness index (hereafter, also referred to as “yellow index” or “YI”) of the polyimide film in the present invention is preferably 20 or less, more preferably 15 or less, still more preferably 10 or less, yet still more preferably 5 or less. The lower limit of the yellowness index of the polyimide film is not particularly limited, but is preferably 0.1 or more, more preferably 0.2 or more, still more preferably 0.3 or more for use as a flexible electronic device.

The out-of-plane retardation (Rth) of the polyimide film in the present invention is preferably 500 nm or less, more preferably 300 nm or less, still more preferably 200 nm or less, yet still more preferably 100 nm or less. The lower limit of Rth of the polyimide film is not particularly limited, but is preferably 0.1 nm or more, more preferably 0.5 nm or more for use as a flexible electronic device.

The polyimide film of the present invention can be realized by performing stretching in the course of forming the polyimide film. Such stretching operation can be realized by performing stretching by 1.5-fold to 4.0-fold in the MD direction and 1.4-fold to 3.0-fold in the TD direction in the course of applying a polyimide solution to a support for polyimide film formation, drying the solution to form a polyimide film containing a solvent at 1% to 50% by mass, and further treating the polyimide film containing a solvent at 1% to 50% by mass at a high temperature on the support for polyimide film formation or in a state of being peeled off from the support for drying. At this time, by stretching the thermoplastic polymer film and the polyimide film at the same time using an unstretched thermoplastic polymer film as the support for polyimide film formation and then peeling off the stretched polyimide film from the thermoplastic polymer film, it is possible to prevent the polyimide film from being scratched at the time of stretching in the MD direction and to obtain a highly colorless and transparent polyimide film with higher quality.

The average coefficient of linear thermal expansion (CTE) of the polyimide film at between 50° C. and 200° C. is preferably 60 ppm/K or less. The average coefficient of linear thermal expansion (CTE) is preferably 50 ppm/K or less, more preferably 35 ppm/K or less. The average coefficient of linear thermal expansion (CTE) is preferably −20 ppm/K or more, more preferably −10 ppm/K or more. When the CTE is in the above range, a small difference in coefficient of linear thermal expansion between the polyimide film and a general support (inorganic substrate) can be maintained, and it is possible to avoid peeling off of the polyimide film and the inorganic substrate from each other or warpage of the polyimide film together with the support when the polyimide film and the inorganic substrate are subjected to a process of applying heat as well. Here, CTE is a factor that indicates reversible expansion and contraction with respect to the temperature. The method for measuring the CTE of the polyimide film is as described in Examples.

The polyimide film can contain a filler. The filler is not particularly limited, and examples thereof include silica, carbon, and ceramic, and silica is preferable among these. These fillers may be used singly or two or more kinds thereof may be used concurrently. By adding a filler, protrusions are imparted to the polyimide film surface, and this increases the slipperiness of the polyimide film surface. By adding a filler, the CTE and Rth of the polyimide film can also be suppressed to low levels. The average particle size of the filler is preferably 1 nm or more, more preferably 5 nm or more. The average particle size of the filler is preferably 1 μm or less, more preferably 500 nm or less, still more preferably 100 nm or less.

The content of the filler in the polyimide film is preferably adjusted depending on the average particle size of the filler. In a case where the particle size of the filler is 30 nm or more, the content of the filler is preferably 0.01% to 5% by mass, more preferably 0.01% to 3% by mass, still more preferably 0.01% to 2% by mass, particularly preferably 0.01% to 1% by mass. Meanwhile, in a case where the particle size of the filler is less than 30 nm, the content of the filler is preferably 0.01% to 50% by mass, more preferably 0.01% to 40% by mass, still more preferably 0.01% to 30% by mass, particularly preferably 0.01% to 20% by mass. By adjusting the content of the filler in the above range, high slipperiness of the polyimide film surface can be maintained without impairing the transparency of the polyimide film, and the CTE and Rth of the polyimide film can be suppressed to low levels.

The method for adding a filler to the polyimide film is not particularly limited, but examples thereof include a method in which the filler is added as a powder and a method in which the filler is added in the form of filler/solvent (slurry) when or after the above-mentioned polyamic acid (polyimide precursor) solution is prepared, and a method in which the filler is added as a slurry is particularly preferable among others. The slurry is not particularly limited, but examples thereof include a slurry in which silica having an average particle size of 10 nm is dispersed in N,N-dimethylacetamide (DMAC) at a concentration of 20% by mass (for example, “SNOWTEX (registered trademark) DMAC-ST” manufactured by Nissan Chemical Corporation), a slurry in which silica having an average particle size of 80 nm is dispersed in N,N-dimethylacetamide (DMAC) at a concentration of 20% by mass (for example, “SNOWTEX (registered trademark) DMAC-ST-ZL” manufactured by Nissan Chemical Corporation), and a slurry in which silica having an average particle size of 10 nm is dispersed in N-methylpyrrolidone (M4P) at a concentration of 20% by mass (for example, “SNOWTEX (registered trademark) NMP-ST” manufactured by Nissan Chemical Corporation).

The polyimide film may contain a coloring agent. For example, by mixing a blue coloring agent into a pale yellow polyimide film, the Y.I. of the film can be decreased.

Examples of the coloring agent include organic pigments, inorganic pigments, and dyes, but organic pigments and inorganic pigments are preferable in order to improve the heat resistance, reliability and light resistance of the colored film. From the viewpoint of heat resistance, the coloring agent preferably has a 1% thermal weight loss temperature of 220° C. or more. The 1% thermal weight loss temperature of a coloring agent can be measured using a TGA instrument (TGA-50, Shimadzu Corporation). This measurement is carried out by placing about 10 mg of coloring agent on an aluminum pan and raising the temperature at a rate of 10° C./min in a nitrogen atmosphere. Then, using the weight when the temperature reaches 150° C. as the starting point, the temperature (1% weight loss temperature: Td₁) when the weight decreases by 1% may be read.

Examples of the organic pigments include: diketopyrrolopyrrole-based pigments; azo-based pigments such as azo, disazo, and polyazo; phthalocyanine-based pigments such as copper phthalocyanine, halogenated copper phthalocyanine, and metal-free phthalocyanine; anthraquinone-based pigments such as aminoanthraquinone, diaminodianthraquinone, anthrapyrimidine, flavanthrone, anthanthrone, indanthrone, pyranthrone, and violanthrone; quinacridone-based pigments; dioxazine-based pigments; perinone-based pigments; perylene-based pigments; thioindigo-based pigments; isoindoline-based pigments; isoindolinone-based pigments; quinophthalone-based pigments; threne-based pigments; and metal complex-based pigments.

Examples of the inorganic pigments include titanium oxide, zinc oxide, zinc sulfide, white lead, calcium carbonate, precipitated barium sulfate, white carbon, alumina white, kaolin clay, talc, bentonite, black iron oxide, cadmium red, red iron oxide, molybdenum red, molybdate orange, chrome vermilion, yellow lead, cadmium yellow, yellow iron oxide, titanium yellow, chromium oxide, viridian, titanium cobalt green, cobalt green, cobalt chrome green, victoria green, ultramarine, navy blue, cobalt blue, cerulean blue, cobalt silica blue, cobalt zinc silica blue, manganese violet, and cobalt violet.

Examples of the dyes include azo dyes, anthraquinone dyes, condensed polycyclic aromatic carbonyl dyes, indigoid dyes, carbonium dyes, phthalocyanine dyes, methine dyes, and polymethine dyes.

The tensile strength at break of the polyimide film is preferably 60 MPa or more, more preferably 120 MPa or more, still more preferably 160 MPa or more. The upper limit of the tensile strength at break is not particularly limited but is practically less than about 1000 MPa. When the tensile strength at break is 60 MPa or more, it is possible to prevent the polyimide film from breaking when being peeled off from the inorganic substrate. The method for measuring the tensile strength at break of the polyimide film is as described in Examples. In a case where the polyimide film is formed after application onto a glass substrate is performed using a casting applicator as well, orthogonal two directions of the parallel direction and vertical direction to the application using a casting applicator are defined as (MD direction) and (TD direction), respectively. Hereinafter, the same applies to the tensile elongation at break and the tensile modulus as well.

The tensile elongation at break of the polyimide film is preferably 1% or more, more preferably 5% or more, still more preferably 10% or more. When the tensile elongation at break is 5% or more, the handling properties are excellent. The method for measuring the tensile strength at break of the polyimide film is as described in Examples.

The tensile modulus of the polyimide film is preferably 2 GPa or more, more preferably 3 GPa or more, still more preferably 4 GPa or more. When the tensile modulus is 3 GPa or more, the polyimide film is less expanded and deformed when being peeled off from the inorganic substrate and exhibits excellent handling properties. The tensile modulus is preferably 20 GPa or less, more preferably 12 GPa or less, still more preferably 10 GPa or less. When the tensile modulus is 20 GPa or less, the polyimide film can be used as a flexible film. The method for measuring the tensile modulus of the polyimide film is as described in Examples.

Since the polyimide film exhibits improved toughness while maintaining a certain degree of tensile modulus, and the tensile product, which is the product of tensile strength and elongation, of the polyimide film is improved compared to those of conventional polyimide films. In other word, the tensile product of the polyimide film of the present invention in a tensile test is preferably 300 MPa-% or more, more preferably 1,000 MPa-% or more, still more preferably 1,200 MPa-% or more. The upper limit is not particularly set, but it is preferable that the tensile product in a tensile test is 20,000 MPa-% or less from the viewpoint of handling properties of the film. The tensile product may be, for example, 18,000 MPa-% or less, 15,000 MPa-% or less, or 10,000 MPa-% or less.

The polyimide film is obtained preferably in the form of being wound as a long polyimide film having a width of 300 mm or more and a length of 10 m or more at the time of production, more preferably in the form of a roll-shaped polyimide film wound around a winding core. When the polyimide film is wound in a roll shape, it is easy to transport the polyimide film in the form of a polyimide film wound in a roll shape.

In a case where the polyimide film has a laminated configuration of two or more layers, it is not preferable that the differences in CTE between the respective layers are different from one another since warpage is caused. Hence, the difference in CTE between the first polyimide film layer that is in contact with an inorganic substrate and the second polyimide film layer that is not in contact with the inorganic substrate but is adjacent to the first polyimide film is preferably 40 ppm/K or less, more preferably 30 ppm/K or less, still more preferably 15 ppm/K or less. In particular, it is preferable that the layer having the thickest film thickness of the second polyimide film is within the above range. It is preferable that the polyimide film has a symmetrical structure in the film thickness direction since warpage is less likely to occur.

In the polyimide film having a laminated configuration of two or more layers, in particular, the thickness of intermingling of the first polyimide film layer in contact with the inorganic substrate with the second polyimide film layer adjacent to the first polyimide film layer (hereinafter, also simply referred to as the “second polyimide film layer”) at the interface is not particularly limited as long as it is thinner than the sum of the thickness of one layer of the first polyimide film layer and the thickness of one layer of the second polyimide film layer, but is preferably 99% or less, more preferably 80% or less, still more preferably 50% or less of the sum of the thickness of one layer of the first polyimide film layer and the thickness of one layer of the second polyimide film layer. The lower limit is not particularly limited, but industrially, there is no problem when the thickness of intermingling is 10 nm or more, and the thickness of intermingling may be 20 nm or more. In a case where the functions of the respective layers are significantly different from one another and it is necessary to fully exert the respective functions without canceling each other out, the intermixed region of each layer is kept preferably to 50% or less, more preferably to 30% or less, still more preferably to 10% or less.

The means for forming a less intermingled layer is not particularly limited, but it is preferable to form either the first polyimide film layer or the second polyimide film layer, perform a heating step, and then form the next layer rather than simultaneously forming the first polyimide film layer and the second polyimide film layer by solution film formation. The expression “after the heating step is performed” includes both a case in the middle of the heating step and a case where the heating step is completed. Less intermingled layers are formed when the next layer is formed after the heating step is completed, but the surface of the finished film is often already unreactive in some cases and has fewer functional groups, thus the adhesive strength between the two layers is weak, and practical problems may occur. For this reason, it is desirable to have an interface where intermingling occurs by 10 nm or more in a case where little intermingling occurs as well.

By forming materials (resins) exhibiting different physical properties into a film having a two-layer configuration, it is possible to form a film exhibiting various properties at the same time. Furthermore, by laminating the layers into a symmetrical structure in the thickness direction (for example, first polyimide film layer/second polyimide film layer/first polyimide film layer), the CTE balance in the entire film becomes favorable and a film that is less likely to undergo warpage can be formed. It is conceivable to impart features to the spectral characteristics by forming any one of the layers as a layer that absorbs ultraviolet rays or infrared rays, and to control the incidence and emission of light by layers having different refractive indexes. By adding a lubricant to the first polyimide film layer, the slipperiness of the film can be improved while the optical and thermal properties of the entire film are maintained to be similar to those of the second polyimide film layer. In this case, the polymer compositions of the first polyimide film layer and second polyimide film layer may be the same as or different from each other.

As a means for forming a film having a layer configuration of two or more layers, various methods such as simultaneous application using a T-die capable of simultaneously discharging two or more layers, sequential application in which one layer is applied and then the next layer is applied, a method in which one layer is applied and then dried, and then the next layer is applied, a method in which the next layer is applied after the film formation of one layer is finished, or multilayering by heat lamination using a thermoplastic layer inserted between layers are conceivable. However, in the present patent, various existing application methods and multilayering methods can be appropriately incorporated.

The polyimide film of the present invention can be suitably used in electronic and optical devices such as liquid crystal displays, plasma displays, organic electroluminescence displays, and electronic paper.

### <Laminated Body>

The laminated body of the present invention includes a polyimide film as described above and an inorganic substrate. In the laminated body as well, in a case where the polyimide film is composed of two or more layers, it is only required that at least one layer contains the polyimide described above (specifically, polyimide obtained by imidizing a polyamic acid, which is a copolymerization reaction product of at least a carboxylic acid, a diamine, and a silsesquioxane derivative). In addition to the polyimide film, a transparent, highly heat-resistant film other than the polyimide film may be laminated.

Examples of the transparent, highly heat-resistant film include PET, PEN, PVC, acrylic, polystyrene, and polycarbonate films. The transparent, highly heat-resistant film can be used on either side of the polyimide film.

A silane coupling agent layer, an adhesive layer, a pressure sensitive adhesive layer, and the like may further be interposed between the polyimide film and the inorganic substrate. The surface of the polyimide film may include a wiring layer, a conductive film layer, a metal layer, and the like.

### <Inorganic Substrate>

The inorganic substrate is only required to be a plate-shaped substrate, which can be used as a substrate formed of an inorganic substance, and examples thereof include those mainly composed of glass plates, ceramic plates, semiconductor wafers, metals and the like and those in which these glass plates, ceramic plates, semiconductor wafers, and metals are laminated, those in which these are dispersed, and those in which fibers of these are contained as the composite of these.

The glass plate includes quartz glass, high silicate glass (96% silica), soda-lime glass, lead glass, aluminoborosilicate glass, borosilicate glass (Pyrex (registered trademark)), borosilicate glass (alkali-free), borosilicate glass (microsheet), aluminosilicate glass, and the like. Among these, those having a coefficient of linear thermal expansion of 5 ppm/K or less are desirable, and in the case of a commercially available product, “Corning (registered trademark) 7059”, “Corning (registered trademark) 1737”, and “EAGLE” manufactured by Corning Inc., “AN100” manufactured by AGC Inc., “OA10” and “OA11G” manufactured by Nippon Electric Glass Co., Ltd., “AF32” manufactured by SCHOTT AG, and the like that are glass for liquid crystal are desirable.

The semiconductor wafer is not particularly limited, but examples thereof include a silicon wafer and wafers of germanium, silicon-germanium, gallium-arsenide, aluminum-gallium-indium, nitrogen-phosphorus-arsenic-antimony, SiC, InP (indium phosphide), InGaAs, GaInNAs, LT, LN, ZnO (zinc oxide), CdTe (cadmium telluride), ZnSe (zinc selenide) and the like. Among these, the wafer preferably used is a silicon wafer, and a mirror-polished silicon wafer having a size of 8 inches or more is particularly preferable.

The metals include single element metals such as W, Mo, Pt, Fe, Ni, and Au, alloys such as Inconel, Monel, Nimonic, carbon-copper, Fe—Ni-based Invar alloy, and Super Invar alloy, and the like. Multilayer metal plates formed by adding another metal layer or a ceramic layer to these metals are also included. In this case, when the overall coefficient of linear thermal expansion (CTE) with the additional layer is low, Cu, Al and the like are also used in the main metal layer. The metals used as the addition metal layer is not limited as long as they are those that strengthen the close contact property with the highly heat-resistant film, those that exhibit properties such as no diffusion and favorable chemical resistance and heat resistance, but suitable examples thereof include Cr, Ni, TiN, and Mo-containing Cu.

Examples of the ceramic plate in the present invention include ceramics for substrate such as Al2O3, mullite, AlN, SiC, crystallized glass, cordierite, spodumene, Pb-BSG+CaZrO₃+Al2O3, crystallized glass+Al2O3, crystallized Ca-BSG, BSG+quartz, BSG+quartz, BSG+Al2O3, Pb-BSG+Al2O3, glass-ceramic, and zerodur material.

It is desirable that the planar portion of the inorganic substrate is sufficiently flat. Specifically, the P-V value of the surface roughness is 50 nm or less, more preferably 20 nm or less, still more preferably 5 nm or less. When the surface is coarser than this, the peel strength between the polyimide film layer and the inorganic substrate is insufficient in some cases.

The thickness of the inorganic substrate is not particularly limited, but a thickness of 10 mm or less is preferable, a thickness of 3 mm or less is more preferable, and a thickness of 1.3 mm or less is still more preferable from the viewpoint of handleability. The lower limit of the thickness is not particularly limited, but is preferably 0.07 mm or more, more preferably 0.15 mm or more, still more preferably 0.3 mm or more. When the inorganic substrate is too thin, the inorganic substrate is easily destroyed and it is difficult to handle the inorganic substrate. When the inorganic substrate is too thick, the inorganic substrate is heavy and it is difficult to handle the inorganic substrate.

### <Formation of Laminated Body>

The laminated body of the present invention is preferably obtained by laminating the polyimide film and the inorganic substrate substantially without using an adhesive. In a case where the polyimide film has a laminated configuration of two or more layers, it is preferable that the polyimide film includes a first polyimide film that is in contact with the inorganic substrate and a second polyimide film layer that is not in contact with the inorganic substrate but is adjacent to the first polyimide film layer. The second polyimide film may further have a plurality of laminated configurations. In the thickness direction of the laminated body, the laminated body may have a configuration in which both ends are the inorganic substrate (for example, inorganic substrate/first polyimide film/second polyimide film/first polyimide film/inorganic substrate). In this case, an adhesive is substantially not used for the polyimide film and the inorganic substrate at both ends.

For the formation of the laminated body, either a method in which a polyimide film is formed and then laminated on an inorganic substrate or a method in which a polyimide film is formed on an inorganic substrate directly or with another layer interposed therebetween may be used. In a case where another layer is interposed therebetween, it is preferable to interpose an easily peeling layer such as a silane coupling agent layer. In order to control the peel force to a proper level, the inorganic substrate may be subjected to surface treatment.

The shape of the laminated body is not particularly limited and may be square or rectangular. The shape of the laminated body is preferably rectangular, and the length of the long side is preferably 300 mm or more, more preferably 500 mm or more, still more preferably 1000 mm or more. The upper limit is not particularly limited, but it is desirable that the laminated body replaces a substrate, which has an industrially used size and is formed from an industrially used material. A length of 20000 mm or less is sufficient, and the length of the long side may be 10000 mm or less.

It is preferable that the laminated body of the present invention is warped in an amount of 10 mm or less when heated at 300° C. The warped amount is more preferably 8 mm or less, still more preferably 6 mm or less since the heat resistance becomes favorable. The lower limit of the warped amount is not particularly limited, but industrially, a warped amount of 0.01 mm or more is sufficient, and the warped amount may be 0.1 mm or more.

### <Adhesive>

It is preferable that an adhesive layer is substantially not interposed between the inorganic substrate and polyimide film. Here, the adhesive layer in the present invention refers to a layer containing a Si (silicon) component at less than 10% in terms of mass ratio (less than 10% by mass). Substantially not used (not interposed) means that the thickness of the adhesive layer interposed between the inorganic substrate and the polyimide film is preferably 0.4 μm or less, more preferably 0.1 μm or less, still more preferably 0.05 μm or less, particularly preferably 0.03 μm or less, most preferably 0 μm.

### <Silane Coupling Agent (SCA)>

In the laminated body, it is preferable to have a silane coupling agent layer between the polyimide film and the inorganic substrate. In the present invention, the silane coupling agent refers to a compound containing a Si (silicon) component at 10% by mass or more. Further, it is preferable to have an alkoxy group in the structure. It is desirable not to contain a methyl group in the structure. By using the silane coupling agent layer, the intermediate layer between the polyimide film and the inorganic substrate can be thinned, and thus there are effects that the amounts of degassed components during heating are small, elution hardly occurs in a wet process as well, and only trace amounts of components are eluted even if elution occurs. The silane coupling agent preferably contains a large amount of silicon oxide component since the heat resistance is improved, and is particularly preferably one exhibiting heat resistance at a temperature of about 400° C. The thickness of the silane coupling agent layer is preferably less than 0.2 μm. As a range for use as a flexible electronic device, the thickness of the silane coupling agent layer is preferably 100 nm or less (0.1 μm or less), more desirably 50 nm or less, still more desirably 10 nm. When a silane coupling agent layer is normally formed, the thickness thereof is about 0.10 μm or less. In processes where it is desired to use as little silane coupling agent as possible, a silane coupling agent layer having a thickness of 5 nm or less can also be used. There is the possibility that the peel strength decreases or some parts are not attached when the thickness is 1 nm or less, and it is thus desirable that the thickness of the silane coupling agent layer is 1 nm or more.

The silane coupling agent in the present invention is not particularly limited, but one having an amino group or an epoxy group is preferable.

Specific examples of the silane coupling agent include N-2-(aminoethyl)-3-aminopropylmethyldimethoxysilane, N-2-(aminoethyl)-3-aminopropyltrimethoxysilane, N-2-(aminoethyl)-3-aminopropyltriethoxysilane, 3-aminopropyltrimethoxysilane, 3-aminopropyltriethoxysilane, 3-triethoxysilyl-N-(1,3-dimethyl-butylidene)propylamine, 2-(3,4-epoxycyclohexyl)ethyltrimethoxysilane, 3-glycidoxypropyltrimethoxysilane, 3-glycidoxypropylmethyldiethoxysilane, 3-glycidoxypropyltriethoxysilane Vinyltrichlorosilane, vinyltrimethoxysilane, vinyltriethoxysilane, 2-(3,4-epoxycyclohexyl)ethyltrimethoxysilane, 3-glycidoxypropyltrimethoxysilane, 3-glycidoxypropylmethyldiethoxysilane, 3-glycidoxypropyltriethoxysilane, p-styryltrimethoxysilane, 3-methacryloxypropylmethyldimethoxysilane, 3-methacryloxypropyltrimethoxysilane, 3-methacryloxypropylmethyldiethoxysilane, 3-methacryloxypropyltriethoxysilane, 3-acryloxypropyltrimethoxysilane, N-phenyl-3-aminopropyltrimethoxysilane, N-(vinylbenzyl)-2-aminoethyl-3-aminopropyltrimethoxysilane hydrochloride, 3-ureidopropyltriethoxysilane, 3-chloropropyltrimethoxysilane, 3-mercaptopropylmethyldimethoxysilane, 3-mercaptopropyltrimethoxysilane, bis(triethoxysilylpropyl)tetrasulfide, 3-isocyanatopropyltriethoxysilane, tris-(3-trimethoxysilylpropyl)isocyanurate, chloromethylphenethyltrimethoxysilane, and chloromethyltrimethoxysilane. Among these, preferred examples include N-2-(aminoethyl)-3-aminopropylmethyldimethoxysilane, N-2-(aminoethyl)-3-aminopropyltrimethoxysilane, N-2-(aminoethyl)-3-aminopropyltriethoxysilane, 3-aminopropyltrimethoxysilane, 3-aminopropyltriethoxysilane, 3-triethoxysilyl-N-(1,3-dimethyl-butylidene)propylamine, 2-(3,4-epoxycyclohexyl)ethyltrimethoxysilane, 3-glycidoxypropyltrimethoxysilane, 3-glycidoxypropylmethyldiethoxysilane, 3-glycidoxypropyltriethoxysilane, aminophenyltrimethoxysilane, aminophenethyltrimethoxysilane, and aminophenylaminomethylphenethyltrimethoxysilane. In a case where heat resistance is required in the process, a silane coupling agent in which Si and an amino group or the like is linked to each other via an aromatic moiety is desirable.

It is required that the peel strength between the polyimide film and the inorganic substrate is 0.3 N/cm or less. This makes it remarkably easy to peel off the polyimide film and the inorganic substrate from each other after a device is formed on the polyimide film. Hence, it is possible to manufacture a device connected body that can be produced in a large quantity and it is easy to manufacture a flexible electronic device. The peel strength is preferably 0.25 N/cm or less, more preferably 0.2 N/cm or less, still more preferably 0.15 N/cm or less, particularly preferably 0.12 N/cm or less. The peel strength is preferably 0.03 N/cm or more. The peel strength is more preferably 0.06 N/cm or more, still more preferably 0.08 N/cm or more, particularly preferably 0.1 N/cm or more since the laminated body does not peel off when a device is formed on the polyimide film. The peel strength is a value of the laminated body after the polyimide film and the inorganic substrate are bonded together and then subjected to heat treatment at 100° C. for 10 minutes in an air atmosphere (initial peel strength). It is preferable that the peel strength of a laminated body obtained by further subjecting the laminated body at the time of initial peel strength measurement to heat treatment at 300° C. for 1 hour in a nitrogen atmosphere is also within the above range (peeling strength after heat treatment at 300° C.).

The laminated body of the present invention can be formed, for example, by the following procedure. The laminated body can be obtained by treating at least one surface of the inorganic substrate with a silane coupling agent in advance, superimposing the surface treated with a silane coupling agent on the polyimide film, and pressurizing the two for lamination. A laminated body can also be obtained by treating at least one surface of the polyimide film with a silane coupling agent in advance, superimposing the surface treated with a silane coupling agent on the inorganic substrate, and pressurizing the two for lamination. In a case where the polyimide film has a laminated configuration of two or more layers, it is preferable that the first polyimide film is superimposed on the inorganic substrate. Examples of the pressurization method include normal pressing or lamination in the air or pressing or lamination in a vacuum, but lamination in the air is desirable in the case of a laminated body having a large size (for example, more than 200 mm) in order to obtain a stable peel strength over the entire surface. In contrast, pressing in a vacuum is preferable in the case of a laminated body having a small size of about 200 mm or less. As the degree of vacuum, a degree of vacuum obtained by an ordinary oil-sealed rotary pump is sufficient, and about 10 Torr or less is sufficient. The pressure is preferably 1 MPa to 20 MPa, still more preferably 3 MPa to 10 MPa. The substrate may be destroyed when the pressure is high, and close contact may not be achieved at some portions when the pressure is low. The temperature is preferably 90° C. to 500° C., still more preferably 100° C. to 400° C. The film may be damaged when the temperature is high, and the close contact force may be weak when the temperature is low.

### <Method for Producing Flexible Electronic Device>

The method for producing a flexible electronic device of the present invention includes a step of forming an electronic device on the polyimide film surface of the laminated body of the present invention and a step of peeling off the inorganic substrate. In this manner, a flexible electronic device in which an electronic device is formed on the polyimide film surface can be produced.

Hence, the flexible electronic device of the present invention includes the polyimide film of the present invention and an electronic device formed on the polyimide film.

When the laminated body is used, a flexible electronic device can be easily produced by using existing equipment and processes for electronic device manufacture. Specifically, a flexible electronic device can be produced by forming an electronic device on the polyimide film of the laminated body and peeling off the electronic device together with the polyimide film from the laminated body.

In the present specification, the electronic device refers to a wiring board which carries out electrical wiring and has a single-sided, double-sided, or multi-layered structure, electronic circuits including active devices such as transistors and diodes and passive devices such as resistors, capacitors, and inductors, sensor elements which sense pressure, temperature, light, humidity and the like, biosensor elements, light emitting elements, image display elements such as liquid crystal displays, electrophoresis displays, and self-luminous displays, wireless and wired communication elements, arithmetic elements, storage elements, MEMS elements, solar cells, thin film transistors, and the like.

The electronic device also includes an interposer function, which is an electrode that penetrates the polyimide in this wiring board. By roughly penetrating the electrode, the step of producing a through electrode after the inorganic substrate has been peeled off is largely omitted. A known method may be used to produce a through hole. For example, the polyimide film is pierced with a UV nanolaser to form a through hole. Next, for example, there is a method in which the through hole is filled with a conductive metal by applying the conventional method used for through holes in double-sided printed wiring boards or via holes in multilayer printed wiring boards, and in addition, a wiring pattern of a metal is formed if necessary.

The polyimide film can also be bonded to the inorganic substrate after a through electrode is formed in the film as described above. In some cases, a through electrode can be formed after the inorganic substrate and the polyimide film are bonded together. It is also possible to penetrate the polyimide film and metallize the penetrated portion, but it is also possible to metallize the penetrated portion in a state where a hole is formed on one side of the polyimide film but does not penetrate the surface on the other side.

### <Step of Peeling Off Inorganic Substrate>

The method for producing a flexible electronic device of the present invention includes a step of peeling off the inorganic substrate after an electronic device is formed on the polyimide film surface of the laminated body. When the inorganic substrate is peeled off, in addition to a case of peeling off the inorganic substrate at the interface between the polyimide film and the inorganic substrate, it is also possible to peel off the inorganic substrate together with one or more layers of the polyimide film composed of two or more layers or to peel off the inorganic substrate together with arbitrary another layer.

In a case where peeling off is performed at the interface between the polyimide film and the inorganic substrate, the method for peeling off the polyimide film with device from the inorganic substrate is not particularly limited, but a method in which the polyimide film is stripped off from the end with tweezers and the like, a method in which a cut is made into the polyimide film, a pressure sensitive adhesive tape is pasted to one side of the cut portion, and then the polyimide film is stripped off from the tape portion, a method in which one side of the cut portion of the polyimide film is vacuum-adsorbed and then the polyimide film is stripped off from that portion, and the like can be adopted. When the cut portion of the polyimide film is bent with a small curvature at the time of peeling off, stress may be applied to the device at that portion and the device may be destroyed, and it is thus desirable to peel off the polyimide film in a state of having a curvature as large as possible. For example, it is desirable to strip off the polyimide film while winding the polyimide film around a roll having a large curvature or to strip off the polyimide film using a machine having a configuration in which the roll having a large curvature is located at the peeling portion.

As the method for making a cut into the polyimide film, there are a method in which the polyimide film is cut using a cutting tool such as a cutter, a method in which the polyimide film is cut by scanning a laser and the laminated body relative to each other, a method in which the polyimide film is cut by scanning a water jet and the laminated body relative to each other, a method in which the polyimide film is cut while being cut a little to the glass layer using a dicing device for a semiconductor chip, and the like, but the method is not particularly limited. For example, when the above-described methods are adopted, it is also possible to appropriately adopt a method in which ultrasonic waves are superimposed on the cutting tool or a method in which a reciprocating motion, a vertical motion and the like are further added to improve the cutting performance.

It is also useful to stick another reinforcing base material to the portion to be peeled off in advance and peel off the polyimide film together with the reinforcing base. In a case where the flexible electronic device to be peeled off is the backplane of a display device, it is also possible to obtain a flexible display device by pasting the front plane of the display device in advance, integrating these on an inorganic substrate, and then peeling off these two at the same time.

In a case where the inorganic substrate is peeled off together with one or more layers of the polyimide film composed of two or more layers, the peel force at the interface of the polyimide film composed of two or more layers is adjusted so that the peel force is lighter than that at the interface with the inorganic substrate in advance, and the peeling off can be performed in the same manner as the methods described above. The peel force at the interface of the polyimide film can be adjusted by the kind of polyimide in each layer and the degree of imidization of the lower layer when the upper layer is applied.

In a case where the inorganic substrate is peeled off together with arbitrary another layer, an adhesive layer having higher close contact force with the inorganic substrate and adjusted peel force with the polyimide film, or the like is provided in advance, and the peeling off can be performed in the same manner as the methods described above.

### EXAMPLES

Hereinafter, the present invention will be described in detail with reference to Examples, but the present invention is not limited to the following Examples as long as the gist of the present invention is not exceeded. The respective physical property values in Synthesis Examples and Examples were measured by the following methods.

### <Coefficient of Static Friction>

The coefficient of static friction between the first and second surfaces of the polyimide film was measured using Tensilon Universal Material Testing Instrument RTG-1210 (manufactured by A&D Company, Limited) in an environment of 23° C. and 65% RH in conformity with JIS K-7125 (1999). Here, one surface of the two surfaces of the polyimide film is called the first surface and the other surface is called the second surface. Specifically, a film A measuring 10 cm×20 cm was cut out from a polyimide film, and the film A was fixed onto a smooth metal plate. Furthermore, a film B measuring 10 cm×5 cm was cut out from the polyimide film, and the film B was attached to a weight having a base area of 6 cm×5 cm and a weight of 4,400 g and placed on the film A which was fixed on a metal plate so as to overlap each other. At this time, the film B was placed on the film A so that the first surface and the second surface were in contact with each other. Thereafter, the film B was pulled at a speed of 200 mm/min, and the force generated at the moment the film B started to move, that is, the static friction force, was measured. The value acquired by dividing the static friction force by the normal force generated by the weight was taken as the coefficient of static friction μs. The same measurement was performed 3 times and the arithmetic mean value thereof was adopted.

### <Roll Slipperiness>

The finished polyimide film was wound into a roll, and the appearance of the polyimide film roll was evaluated. This is because scratches and wrinkles are generated by rubbing between polyimide films when the polyimide film is wound up in a case where the easily slipping properties of the polyimide film are not sufficient. Specifically, the polyimide film roll was visually inspected, and the roll slipperiness was judged as Favorable in a case where there were no scratches or wrinkles, and as Poor in a case where there were at least either scratches or wrinkles.

### <Measurement of Thickness of Polyimide Film>

The film thickness was measured using a micrometer (Millitron 1245D manufactured by Feinpruf GmbH). The same measurement was performed 3 times and the arithmetic mean value thereof was adopted.

### <Total Light Transmittance>

The total light transmittance (TT) of the films was measured using HAZEMETER (NDH5000 manufactured by NIPPON DENSHOKU INDUSTRIES CO., LTD.). A D65 lamp was used as the light source. The same measurement was performed 3 times and the arithmetic mean value thereof was adopted.

### <Haze>

The haze of the films was measured using HAZEMETER (NDH5000 manufactured by NIPPON DENSHOKU INDUSTRIES CO., LTD.). A D65 lamp was used as the light source. The same measurement was performed 3 times and the arithmetic mean value thereof was adopted.

### <Yellow Index>

Using a color meter (ZE6000 manufactured by NIPPON DENSHOKU INDUSTRIES CO., LTD.) and a C2 light source, the tristimulus values, XYZ values of the films were measured in conformity with ASTM D1925, and the yellow index (YI) was calculated by the following equation. The same measurement was performed 3 times and the arithmetic mean value thereof was adopted.

$$YI = 100 \times ( 1. 28 X - 1. 06 Z ) / Y$$

### <Refractive Index, Retardation (Rth)>

The refractive index was measured using an Abbe refractometer (NAR-4T, ATAGO), and the out-of-plane retardation Rth was calculated. Specifically, the refractive indexes (Nx, Nz) and (Ny, Nz) of the film were measured, respectively, and AP was calculated by the following equation. Furthermore, AP was multiplied by the film thickness (unit: μm) to calculate the out-of-plane retardation Rth (nm). Rth is expressed as the average value for the front and back surfaces of the film.

$$Δ P = ( Nx + Ny ) / 2 - Nz \\ Rth ( nm ) = Δ P \times thickness \times 1000$$

Thermal decomposition temperature (Td₁) The measurement was performed using a TGA instrument (TGA-50, Shimadzu Corporation). The measurement was performed by placing about 10 mg of the film on an aluminum pan in a nitrogen atmosphere and raising the temperature at a rate of 10° C./min. Using the weight when the temperature reached 150° C. as the starting point, the temperature (1% weight loss temperature: Td₁) when the weight decreased by 1% was read.

### <Glass Transition Temperature (Tg), Coefficient of Linear Thermal Expansion (CTE)>

The measurement was performed using TMA (TMA4000S, BRUKER AXIS). The film was cut into a strip measuring 15 mm in width and 2 mm in length, and set in the instrument with a chuck distance of 10 mm and a load of 5 gf. In an argon atmosphere, the temperature was increased to 250° C. at a rate of 20° C./min, and then decreased to 30° C. at a rate of 5° C./min. The temperature was then increased at 10° C./min to a temperature (Td1−20° C.) at which thermal decomposition did not take place. CTE was calculated from the slope in the zone of 200° C. to 50° C. during the temperature drop, and the inflection point during the second temperature rise was taken as Tg.

### <Tensile Modulus, Tensile Strength, Elongation, Tensile Product>

The test was carried out using Tensilon (Autograph AG-IS, Shimadzu Corporation) as follows. The film was cut into a strip shape measuring 5 mm in machine direction (MD direction) during coating and 50 mm in length to prepare a test piece. Both ends of the strip were held at 30 mm with air jaw chucks, and the tensile modulus, tensile strength at break, and elongation at break in the MD direction were determined under conditions of room temperature and a tension speed of 50 mm/min. The tensile modulus was determined from the initial elastic slope of the strain-stress curve. The measurement was performed N=5 at each level, and the average value at three points excluding the maximum and minimum values was treated as data. The product of the tensile strength at break and elongation at break was taken as the tensile product.

### <¹HNMR Measurement of Silsesquioxane Compound Having Acid Anhydride Group>

Using each sample, ¹H NMR measurement was performed under the following conditions.

Instrument: DPX400 manufactured by Bruker BioSpin

### (Examples 1 and 2) or 400MR manufactured by Agilent

### Examples 3 to 9

Solvent: Deuterated chloroform (CDCl₃) (Examples 1 and 2) or deuterated DMSO (DMSO-d₆) (Examples 3 to 9)
Sample concentration: 3 mg/1 mL
Measured temperature: Room temperature (24° C.)
Resonance frequency: 400 MHz
Cumulative number: 32 times

### Examples 1 to 9 and Comparative Examples 1 to 6 and 8

First, Examples 1 to 9 and Comparative Examples 1 to 6 and 8 will be described. Specifically, with regard to these, the synthesis of silsesquioxane compounds, the synthesis of the polyamic acid solutions, the formation of polyimide films, various evaluation results, and the like will be described.

### Synthesis Example 1-1: Synthesis of Thiol Group-Containing Silsesquioxane Compound 1

A reactor equipped with a stirrer, a cooling pipe, a water diverting unit, a thermometer, a dropping funnel, and a nitrogen blowing port was charged with 11.8 g (60.0 mmol) of 3-mercaptopropyltrimethoxysilane, 2.72 g (20.0 mmol) of methyltrimethoxysilane ([number of moles of component (a2)]/[total number of moles of components (a1) and (a2)]=0.25), 1.9 g of ion-exchanged water ([number of moles of water used in hydrolysis reaction]/[total number of moles of alkoxy groups contained in components (a1) and (a2)](molar ratio)=0.45), and 1.0 g of a cation exchange resin, and the hydrolysis reaction was conducted at room temperature for 30 minutes. After the reaction, the cation exchange resin was filtered off, and the resultant was diluted with 5 g of ethylene glycol dimethyl ether (DMG) to obtain a hydrolysate solution.

Next, 9 g of DMG and 0.05 g of a 25% aqueous solution of tetramethylammonium hydroxide were charged into another reaction vessel and heated to 80° C. The hydrolysate solution obtained above was added dropwise thereto over 2 hours and 30 minutes. During the dropwise addition, tetramethylammonium hydroxide was dissolved and the reaction solution became clear. After the dropwise addition, the reaction was further conducted at 80° C. for 15 minutes and then cooling to 25° C. was performed. To the resultant, 0.5 g of a cation exchange resin was added, and stirring was performed at room temperature for 4 hours. During stirring, tetramethylammonium hydroxide was adsorbed and the reaction solution became clear. The cation exchange resin was filtered off to obtain a solution of thiol group-containing silsesquioxane (average number of thiol groups per molecule=6). Toluene was added, and heating to 70° C. was performed under reduced pressure to distill off methanol and water generated by hydrolysis, as well as a portion of toluene. Toluene was further added appropriately to adjust the final solid concentration to 72%.

### Synthesis Example 1-2: Synthesis of Thiol Group-Containing Silsesquioxane Compound 2

The synthesis was carried out in the same manner as in Synthesis Example 1-1, except that 8.83 g (45.0 mmol) of 3-mercaptopropyltrimethoxysilane, 5.44 g (40.0 mmol) of methyltrimethoxysilane ([number of moles of component (a2)]/[total number of moles of components (a1) and (a2)]=0.47), and 2.0 g of ion-exchanged water ([number of moles of water used in hydrolysis reaction]/[total number of moles of alkoxy groups contained in components (a1) and (a2)](molar ratio)=0.45) were used. The average number of thiol groups per molecule of the obtained thiol group-containing silsesquioxane was 4.5, and the final solid concentration was 72% by mass.

### Synthesis Example 1-3: Synthesis of Thiol Group-Containing Silsesquioxane Compound 3

The synthesis was carried out in the same manner as in Synthesis Example 1-1, except that 4.91 g (25.0 mmol) of 3-mercaptopropyltrimethoxysilane, 6.81 g (50.0 mmol) of methyltrimethoxysilane ([number of moles of component (a2)]/[total number of moles of components (a1) and (a2)]=0.67), and 1.8 g of ion-exchanged water ([number of moles of water used in hydrolysis reaction]/[total number of moles of alkoxy groups contained in components (a1) and (a2)](molar ratio)=0.45) were used. The average number of thiol groups per molecule of the obtained thiol group-containing silsesquioxane was 2.5, and the final solid concentration was 72% by mass.

### Synthesis Example 2-1: Synthesis of Silsesquioxane SQ1 Having Acid Anhydride Group

Into a reaction vessel, 10 g (thiol group amount 16.7 mmol) of the following thiol group-containing silsesquioxane solution (COMPOCERAN SQ-109 manufactured by ARAKAWA CHEMICAL INDUSTRIES, LTD.) and 2.74 g (16.7 mmol) of norbornene acid anhydride were charged and irradiated with ultraviolet light (Spot Cure SP-11, USHIO LIGHTING, INC.) for 20 minutes while being stirred, thereby obtaining a silsesquioxane SQ1 having an acid anhydride group as a colorless and transparent solution. By NMR and IR measurement, it was confirmed that the thiol group had reacted with norbornene. The obtained solution was filtered through a PTFE filter (pore size 10 μm) and then used in the synthesis of a polyamic acid solution described later (the same applies to SQ3 to SQ9).

COMPOCERAN SQ-109: Condensate of methyltrimethoxysilane and 3-mercaptopropyltrimethoxysilane, molar ratio (former/(former+latter))=2/8, solvent: PGMEA, solid concentration: 25% by mass.

The molar ratio and the average number of thiol groups per molecule were calculated as follows. In the ¹H NMR measurement of COMPOCERAN SQ-109, the molar ratio of methyltrimethoxysilane to 3-mercaptopropyltrimethoxysilane was calculated from the integral ratio of the protons derived from the methyl group (δ=near 0.0 to 0.2, 3H) and the protons derived from the propylthiol group (δ=near 0.2 to 0.8, 2H). The average number of thiol groups per molecule was calculated from the ratio of thiol groups to methyl groups, the molecular weight per structural unit (SiO_{1.5}Me=67.1, SiO_{1.5}C₃H₆SH=127.2), the thiol group equivalent of the solution (600 g/eq.), and the solid concentration of 25% by mass.

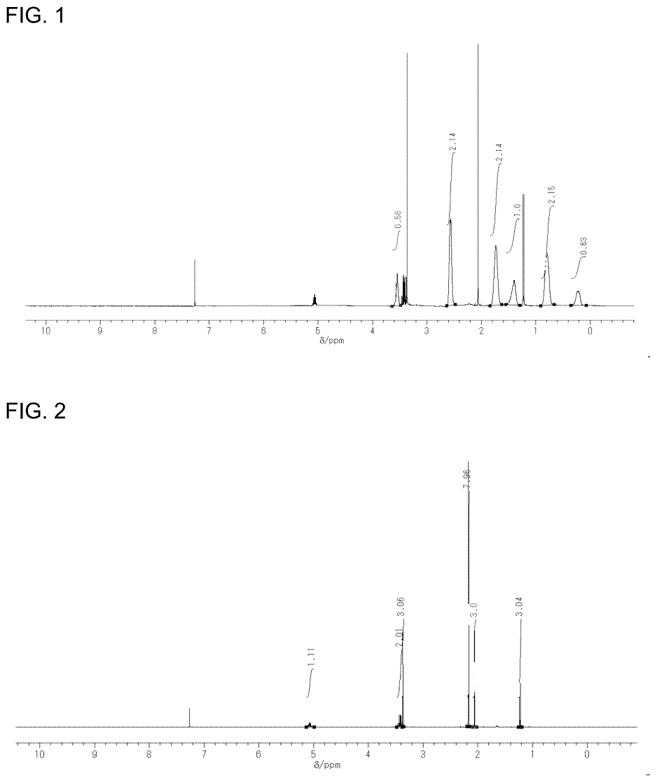

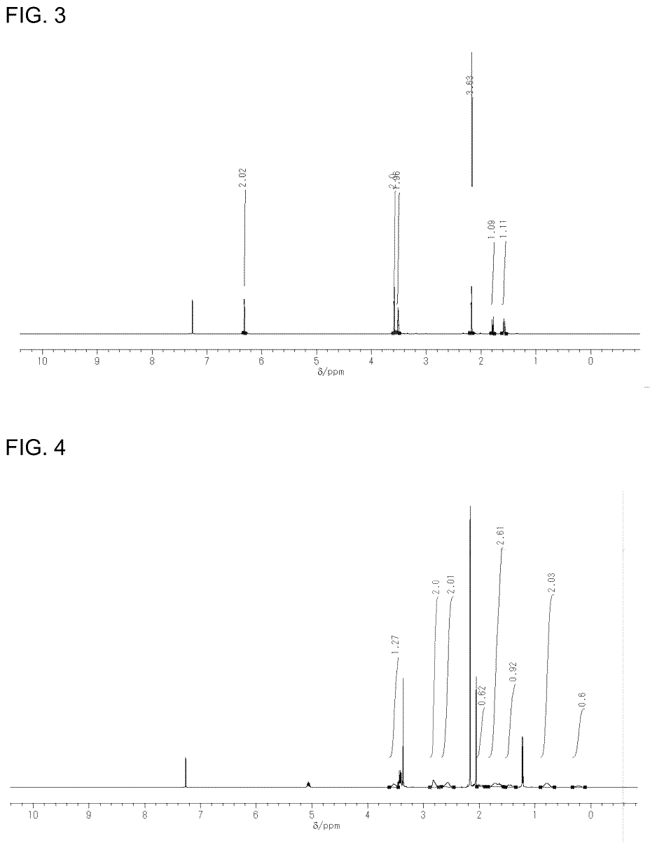

For reference, the results of NMR measurement are illustrated in FIGS. 1 to 4. FIG. 1 illustrates the 1H NMR (CDCl₃) spectrum of SQ109 (PGMEA solution), FIG. 2 illustrates the ¹H NMR (CDCl₃) spectrum of PGMEA, FIG. 3 illustrates the ¹H NMR (CDCl₃) spectrum of norbornene acid anhydride, and FIG. 4 illustrates the 1H NMR (CDCl₃) spectrum of the reaction mixture after the reaction. In FIG. 4, the peaks (δ=6.3 and the like) attributed to the double bond of norbornene acid anhydride have disappeared, and this suggests that the reaction between the thiol group and the double bond has taken place.

### Synthesis Example 2-2: Synthesis of Silsesquioxane SQ2 Having Acid Anhydride Group

Into a reaction vessel, 10 g (thiol group amount 16.7 mmol) of thiol group-containing silsesquioxane solution (COMPOCERAN SQ-109 manufactured by ARAKAWA CHEMICAL INDUSTRIES, LTD.), 2.74 g (16.7 mmol) of norbornene acid anhydride, and 1 mg of iron(III) chloride were charged and stirred for 10 minutes, thereby obtaining a silsesquioxane SQ2 having an acid anhydride group as a pale yellow solution (the yellow color is considered to come from iron chloride). By NMR and IR measurement, it was confirmed that the thiol group had reacted with norbornene.

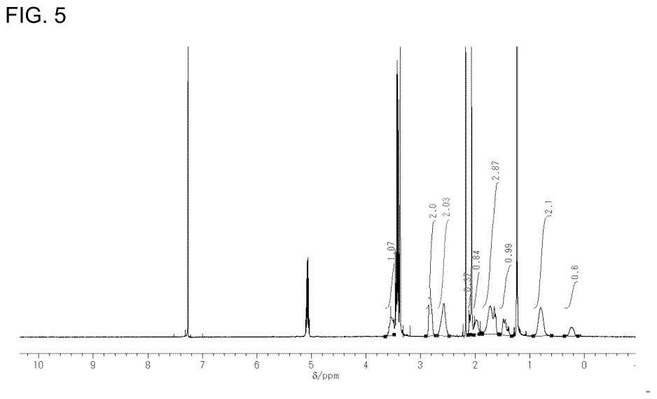

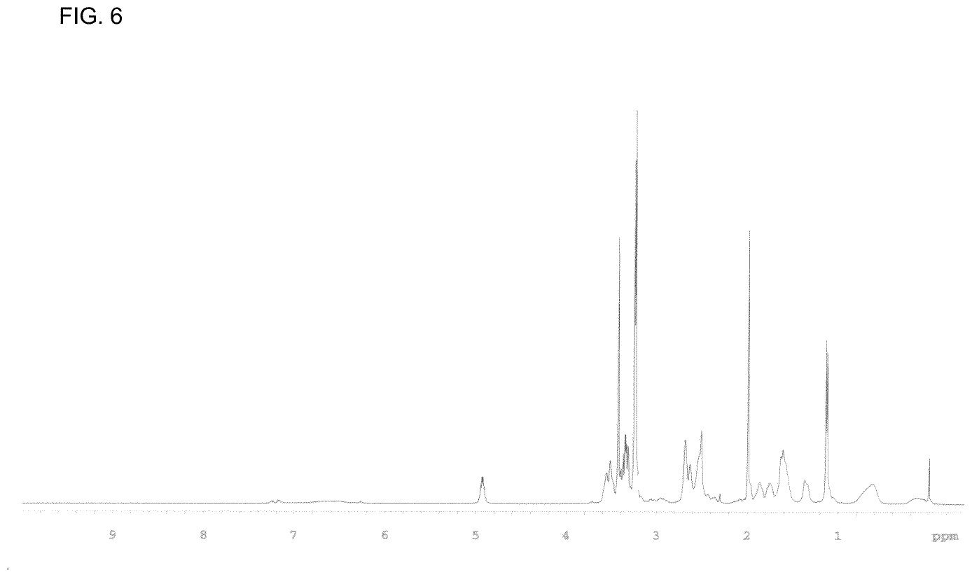

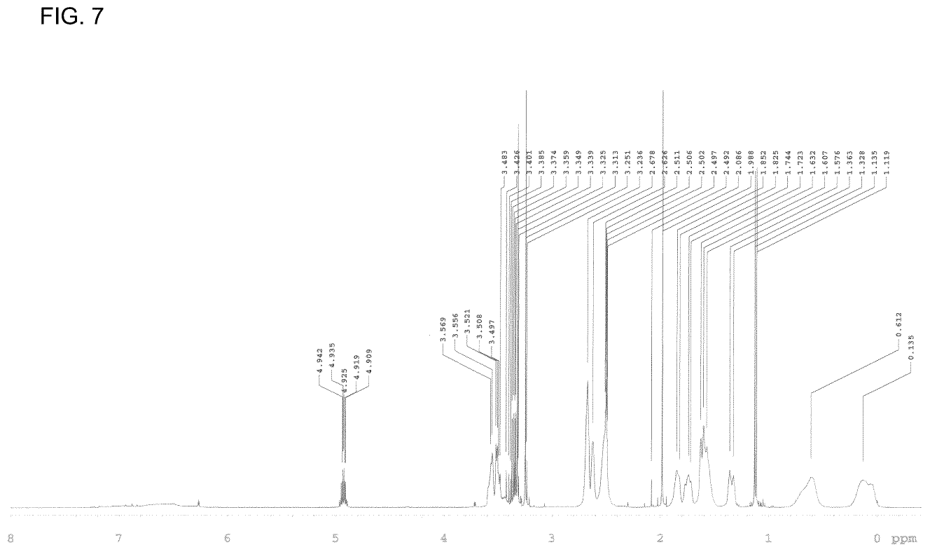

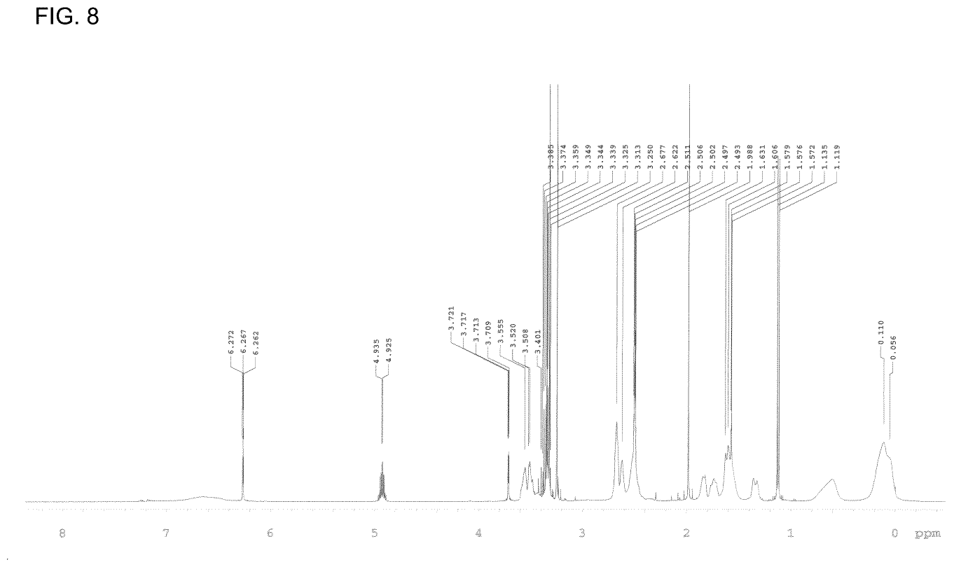

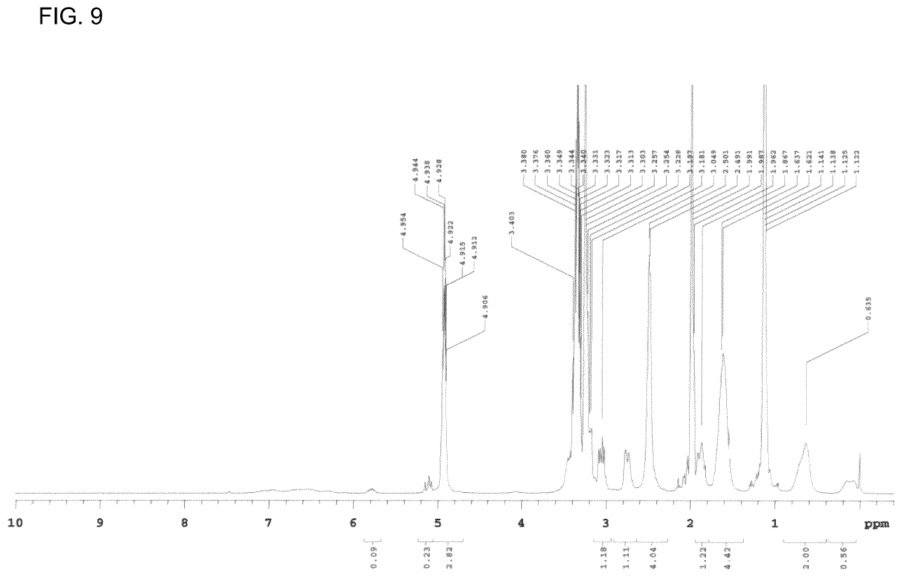

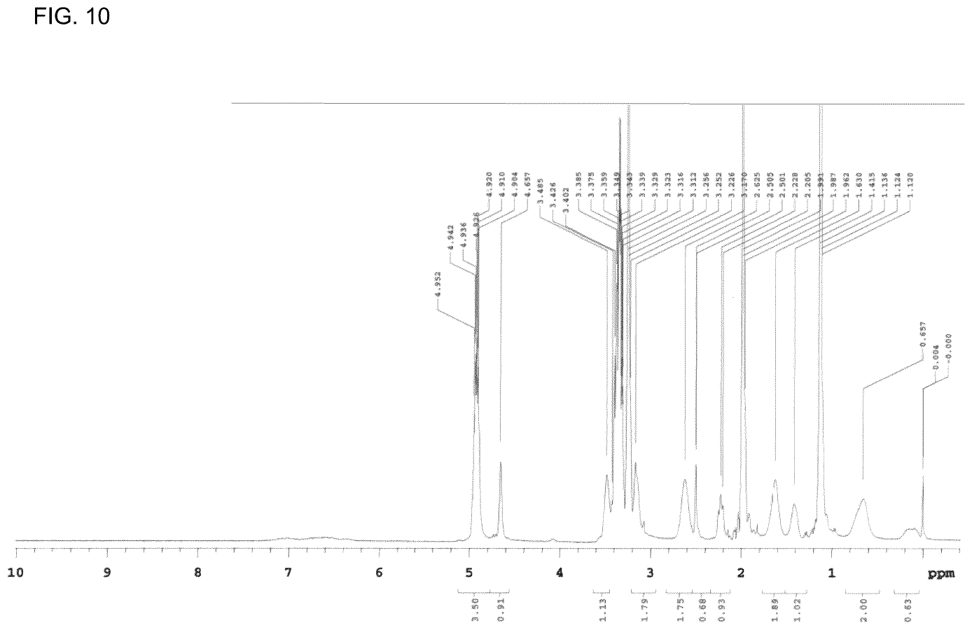

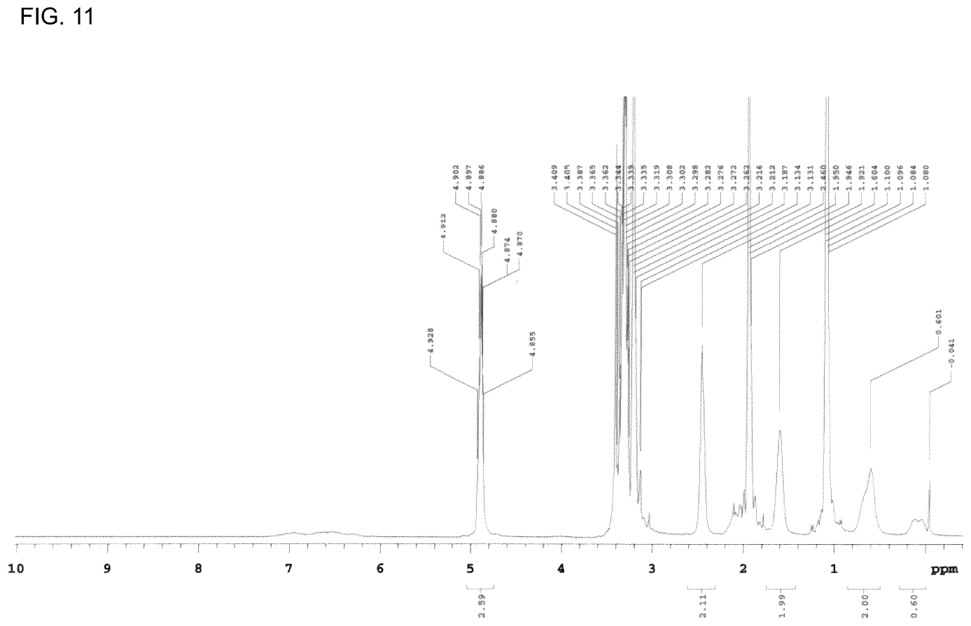

For reference, as the results of NMR measurement, FIG. 5 illustrates the 1H NMR (CDCl₃) spectrum of the reaction mixture after the reaction. In FIG. 5, the peaks (5=6.3 and the like) attributed to the double bond of norbornene acid anhydride have disappeared, and this suggests that the reaction between the thiol group and the double bond has taken place.

### Synthesis Example 2-3: Synthesis of Silsesquioxane SQ3 Having Acid Anhydride Group

Into a reaction vessel, 20 g (thiol group amount 97.0 mmol) of the solution of thiol group-containing silsesquioxane compound 1 obtained in Synthesis Example 1-1, 15.9 g (97.0 mmol) of norbornene acid anhydride, and 10.0 g of PGMEA were charged and irradiated with ultraviolet light (Spot Cure SP-11, USHIO LIGHTING, INC.) for 20 minutes while being stirred, thereby obtaining a silsesquioxane SQ3 having an acid anhydride group as a colorless and transparent solution. By NMR and IR measurement, it was confirmed that the thiol group had reacted with norbornene.

### Synthesis Example 2-4: Synthesis of Silsesquioxane SQ4 Having Acid Anhydride Group

Into a reaction vessel, 20 g (thiol group amount 77.9 mmol) of the solution of thiol group-containing silsesquioxane compound 2 obtained in Synthesis Example 1-2, 12.8 g (77.9 mmol) of norbornene acid anhydride, and 10.0 g of PGMEA were charged and irradiated with ultraviolet light (Spot Cure SP-11, USHIO LIGHTING, INC.) for 20 minutes while being stirred, thereby obtaining a silsesquioxane SQ4 having an acid anhydride group as a colorless and transparent solution. By NMR and IR measurement, it was confirmed that the thiol group had reacted with norbornene.

### Synthesis Example 2-5: Synthesis of Silsesquioxane SQ5 Having Acid Anhydride Group

Into a reaction vessel, 20 g (thiol group amount 54.5 mmol) of the solution of thiol group-containing silsesquioxane compound 3 obtained in Synthesis Example 1-3, 8.95 g (54.5 mmol) of 5-norbornene-2,3-dicarboxylic anhydride, and 10.0 g of PGMEA were charged and irradiated with ultraviolet light (Spot Cure SP-11, USHIO LIGHTING, INC.) for 20 minutes while being stirred, thereby obtaining a silsesquioxane SQ5 having an acid anhydride group as a colorless and transparent solution. By NMR and IR measurement, it was confirmed that the thiol group had reacted with 5-norbornene-2,3-dicarboxylic anhydride.

### Synthesis Example 2-6: Synthesis of Silsesquioxane SQ6 Having Acid Anhydride Group

Into a reaction vessel, 6 g (thiol group amount 10.0 mmol) of thiol group-containing silsesquioxane solution (COMPOCERAN SQ-109 manufactured by ARAKAWA CHEMICAL INDUSTRIES, LTD.) and 1.40 g (10.0 mmol) of allylsuccinic anhydride were charged and irradiated with ultraviolet light (Spot Cure SP-11, USHIO LIGHTING, INC.) for 20 minutes while being stirred, thereby obtaining a silsesquioxane SQ6 having an acid anhydride group as a colorless and transparent solution. By NMR and IR measurement, it was confirmed that the thiol group had reacted with allylsuccinic anhydride.

### Synthesis Example 2-7: Synthesis of Silsesquioxane SQ7 Having Acid Anhydride Group

Into a reaction vessel, 6 g (thiol group amount 10.0 mmol) of thiol group-containing silsesquioxane solution (COMPOCERAN SQ-109 manufactured by ARAKAWA CHEMICAL INDUSTRIES, LTD.) and 1.66 g (10.0 mmol) of exo-3,6-epoxy-1,2,3,6-tetrahydrophthalic anhydride were charged and irradiated with ultraviolet light (Spot Cure SP-11, USHIO LIGHTING, INC.) for 20 minutes while being stirred, thereby obtaining a silsesquioxane SQ7 having an acid anhydride group as a colorless and transparent solution. By NMR and IR measurement, it was confirmed that the thiol group had reacted with exo-3,6-epoxy-1,2,3,6-tetrahydrophthalic anhydride.

### Synthesis Example 2-8: Synthesis of Silsesquioxane SQ8 Having Acid Anhydride Group

Into a reaction vessel, 3 g (thiol group amount 5.0 mmol) of thiol group-containing silsesquioxane solution (COMPOCERAN SQ-109 manufactured by ARAKAWA CHEMICAL INDUSTRIES, LTD.), 0.94 g (5.0 mmol) of 5,6-dihydro-1,4-dithiine-2,3-dicarboxylic anhydride, and γ-butyrolactone (5 mL) were charged and irradiated with ultraviolet light (Spot Cure SP-11, USHIO LIGHTING, INC.) for 20 minutes while being stirred, thereby obtaining a silsesquioxane SQ8 having an acid anhydride group as a colorless and transparent solution. By NMR and IR measurement, it was confirmed that the thiol group had reacted with 5,6-dihydro-1,4-dithiine-2,3-dicarboxylic anhydride.

### Synthesis Example 2-9: Synthesis of Silsesquioxane SQ9 Having Acid Anhydride Group

Into a reaction vessel, 6 g (thiol group amount 10.0 mmol) of thiol group-containing silsesquioxane solution (COMPOCERAN SQ-109 manufactured by ARAKAWA CHEMICAL INDUSTRIES, LTD.) was charged, and 2.10 g (10.0 mmol) of trimellitic anhydride chloride was slowly added while stirring was performed. Stirring was performed at room temperature for 24 hours, thereby obtaining a silsesquioxane SQ9 having an acid anhydride group as a colorless and transparent solution. By NMR and IR measurement, it was confirmed that the thiol group had reacted with the acid chloride group.

### Example A: Synthesis of Polyamic Acid Solution A

While nitrogen was allowed to pass through a reactor equipped with a nitrogen inlet tube and a stirrer, 1,2,3,4-cyclobutanetetracarboxylic dianhydride (CBDA, 5.88 g), 4,4′-diamino-2,2′-bis(trifluoromethyl)biphenyl (TFMB, 9.74 g), and the SQ1 solution (0.655 g) were charged, dissolved in N,N-dimethylacetamide (DMAc, 125.0 g), and then stirred at 25° C. for 24 hours, thereby obtaining a polyamic acid solution A (molar ratio of CBDA/SQ1/TFMB=0.985/0.015/1.00). Here, the molar ratio of SQ1 is a value calculated based on the molar ratio per divalence of the acid anhydride group, and is specifically calculated as the number acquired by dividing the total number of moles of the unit structures derived from the silsesquioxane compound by the total number of the dicarboxylic anhydride groups and multiplying the result by two (the same applies to the following molar ratios).

### Example B: Synthesis of Polyamic Acid Solution B

While nitrogen was allowed to pass through a reactor equipped with a nitrogen inlet tube and a stirrer, 1,2,3,4-cyclobutanetetracarboxylic dianhydride (CBDA, 5.88 g), 4,4′-diaminobenzanilide (DABA, 6.92 g), and the SQ1 solution (0.655 g) were charged, dissolved in N,N-dimethylacetamide (DMAc, 133.7 g), and then stirred at 25° C. for 24 hours, thereby obtaining a polyamic acid solution B (molar ratio of CBDA/SQ1/DABA=0.985/0.015/1.00).

### Example Ca: Synthesis of Polyamic Acid Solution Ca

While nitrogen was allowed to pass through a reactor equipped with a nitrogen inlet tube and a stirrer, pyromellitic dianhydride (PMDA, 3.27 g), 4,4′-diamino-2,2′-bis(trifluoromethyl)biphenyl (TFMB, 4.88 g), and the SQ1 solution (0.328 g) were charged, dissolved in N,N-dimethylacetamide (DMAc, 67.0 g), and then stirred at 25° C. for 24 hours, thereby obtaining a polyamic acid solution Ca (molar ratio of PMDA/SQ1/TFMB=0.985/0.015/1.00).

### Example Cb: Synthesis of Polyamic Acid Solution Cb

While nitrogen was allowed to pass through a reactor equipped with a nitrogen inlet tube and a stirrer, pyromellitic dianhydride (PMDA, 3.27 g), 4,4′-diamino-2,2′-bis(trifluoromethyl)biphenyl (TFMB, 4.90 g), and the SQ3 solution (0.227 g) were charged, dissolved in N-methyl-2-pyrrolidone (M4P, 66.0 g), and then stirred at 25° C. for 24 hours, thereby obtaining a polyamic acid solution Cb (molar ratio of PMDA/SQ3/TFMB=0.98/0.02/1.00).

### Example Cc: Synthesis of Polyamic Acid Solution Cc

While nitrogen was allowed to pass through a reactor equipped with a nitrogen inlet tube and a stirrer, pyromellitic dianhydride (PMDA, 3.27 g), 4,4′-diamino-2,2′-bis(trifluoromethyl)biphenyl (TFMB, 4.90 g), and the SQ4 solution (0.258 g) were charged, dissolved in N-methyl-2-pyrrolidone (M4P, 66.0 g), and then stirred at 25° C. for 24 hours, thereby obtaining a polyamic acid solution Cc (molar ratio of PMDA/SQ4/TFMB=0.98/0.02/1.00).

### Example Cd: Synthesis of Polyamic Acid Solution Cd

While nitrogen was allowed to pass through a reactor equipped with a nitrogen inlet tube and a stirrer, pyromellitic dianhydride (PMDA, 3.27 g), 4,4′-diamino-2,2′-bis(trifluoromethyl)biphenyl (TFMB, 4.90 g), and the SQ5 solution (0.325 g) were charged, dissolved in N-methyl-2-pyrrolidone (M4P, 66.0 g), and then stirred at 25° C. for 24 hours, thereby obtaining a polyamic acid solution Cd(molar ratio of PMDA/SQ5/TFMB=0.98/0.02/1.00).

### Example Ce: Synthesis of Polyamic Acid Solution Ce

While nitrogen was allowed to pass through a reactor equipped with a nitrogen inlet tube and a stirrer, pyromellitic dianhydride (PMDA, 3.27 g), 4,4′-diamino-2,2′-bis(trifluoromethyl)biphenyl (TFMB, 4.90 g), and the SQ9 solution (0.354 g) were charged, dissolved in N-methyl-2-pyrrolidone (M4P, 66.0 g), and then stirred at 25° C. for 24 hours, thereby obtaining a polyamic acid solution Ce (molar ratio of PMDA/SQ9/TFMB=0.985/0.015/1.00).

### Example D: Synthesis of Polyamic Acid Solution D

While nitrogen was allowed to pass through a reactor equipped with a nitrogen inlet tube and a stirrer, pyromellitic dianhydride (PMDA, 3.27 g), 4,4′-diaminobenzanilide (DABA, 3.47 g), and the SQ1 solution (0.328 g) were charged, dissolved in N,N-dimethylacetamide (DMAc, 63.0 g), and then stirred at 25° C. for 24 hours, thereby obtaining a polyamic acid solution D (molar ratio of PMDA/SQ1/DABA=0.985/0.015/1.00).

### Comparative Example A1: Synthesis of Polyamic Acid Solution A1

While nitrogen was allowed to pass through a reactor equipped with a nitrogen inlet tube and a stirrer, 1,2,3,4-cyclobutanetetracarboxylic dianhydride (CBDA, 19.6 g) and 4,4′-diamino-2,2′-bis(trifluoromethyl)biphenyl (TFMB, 32.3 g) were charged, dissolved in N,N-dimethylacetamide (DMAc, 279.0 g), and then stirred at 25° C. for 24 hours, thereby obtaining a polyamic acid solution A1 (molar ratio of CBDA/TFMB=1.00/1.00).

### Comparative Example B1: Synthesis of Polyamic Acid Solution B1

While nitrogen was allowed to pass through a reactor equipped with a nitrogen inlet tube and a stirrer, 1,2,3,4-cyclobutanetetracarboxylic dianhydride (CBDA, 3.98 g) and 4,4′-diaminobenzanilide (DABA, 4.58 g) were charged, dissolved in N,N-dimethylacetamide (DMAc, 76.0 g), and then stirred at 25° C. for 24 hours, thereby obtaining a polyamic acid solution B1 (molar ratio of CBDA/DABA=1.00/1.00).

### Comparative Example B2: Synthesis of Polyamic Acid Solution B2

While nitrogen was allowed to pass through a reactor equipped with a nitrogen inlet tube and a stirrer, 1,2,3,4-cyclobutanetetracarboxylic dianhydride (CBDA, 2.94 g), 4,4′-diaminobenzanilide (DABA, 3.54 g), and the SQ1 solution (1.00 g) were charged, dissolved in N,N-dimethylacetamide (DMAc, 90 g), and then stirred at 25° C. for 24 hours, thereby obtaining a polyamic acid solution B2 (molar ratio of CBDA/SQ1/DABA=0.955/0.045/1.00).

### Comparative Example B4: Synthesis of Polyamic Acid Solution B4

While nitrogen was allowed to pass through a reactor equipped with a nitrogen inlet tube and a stirrer, 1,2,3,4-cyclobutanetetracarboxylic dianhydride (CBDA, 3.98 g) and 4,4′-diaminobenzanilide (DABA, 4.55 g) were charged, dissolved in N,N-dimethylacetamide (DMAc, 76.0 g), and then stirred at 25° C. for 24 hours. Thereafter, SQ-109 (0.546 g) was added, and stirring was performed for an additional 24 hours, thereby obtaining a polyamic acid solution B4 (molar ratio of CBDA/DABA/SQ-109=1.00/1.00/0.01).

### Comparative Example B5: Synthesis of Polyamic Acid Solution B5

While nitrogen was allowed to pass through a reactor equipped with a nitrogen inlet tube and a stirrer, 1,2,3,4-cyclobutanetetracarboxylic dianhydride (CBDA, 3.98 g) and 4,4′-diaminobenzanilide (DABA, 4.55 g) were charged, dissolved in N,N-dimethylacetamide (DMAc, 76.0 g), and then stirred at 25° C. for 24 hours. Thereafter, SQ-109 (8.19 g) was added, and stirring was performed for an additional 24 hours, thereby obtaining a polyamic acid solution B5 (molar ratio of CBDA/DABA/SQ-109=1.00/1.00/0.15).

### Comparative Example B6: Synthesis of Polyamic Acid Solution B6

While nitrogen was allowed to pass through a reactor equipped with a nitrogen inlet tube and a stirrer, 1,2,3,4-cyclobutanetetracarboxylic dianhydride (CBDA, 3.98 g) and 4,4′-diaminobenzanilide (DABA, 4.55 g) were charged, dissolved in N,N-dimethylacetamide (DMAc, 76.0 g), and then stirred at 25° C. for 24 hours. Thereafter, SQ-109 (27.3 g) was added, and stirring was performed for an additional 24 hours, thereby obtaining a polyamic acid solution B6 (molar ratio of CBDA/DABA/SQ-109=1.00/1.00/0.50).

### Comparative Example C1: Synthesis of Polyamic Acid Solution C1

While nitrogen was allowed to pass through a reactor equipped with a nitrogen inlet tube and a stirrer, pyromellitic dianhydride (PMDA, 6.54 g) and 4,4′-diamino-2,2′-bis(trifluoromethyl)biphenyl (TFMB, 9.61 g) were charged, dissolved in N,N-dimethylacetamide (DMAc, 164.0 g), and then stirred at 25° C. for 24 hours, thereby obtaining a polyamic acid solution C1 (molar ratio of PMDA/TFMB=1.00/1.00).

### Comparative Example D1: Synthesis of Polyamic Acid Solution D1

While nitrogen was allowed to pass through a reactor equipped with a nitrogen inlet tube and a stirrer, pyromellitic dianhydride (PMDA, 3.27 g) and 4,4′-diaminobenzanilide (DABA, 3.41 g) were charged, dissolved in N,N-dimethylacetamide (DMAc, 63.0 g), and then stirred at 25° C. for 24 hours, thereby obtaining a polyamic acid solution D1 (molar ratio of PMDA/DABA=1.00/1.00).

The polyamic acid solutions obtained in Examples and Comparative Examples above were formed into films by the following method, and the optical properties, thermal properties, and mechanical properties of the films were measured.

### Example 1

The polyamic acid solution A was applied onto a polyester film (A4100, Toyobo product) using a casting applicator, and heated at 100° C. for 18 minutes in a nitrogen atmosphere. The obtained green film was cut with a cutter, peeled off from the polyester film, and fixed to a metal frame. Thermal imidization was carried out by performing heating sequentially at 200° C. for 10 minutes, at 250° C. for 10 minutes, at 300° C. for 10 minutes, and at 350° C. for 10 minutes while gradually increasing the temperature at a rate of 10° C./min in a nitrogen atmosphere. After cooling, the film was detached from the metal frame to obtain a polyimide film.

### Examples 2 to 5

Polyimide films were obtained in the same manner as in Example 1, except that the polyamic acid solutions B, Ca to Ce, D, and B2 were used instead of the polyamic acid solution A in Example 1. The components used at that time and the evaluation results are presented in Table 1.

### Comparative Examples 1 to 9

Polyimide films were obtained in the same manner as in Example 1, except that the polyamic acid solutions A1, B1, B4, B5, B6, C1 and D1 were used instead of the polyamic acid solution A in Example 1. The components used at that time and the evaluation results are presented in Table 1.

TABLE 1

| | | Example | Example | Example | Example | Example | Example | Example | Example |
|---|---|---|---|---|---|---|---|---|---|
| | | 1 | 2 | 3a | 3b | 3c | 3d | 3e | 4 |
| Polyamic acid solution | | A | B | Ca | Cb | Cc | Cd | Ce | D |
| Charged mol % of acid | CBDA | 98.5 | 98.5 | — | — | — | — | — | — |
| component | PMDA | — | — | 98.5 | 98 | 98 | 98 | 98.5 | 98.5 |
| Charged mol % of | TFMB | 100 | — | 100 | 100 | 100 | 100 | 100 | — |
| diamine component | DABA | — | 100 | — | — | — | — | — | 100 |
| Charged mol % of | SQ1 | 1.5 | 1.5 | 1.5 | — | — | — | — | 1.5 |
| silsesquioxane | SQ3 | — | — | — | 2 | — | — | — | — |
| | SQ4 | — | — | — | — | 2 | — | — | — |
| | SQ5 | — | — | — | — | — | 2 | — | — |
| | SQ9 | — | — | — | — | — | — | 1.5 | — |
| | SQ-109 | — | — | — | — | — | — | — | — |
| Solution appearance | | — | — | — | — | — | — | — | — |
| Special note | | | | | | | | | |
| Film thickness | μm | 7 | 13 | 15 | 18 | 17 | 19 | 17 | 13 |
| Total light | % | 90.3 | 86.2 | 87.4 | 83.4 | 85.2 | 83.8 | 86.2 | 61.3 |
| transmittance | | | | | | | | | |
| Haze | % | 0.3 | 0.4 | 0.2 | 0.3 | 0.3 | 0.3 | 2.2 | 0.3 |
| Yellow index | | 1.8 | 5.7 | 7.0 | 18.7 | 14.7 | 17.2 | 9.4 | 102.8 |
| Tg | ° C. | 392 | > 450 | > 450 | > 450 | > 450 | > 450 | > 450 | > 450 |
| CTE | ppm/K | 34 | 16 | 8 | 7 | 5 | 1 | 0 | 5 |
| Tensile product | MPa · % | 1320 | 1337 | 1440 | 1701 | 1757 | 1000 | 1020 | 3465 |
| Strength at break | MPa | 165 | 191 | 240 | 243 | 251 | 250 | 170 | 231 |
| Elongation at break | % | 8 | 7 | 6 | 7 | 7 | 4 | 6 | 15 |
| Tensile modulus | GPa | 5.2 | 6.8 | 7.6 | 7.6 | 7.6 | 7.6 | 7.6 | 7.7 |
| Coefficient of | | 2.0 | 1.8 | 2.0 | 1.7 | 1.7 | 1.7 | 1.9 | 1.9 |
| static friction | | | | | | | | | |
| | | | Com- | Com- | Com- | Com- | Com- | Com- | Com- |
| | | Example | parative | parative | parative | parative | parative | parative | parative |
| | | 5 | Example 1 | Example 2 | Example 3 | Example 4 | Example 5 | Example 6 | Example 9 |
| Polyamic acid solution | | B2 | A1 | B1 | B4 | B5 | B6 | C1 | D1 |
| Charged mol % of acid | CBDA | 95.5 | 100 | 100 | 100 | 100 | 100 | — | — |
| component | PMDA | — | — | — | — | — | — | 100 | 100 |
| Charged mol % of | TFMB | — | 100 | — | — | — | — | 100 | — |
| diamine component | DABA | 100 | — | 100 | 100 | 100 | 100 | — | 100 |
| Charged mol % of | SQ1 | 4.5 | — | — | — | — | — | — | — |
| silsesquioxane | SQ3 | — | — | — | — | — | — | — | — |
| | SQ4 | — | — | — | — | — | — | — | — |
| | SQ5 | — | — | — | — | — | — | — | — |
| | SQ9 | — | — | — | — | — | — | — | — |
| | SQ-109 | — | — | — | 1 | 15 | 50 | — | — |
| Solution appearance | | Small amount | — | — | — | Cloudiness | Cloudiness | — | — |
| Special note | | of gel | | | | | | | |
| Film thickness | μm | 13 | 15 | 15 | 17 | 26 | 26 | 15 | 15 |
| Total light | % | 86.0 | 89.8 | 86.2 | 85.9 | 68.7 | 36.2 | 87.2 | 66.7 |
| transmittance | | | | | | | | | |
| Haze | % | 0.4 | 0.3 | 0.3 | 0.4 | 5.8 | 78.2 | 0.3 | 0.2 |
| Yellow index | | 8.0 | 3.2 | 6.1 | 7.0 | 48.1 | 131.1 | 9.2 | 90.8 |
| Tg | ° C. | > 450 | 392 | > 450 | > 450 | > 450 | > 450 | > 450 | > 450 |
| CTE | ppm/K | 26 | 33 | 11 | 17 | 25 | 40 | 6 | 4 |
| Tensile product | MPa · % | 1512 | 628 | 1266 | 664 | Un- | Un- | 948 | 2964 |
| Strength at break | MPa | 189 | 157 | 211 | 166 | measurable | measurable | 237 | 247 |
| Elongation at break | % | 8 | 4 | 6 | 4 | (brittle) | (brittle) | 4 | 12 |
| Tensile modulus | GPa | 6.7 | 5.3 | 8.3 | 6.8 | | | 7.8 | 7.7 |

| | | | | | | | | |
|---|---|---|---|---|---|---|---|---|
| Coefficient of | 1.5 | 2.7 | 2.6 | 2.2 | — | — | 2.5 | 2.4 |
| static friction | | | | | | | | |

As presented in Table 1, it can be seen that the polyimide films containing SQ1 at 1 mol % in the structure (Examples 1, 2, 3a, and 4) have approximately the same total light transmittance, haze, yellow index, Tg, and CTE, a lower coefficient of static friction, and an increased tensile product compared with the polyimide films (Comparative Examples 1, 2, 6, and 9) having the same composition except that SQ1 is not contained.

Comparing Example 2, Comparative Example 3, Comparative Example 4, and Comparative Example 5, in a case where SQ-109 not having an acid anhydride group was mixed instead of SQ1 having an acid anhydride group at the terminal, cloudiness of the polyamic acid solution and polyimide film was observed as the amount of SQ-109 added was increased to 1%, 15%, and 50%. In a case where SQ-109 was mixed, the increase in tensile product was not observed, and the film became more brittle as the amount of SQ-109 added was increased. The polyimide film having an amount of SQ-109 added of 1% had a higher coefficient of static friction than the polyimide film not containing SQ-109 (see Example 2 and Comparative Example 3).

Comparing Examples 3a to 3e with Comparative Example 6, Examples 3a to 3e had a lower coefficient of static friction and also an improved tensile product compared with Comparative Example 6.

### Application Example 1

A dispersion obtained by dispersing colloidal silica as a lubricant in NMP (“SNOWTEX (registered trademark) NMP-ST-ZL” manufactured by Nissan Chemical Corporation) was added to the solution of Example Ca so that the colloidal silica (lubricant) was 0.3% by mass of the total amount of polymer solids in the polyamic acid solution, and stirring was performed at room temperature for 24 hours. This was used as the Example Ca2 solution.

Next, the Example Ca2 solution was applied onto the lubricant-free surface of polyethylene terephthalate film A4100 (manufactured by TOYOBO CO., LTD.) using a comma coater so that the final film thickness was 1.5 μm. Subsequently, the Example Ca solution was applied onto the Example Ca2 solution using a die coater so that the final film thickness was 22 μm. This was dried at 110° C. for 10 minutes. The polyamic acid film that gained self-supporting properties after drying was peeled off from the A4100 film that had served as a support, allowed to pass through a pin tenter with a pin sheet having pins disposed, and gripped by inserting the film edges into the pins, the pin sheet interval was adjusted so that the film did not break and unnecessary slackening did not occur, and the film was transported and heated at 200° C. for 3 minutes, at 250° C. for 3 minutes, at 300° C. for 3 minutes, and at 400° C. for 3 minutes to conduct the imidization reaction. Thereafter, the film was cooled to room temperature for 2 minutes, the portions exhibiting poor flatness at both ends of the film were cut off using a slitter, and the film was wound into a roll shape, thereby obtaining a polyimide film A1 having a width of 450 mm by 500 m.

### Application Example 2

First, the polyimide film obtained in Example 3a (PMDA/TFMB/SQ1) was cut into a rectangle of 360 mm×460 mm. Next, UV/O₃ irradiation was performed for 3 minutes using a UV/O₃ irradiator (SKR1102N-03 manufactured by LANTECHNICAL SERVICE CO., LTD.) as a film surface treatment. At this time, the distance between the UV/O₃ lamp and the film was set to 30 mm.

Display glass (370 mm×470 mm, 0.7 mm thick glass substrate: OA10G manufactured by Nippon Electric Glass Co., Ltd.) was coated with 3-aminopropyltrimethoxysilane (KBM-903 manufactured by Shin-Etsu Chemical Co., Ltd.) as a silane coupling agent using a spray coater. The glass substrate used was washed with pure water, dried, and then irradiated using a UV/O₃ irradiator (SKR1102N-03 manufactured by LANTECHNICAL SERVICE CO., LTD.) for 1 minute for dry cleaning.

Next, the glass substrate coated with a silane coupling agent was set in a roll laminator equipped with a silicone rubber roller. First, 500 ml of pure water was dropped onto the silane coupling agent-coated surface using a dropper so as to spread over the entire substrate, thereby wetting the substrate.

The treated surface of the polyimide film subjected to surface treatment was stacked on the substrate so as to face the silane coupling agent-coated surface of the glass substrate, that is, the surface wetted with pure water, and the stacked body was pressurized while pure water between the polyimide film and the glass substrate was extruded using a rotating roll sequentially from one side of the glass substrate to laminate the glass substrate and the polyimide film, thereby obtaining a temporary laminated body. The laminator used was a laminator having an effective roll width of 650 mm (manufactured by MCK CO., LTD.), and the bonding conditions were: air source pressure: 0.5 MPa, laminating speed: 50 mm/sec, roll temperature: 22° C., environmental temperature: 22° C., and humidity: 55% RH.

The obtained temporary laminated body was subjected to heat treatment at 200° C. for 10 minutes in a clean oven to obtain the laminated body consisting of a polyimide film and a glass substrate.

A tungsten film (film thickness 75 nm) was formed on the polyimide film surface of the obtained laminated body by the following steps, and further a silicon oxide film (thickness 150 nm) as an insulating film was laminated and formed thereon without touching the air. Next, a silicon oxide nitride film (thickness 100 nm) to be the ground insulating film was formed by the plasma CVD method, and further an amorphous silicon film (thickness 54 nm) was laminated and formed without touching the air.

A TFT device was fabricated using the obtained amorphous silicon film. First, patterning of the amorphous silicon thin film was performed to form a silicon region having a predetermined shape, as appropriate, a gate insulating film was formed, a gate electrode was formed, a source region or a drain region was formed by doping the active region, the interlayer insulating film was formed, the source electrode and drain electrode were formed, and the activation treatment was performed, thereby fabricating a P-channel TFT array.

The polyimide film portion was burned off by a UV-YAG laser along about 0.5 mm inner side of the TFT array periphery, and the polyimide film was peeled off from the end of the cut using a thin razor-shaped blade so as to scoop up, thereby obtaining a flexible A3 size TFT array. The peeling was possible by extremely weak force, and it was possible to peel off the TFT array without damaging the TFT. The obtained flexible TFT array did not show any deterioration in performance even when wound around a 5 mmφ round bar, and maintained favorable properties.

### Examples 11 and Onwards and Comparative Examples 11 and Onwards

Next, Examples 11 and onwards and Comparative Examples 11 and onwards will be described. Specifically, with regard to these, the synthesis of silsesquioxane compounds, the synthesis of the polyamic acid solutions, the formation of polyimide films, various evaluation results, and the like will be described.

### [Obtaining of Acid Anhydride Group-Containing Double-Decker Silsesquioxane Derivative 1 (Hereinafter Referred to as “AASQ1”)]

As the acid anhydride group-containing double-decker silsesquioxane derivative 1 (namely, AASQ1), DDSQ manufactured by Japan Material Technologies Corporation was obtained. DDSQ, that is, AASQ1, is a powdered product.

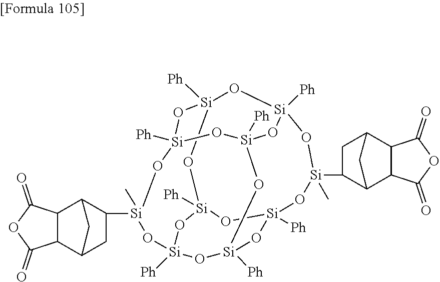 [SMILES: C[Si]1(C2CC3CC2C2C(=O)OC(=O)C32)O[Si]2(c3ccccc3)O[Si]3(c4ccccc4)O[Si]4(c5ccccc5)O[Si](c5ccccc5)(O[Si]5(c6ccccc6)O[Si](c6ccccc6)(O2)O[Si](c2ccccc2)(O3)O[Si](C)(C2CC3CC2C2C(=O)OC(=O)C32)O[Si](c2ccccc2)(O4)O5)O1]

### [Synthesis of Amino Group-Containing Double-Decker Silsesquioxane Derivative 1 (Hereinafter Referred to as “AMSQ1”)]

The amino group-containing double-decker silsesquioxane derivative 1 (namely, AMSQ1) represented by the following structure was produced by the method described in JP-A-2006-265243.

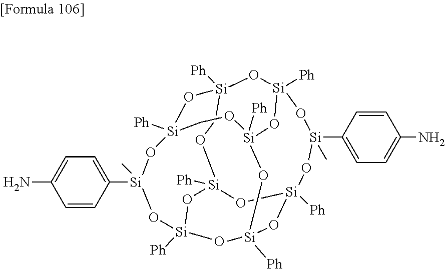 [SMILES: C[Si]1(c2ccc(N)cc2)O[Si]2(c3ccccc3)CO[Si]3(c4ccccc4)O[Si]4(c5ccccc5)O[Si](C)(c5ccc(N)cc5)O[Si]5(c6ccccc6)O[Si](c6ccccc6)(OC[Si](c6ccccc6)(O2)O4)O[Si](c2ccccc2)(O1)O[Si](c1ccccc1)(O3)O5]

### [Synthesis of Acid Anhydride Group-Containing Double-Decker Silsesquioxane Derivative 2 (Hereinafter Referred to as “AASQ2”)]

A reaction vessel was charged with 0.535 g (0.500 mmol) of a compound in which all Z1 are hydrogen atoms and all R¹ are phenyl groups in General Formula AA-D2 and THF (15 mL), and stirring was performed at room temperature to dissolve the compound. To this solution, 0.421 g (2.0 mmol) of trimellitic anhydride chloride was slowly added. This was stirred at room temperature for 3 hours to obtain a reaction solution. This reaction solution was concentrated under reduced pressure, and the residue was dried at 120° C. in a vacuum to remove unreacted trimellitic anhydride chloride. By NMR and IR measurement, it was confirmed that the desired reaction had taken place. By this procedure, an acid anhydride group-containing double-decker silsesquioxane derivative 2 (namely, AASQ2) was obtained.

### [Synthesis of Acid Anhydride Group-Containing Corner-Open Silsesquioxane Derivative 3 (Hereinafter Referred to as “YAASQ3”)

A reaction vessel was charged with 0.466 g (0.500 mmol) of a compound (SO1458 manufactured by Hybrid Plastics) in which all Z¹ are hydrogen atoms and all R¹ are phenyl groups in General Formula AA-C1 and THF (15 mL), and stirring was performed at room temperature to dissolve the compound. To this solution, 0.316 g (1.5 mmol) of trimellitic anhydride chloride was slowly added. This was stirred at room temperature for 3 hours to obtain a reaction solution. This reaction solution was concentrated under reduced pressure, and the residue was dried at 120° C. in a vacuum to remove unreacted trimellitic anhydride chloride. By NMR and IR measurement, it was confirmed that the desired reaction had taken place. By this procedure, an acid anhydride group-containing corner-open silsesquioxane derivative 3 (namely, AASQ3) was obtained.

### [Synthesis of Polyamic Acid Solution A-1]

While nitrogen was allowed to pass through a reactor equipped with a nitrogen inlet tube and a stirrer, 1,2,3,4-cyclobutanetetracarboxylic dianhydride (CBDA, 3.922 g) and 4,4′-diamino-2,2′-bis(trifluoromethyl)biphenyl (TFMB, 6.405 g) were charged, dissolved in N,N-dimethylacetamide (DMAc, 80 ml), and then stirred at 25° C. for 18 hours, thereby obtaining a polyamic acid solution A-1 (molar ratio of CBDA/TFMB=1.00/1.00). In other words, according to the composition presented in Table 2, the polyamic acid solution A-1 was synthesized.

### [Synthesis of Polyamic Acid Solution A-2]

While nitrogen was allowed to pass through a reactor equipped with a nitrogen inlet tube and a stirrer, 1,2,3,4-cyclobutanetetracarboxylic dianhydride (CBDA, 1.961 g), 4,4′-diamino-2,2′-bis(trifluoromethyl)biphenyl (TFMB, 3.268 g), and AASQ1 (0.303 g) were charged, dissolved in γ-butyrolactone (γBL, 32 ml), and then stirred at 25° C. for 18 hours, thereby obtaining a polyamic acid solution A-2 (molar ratio of CBDA/AASQ1/TFMB=0.98/0.02/1.00). In other words, according to the composition presented in Table 2, the polyamic acid solution A-2 was synthesized.

### [Synthesis of Polyamic Acid Solution A-3]

A polyamic acid solution A-3 was prepared according to the composition presented in Table 2 by the same procedure as in the synthesis of the polyamic acid solution A-2.

### [Synthesis of Polyamic Acid Solution B-1]

While nitrogen was allowed to pass through a reactor equipped with a nitrogen inlet tube and a stirrer, 1,2,3,4-cyclobutanetetracarboxylic dianhydride (CBDA, 7.844 g) and 4,4′-diaminobenzanilide (DABA, 8.954 g) were charged, dissolved in N,N-dimethylacetamide (DMAc, 151 ml), and then stirred at 25° C. for 24 hours, thereby obtaining a polyamic acid solution B-1 (molar ratio of CBDA/DABA=1.00/0.985). In other words, according to the composition presented in Table 2, the polyamic acid solution B-1 was synthesized. Incidentally, 8.954 g of DABA is 98.5 mmol of DABA in terms of moles. With regard to this, in a preliminary experiment, a polyamic acid solution synthesized by adding 100 mmol of DABA and 100 mmol of CBDA became a highly viscous solution that was not suitable for film formation, and therefore, the amount of DABA was set to 98.5 mmol when the polyamic acid solution B-1 was synthesized.

### [Synthesis of Polyamic Acid Solution B-2]

While nitrogen was allowed to pass through a reactor equipped with a nitrogen inlet tube and a stirrer, 1,2,3,4-cyclobutanetetracarboxylic dianhydride (CBDA, 2.942 g), 4,4′-diaminobenzanilide (DABA, 3.588 g), and AASQ1 (1.170 g) were charged, dissolved in N,N-dimethylacetamide (DMAc, 53 ml), and then stirred at 25° C. for 24 hours, thereby obtaining a polyamic acid solution B-1 (molar ratio of CBDA/AASQ1/DABA=0.95/0.05/1.00). In other words, according to the composition presented in Table 2, the polyamic acid solution B-2 was synthesized.

### [Synthesis of Polyamic Acid Solution C-1]

While nitrogen was allowed to pass through a reactor equipped with a nitrogen inlet tube and a stirrer, pyromellitic dianhydride (PMDA, 4.362 g) and 4,4′-diamino-2,2′-bis(trifluoromethyl)biphenyl (TFMB, 6.405 g) were charged, dissolved in N-methyl-2-pyrrolidone (M4P, 164 ml), and then stirred at 25° C. for 24 hours, thereby obtaining a polyamic acid solution C-1 (molar ratio of PMDA/TFMB=1.00/1.00). In other words, according to the composition presented in Table 3, the polyamic acid solution C-1 was synthesized.

### [Synthesis of Polyamic Acid Solution C-2]

While nitrogen was allowed to pass through a reactor equipped with a nitrogen inlet tube and a stirrer, pyromellitic dianhydride (PMDA, 3.272 g), 4,4′-diamino-2,2′-bis(trifluoromethyl)biphenyl (TFMB, 4.902 g), and AASQ1 (0.454 g) were charged, dissolved in N-methyl-2-pyrrolidone (M4P, 52 ml), and then stirred at 25° C. for 24 hours, thereby obtaining a polyamic acid solution C-2 (molar ratio of PMDA/AASQ1/TFMB=0.98/0.02/1.00). In other words, according to the composition presented in Table 3, the polyamic acid solution C-2 was synthesized.

### [Synthesis of Polyamic Acid Solution C-3]

While nitrogen was allowed to pass through a reactor equipped with a nitrogen inlet tube and a stirrer, pyromellitic dianhydride (PMDA, 3.272 g), 4,4′-diamino-2,2′-bis(trifluoromethyl)biphenyl (TFMB, 4.708 g), and AMSQ1 (0.401 g) were charged, dissolved in N-methyl-2-pyrrolidone (M4P, 67 ml), and then stirred at 25° C. for 24 hours, thereby obtaining a polyamic acid solution C-3 (molar ratio of PMDA/AMSQ1/TFMB=1.00/0.02/0.98). In other words, according to the composition presented in Table 3, the polyamic acid solution C-3 was synthesized.

[Synthesis of polyamic acid solution C-4]A polyamic acid solution C-4 was synthesized according to the composition presented in Table 3 by the same procedure as in the synthesis of the polyamic acid solution C-3.

### [Synthesis of Polyamic Acid Solution C-5]

A polyamic acid solution C-5 was synthesized according to the composition presented in Table 3 by the same procedure as in the synthesis of the polyamic acid solution C-3.

### [Synthesis of Polyamic Acid Solution C-6]

While nitrogen was allowed to pass through a reactor equipped with a nitrogen inlet tube and a stirrer, pyromellitic dianhydride (PMDA, 1.42 g), 4,4′-diamino-2,2′-bis(trifluoromethyl)biphenyl (TFMB, 2.12 g), and AASQ2 (0.117 g) were charged, dissolved in N-methyl-2-pyrrolidone (M4P, 30 g), and then stirred at 25° C. for 24 hours, thereby obtaining a polyamic acid solution C-6 (molar ratio of PMDA/AASQ2/TFMB=0.98/0.01/1.00). In other words, according to the composition presented in Table 3, the polyamic acid solution C-6 was synthesized.

### [Synthesis of Polyamic Acid Solution C-7]

While nitrogen was allowed to pass through a reactor equipped with a nitrogen inlet tube and a stirrer, pyromellitic dianhydride (PMDA, 1.64 g), 4,4′-diamino-2,2′-bis(trifluoromethyl)biphenyl (TFMB, 2.45 g), and AASQ3 (0.196 g) were charged, dissolved in N-methyl-2-pyrrolidone (M4P, 19 g), and then stirred at 25° C. for 24 hours, thereby obtaining a polyamic acid solution C-6 (molar ratio of PMDA/AASQ3/TFMB=0.98/0.02/1.00). In other words, according to the composition presented in Table 3, the polyamic acid solution C-7 was synthesized.

### [Preparation of Polyamic Acid Solution C-8]

While nitrogen was allowed to pass through a reactor equipped with a nitrogen inlet tube and a stirrer, 2,2′-bis(trifluoromethyl)benzidine (TFMB, 6.40 g), AMSQ1 (0.55 g), pyromellitic dianhydride (PMDA, 2.66 g), and 3,3′,4,4′-biphenyltetracarboxylic acid (BPDA, 2.39 g) were added as solids, then dissolved in N-methyl-2-pyrrolidone (M4P, 77.4 g), and then stirred at 25° C. for 24 hours, thereby obtaining a polyamic acid solution C-8 (molar ratio of TFMB/AMSQ1/PMDA/BPDA=0.98/0.02/0.60/0.40). In other words, according to the composition presented in Table 3, the polyamic acid solution C-8 was synthesized.

### [Preparation of Polyamic Acid Solution C-9]

While nitrogen was allowed to pass through a reactor equipped with a nitrogen inlet tube and a stirrer, 2,2′-bis(trifluoromethyl)benzidine (TFMB, 6.40 g), AMSQ1 (0.55 g), pyromellitic dianhydride (PMDA, 2.66 g), and 3,3′,4,4′-biphenyltetracarboxylic acid (BPDA, 2.39 g) were added as solids, then dissolved in N,N-Dimethylacetamide (DMAc, 68.10 g), and then stirred at 25° C. for 24 hours, thereby obtaining a polyamic acid solution C-9 (molar ratio of TFMB/AMSQ1/PMDA/BPDA=0.98/0.02/0.60/0.40). In other words, according to the composition presented in Table 3, the polyamic acid solution C-9 was synthesized.

### [Preparation of Polyamic Acid Solution C-10]

While nitrogen was allowed to pass through a reactor equipped with a nitrogen inlet tube and a stirrer, 2,2′-bis(trifluoromethyl)benzidine (TFMB, 6.40 g), AMSQ1 (0.55 g), pyromellitic dianhydride (PMDA, 2.66 g), and 3,3′,4,4′-biphenyltetracarboxylic acid (BPDA, 2.39 g) were added as solids, then dissolved in N,N-Dimethylacetamide (DMAc, 68.10 g), and then stirred at 25° C. for 24 hours, thereby obtaining a polyamic acid solution C-9 (molar ratio of TFMB/AMSQ1/PMDA/BPDA=0.98/0.02/0.60/0.40). A solution prepared by dispersing amorphous silica fine particles (lubricant) having an average particle size of 2.7 μm in N,N-dimethylacetamide was added to the polyamic acid solution C-9 so that the lubricant was 200 ppm by mass with respect to the polyamic acid, thereby obtaining a lubricant-containing polyamic acid solution. In other words, according to the composition presented in Table 3, the polyamic acid solution C-10 was synthesized.

### [Preparation of Polyamic Acid Solution C-11]

While nitrogen was allowed to pass through a reactor equipped with a nitrogen inlet tube and a stirrer, 2,2′-bis(trifluoromethyl)benzidine (TFMB, 5.88 g), AMSQ1 (2.75 g), pyromellitic dianhydride (PMDA, 2.66 g), and 3,3′,4,4′-biphenyltetracarboxylic acid (BPDA, 2.39 g) were added as solids, then dissolved in N,N-Dimethylacetamide (DMAc, 68.10 g), and then stirred at 25° C. for 24 hours, thereby obtaining a polyamic acid solution C-11 (molar ratio of TFMB/AMSQ1/PMDA/BPDA=0.90/0.10/0.60/0.40). In other words, according to the composition presented in Table 3, the polyamic acid solution C-11 was synthesized.

Using these polyamic acid solutions, polyimide films were formed by the following method, and the coefficient of static friction, optical properties, thermal properties, and mechanical properties of the polyimide films were measured.

### Comparative Example 11

The polyamic acid solution A-1 was applied onto a polyester film (A4100, Toyobo product) using a casting applicator, and the polyamic acid solution on the polyester film was heated under predetermined conditions (specifically, GF1 described later). The green film obtained by this heating was cut with a cutter, peeled off from the polyester film, and fixed to a metal frame. The green film fixed to the metal frame was heated under predetermined conditions (specifically, B1 described later) to conduct thermal imidization. After cooling, the film was detached from the metal frame to obtain a polyimide film.

### Examples 11 to 27 and Comparative Examples 12 to 14

Polyimide films were obtained in the same manner as in Example 1, except that the polyamic acid solutions presented in Tables 2 and 3 were used instead of the polyamic acid solution A-1, the polyamic acid solutions were heated under the GF preparation conditions presented in Tables 2 and 3, and the green films were heated under the firing conditions presented in Tables 2 and 3.

### Example 28

The polyamic acid solution C-2 was applied onto a polyester film (A4100, Toyobo product) using a comma coater, and the polyamic acid solution on the polyester film was heated under predetermined conditions (specifically, GF3 described later). The green film obtained by this heating was cut with a cutter, peeled off from the polyester film, and fixed with Kapton tape to a frame cut out of Xenomax (registered trademark) film (manufactured by Xenomax Japan Co., Ltd.). The green film fixed to the metal frame was heated under predetermined conditions (specifically, B3 described later) to conduct thermal imidization. After cooling, the film was detached from the frame to obtain a polyimide film.

TABLE 2

| | | | Comparative | | | Comparative | |
|---|---|---|---|---|---|---|---|
| | | | Example 11 | Example 11 | Example 12 | Example 12 | Example 13 |
| Polyamic acid solution | | | A-1 | A-2 | A-3 | B-1 | B-2 |
| Properties | Charged mol % of | CBDA | 100 | 98 | 95 | 100 | 95 |
| | acid component | PMDA | — | — | — | — | — |
| | Charged mol % of | TFMB | 100 | 100 | 100 | — | — |
| | diamine component | DABA | — | — | — | 98.5 | 100 |
| | Charged mol % of | AASQ1 | — | 2 | 5 | — | 5 |
| | silsesquioxane | AMSQ1 | — | — | — | — | — |
| | Solvent | | DMAc | γBL | γBL | DMAc | DMAc |
| GF preparation condition | | | GF1 | GF1 | GF1 | GF2 | GF2 |
| Firing condition | | | B1 | B1 | B1 | B1 | B1 |
| Properties | Film thickness | μm | 14 | 20 | 15 | 15 | 9 |
| | Total light | % | 89.8 | 89.6 | 90.4 | 86.2 | 86.7 |
| | transmittance | | | | | | |
| | Haze | % | 0.25 | 0.40 | 0.34 | 0.26 | 0.23 |
| | Yellow index | | 3.2 | 4.6 | 2.6 | 6.1 | 6.9 |
| | Rth | nm | 660 | 358 | 217 | 1500 | 1061 |
| | Td1 | ° C. | 414 | 398 | 405 | 427 | 424 |
| | Tg | ° C. | 392 | 388 | 380 | 359 | 352 |
| | CTE | ppm/K | 33 | 45 | 49 | 11 | 28 |
| | Tensile product | MPa · % | 188 | 382 | 360 | 692 | 956 |
| | Strength at break | MPa | 157 | 109 | 90 | 182 | 121 |
| | Elongation at break | % | 1.2 | 3.5 | 4.0 | 3.8 | 7.9 |
| | Tensile modulus | GPa | 5.4 | 4.6 | 3.6 | 7.9 | 4.6 |

| | | | | | |
|---|---|---|---|---|---|
| Coefficient of static friction | 2.7 | 1.7 | 1.4 | 2.6 | 1.0 |

TABLE 3

| | | | Com- | Com- | | | | | Exam- | Exam- | Exam- |
|---|---|---|---|---|---|---|---|---|---|---|---|
| | | | parative | parative | Example | Example | Example | Example | ple | ple | ple |
| | | | Example 13 | Example 14 | 14 | 15 | 16 | 17 | 18 | 19 | 20 |
| Polyamic acid solution | | | C-1 | C-1 | C-2 | C-2 | C-3 | C-3 | C-4 | C-4 | C-5 |
| Properties | Charged mol % | CBDA | — | — | — | — | — | — | — | — | — |
| | of acid | PMDA | 100 | 100 | 98 | 98 | 100 | 100 | 100 | 100 | 100 |
| | component | BPDA | | | | | | | | | |
| | Charged mol % | TFMB | 100 | 100 | 100 | 100 | 98 | 98 | 90 | 90 | 80 |
| | of diamine | DABA | — | — | — | — | — | — | — | — | 1 |
| | component | | | | | | | | | | |
| | Charged mol % | AASQ1 | — | — | 2 | 2 | — | — | — | — | — |
| | of | AMSQ1 | — | — | — | — | 2 | 2 | 10 | 10 | 20 |
| | silsesquioxane | AASQ2 | — | — | — | — | — | — | — | — | — |
| | | AASQ3 | — | — | — | — | — | — | — | — | — |
| | Solvent | | NMP | NMP | NMP | NMP | NMP | NMP | NMP | NMP | NMP |
| | Silica particles | Mass ppm | | | | | | | | | |
| GF preparation condition | | | GF1 | GF1 | GF1 | GF1 | GF1 | GF1 | GF1 | GF1 | GF1 |
| Firing condition | | | B1 | B2 | B1 | B2 | B1 | B2 | B1 | B2 | B1 |
| Properties | Film thickness | μm | 6 | 5 | 23 | 21 | 20 | 16 | 18 | 15 | 15 |
| | Total light | % | 86.6 | 85.3 | 84.5 | 71.5 | 85.4 | 84.5 | 87.8 | 86.5 | 87.9 |
| | transmittance | | | | | | | | | | |
| | Haze | % | 0.23 | 0.39 | 0.27 | 0.48 | 0.28 | 0.67 | 0.23 | 0.22 | 0.20 |
| | Yellow index | | 7.6 | 11.3 | 17.8 | 51.7 | 13.6 | 17.9 | 7.9 | 11.8 | 10.1 |
| | Rth | nm | 1952 | — | 1623 | — | 1733 | 1989 | — | — | — |
| | Td₁ | ° C. | 531 | — | 519 | — | 545 | — | — | — | — |
| | Tg | ° C. | > 450 | > 450 | > 450 | > 450 | > 450 | > 450 | > 450 | > 450 | — |
| | CTE | ppm/K | −5 | −6 | 2 | 2 | 4 | 0.2 | 11 | 13 | Un-mea- |
| | | | | | | | | | | | surable |
| | Tensile product | MPa · % | 720 | 2700 | 2111 | 4409 | 1581 | 5217 | 210 | 6 | — |
| | Strength at break | MPa | 200 | 300 | 232 | 292 | 236 | 279 | 100 | 14 | — |
| | Elongation | % | 3.6 | 9.0 | 9.1 | 15.1 | 6.7 | 18.7 | 2.1 | 0.4 | — |
| | at break | | | | | | | | | | |
| | Tensile modulus | GPa | 7.3 | 9.0 | 8.0 | 7.1 | 8.2 | 7.7 | 6.4 | — | — |
| Coefficient of | | | 2.5 | 2.5 | 1.7 | 1.7 | 1.6 | 1.6 | 1.0 | 1.0 | 0.8 |
| static friction | | | | | | | | | | | |
| | | | | | | | | | Exam- | Exam- | |
| | | | Example | Example | Example | Example | Example | Example | ple | ple | |
| | | | 21 | 22 | 23 | 24 | 25 | 26 | 27 | 28 | |
| Polyamic acid solution | | | C-5 | C-6 | C-7 | C-8 | C-9 | C-10 | C-11 | C-2 | |
| Properties | Charged mol % | CBDA | — | — | — | — | — | — | — | — | |
| | of | PMDA | 100 | 98 | 98 | 60 | 60 | 60 | 60 | 98 | |
| | acid component | BPDA | | | | 40 | 40 | 40 | 40 | | |
| | Charged mol % | TFMB | 80 | 100 | 100 | 98 | 98 | 98 | 90 | 100 | |
| | of diamine | DABA | — | — | — | — | — | — | — | — | |
| | component | | | | | | | | | | |
| | Charged mol % | AASQ1 | — | — | — | — | — | — | — | 2 | |
| | of | AMSQ1 | 20 | — | — | 2 | 2 | 2 | 10 | 1 | |
| | silsesquioxane | AASQ2 | — | — | — | — | — | — | — | 1 | |
| | | AASQ3 | — | — | 2 | — | — | — | — | — | |
| | Solvent | | NMP | NMP | NMP | NMP | DMAC | DMAC | DMAC | NMP | |
| | Silica particles | Mass ppm | | | | | | 200 | | | |
| GF preparation condition | | | GF1 | GF1 | GF1 | GF1 | GF1 | GF1 | GF1 | GF3 | |
| Firing condition | | | B2 | B2 | B2 | B1 | B1 | B1 | B1 | B3 | |
| Properties | Film thickness | μm | 12 | 21 | 17 | 18 | 15 | 16 | 15 | 19 | |
| | Total light | % | 85.2 | 84.5 | 84.4 | 87.0 | 87.0 | 87.0 | 87.0 | 85.0 | |
| | transmittance | | | | | | | | | | |
| | Haze | % | 0.47 | 0.41 | 0.43 | 0.28 | 0.30 | 0.35 | 0.30 | 0.44 | |
| | Yellow index | | 21.7 | 26.0 | 23.0 | 7.6 | 7.0 | 7.2 | 8.0 | 14.0 | |
| | Rth | nm | — | — | — | — | — | — | — | — | |
| | Td₁ | ° C. | — | 528 | 541 | 532 | 533 | 533 | 530 | 521 | |
| | Tg | ° C. | — | > 450 | > 450 | 420 | 420 | 420 | 420 | > 450 | |
| | CTE | ppm/K | Unmeasurable | 5 | −1 | 11 | 12 | 13 | 22 | 7 | |
| | Tensile product | MPa · % | — | 4216 | 4438 | — | 1 | — | — | 12638 | |
| | Strength at break | MPa | — | 317 | 292 | 218 | 229 | 229 | 250 | 354 | |
| | Elongation | % | — | 13.3 | 15.2 | 13.8 | 14.2 | 14.0 | 18.0 | 35.7 | |
| | at break | | | | | | | | | | |
| | Tensile modulus | GPa | — | 9.3 | 8.8 | 6.7 | 6.7 | 6.8 | 6.0 | 8.6 | |
| Coefficient of | | | 0.8 | 1.9 | 1.5 | 1.5 | 1.5 | 0.9 | 1.0 | 1.5 | |
| static friction | | | | | | | | | | | |

In these tables, GF1, GF2 and GF3 are the heating conditions to form the green films. GF1 indicates that the polyamic acid solution on the polyester film was heated at 100° C. for 18 minutes in a nitrogen atmosphere. Meanwhile, GF2 indicates that the polyamic acid solution on the polyester film was heated at 100° C. for 20 minutes in a nitrogen atmosphere. GF3 indicates that the polyamic acid solution on the polyester film was heated at 120° C. for 12 minutes in the air.

B1, B2 and B3 are the firing conditions of the green films. The green film can be thermally imidized under any of B1, B2 or B3. B1 indicates that the green film was heated sequentially at 200° C. for 10 minutes, at 250° C. for 10 minutes, at 300° C. for 10 minutes, and at 350° C. for 10 minutes while the temperature was gradually increased at a rate of 10° C./min in a nitrogen atmosphere. Meanwhile, B2 indicates that the green film was heated sequentially at 300° C. for 60 minutes and at 400° C. for 30 minutes while the temperature was gradually increased at a rate of 10° C./min in a nitrogen atmosphere. B3 indicates that the green film was heated sequentially in a furnace at 220° C. for 3 minutes, in a furnace at 270° C. for 3 minutes, in a furnace at 320° C. for 3 minutes, and in a furnace at 370° C. for 3 minutes in the air.

In these tables, “-” in the cell presenting a property indicates that the property was not measured. In the cell presenting a property (for example, CTE in Example 20) of which the measurement was impossible, “unmeasurable” is noted.

As presented in Table 2, in the composition system of CBDA and TFMB, the polyimide film containing AASQ1 at 2 mol % in the structure (Example 11) and the polyimide film containing AASQ1 at 5 mol % in the structure (Example 12) had approximately the same total light transmittance, haze, yellow index, Rth, Tdᵢ(namely, thermal decomposition temperature), Tg, and CTE, a lower coefficient of static friction, and a superior tensile product compared with the polyimide film not containing AASQ1 (Comparative Example 11). Among these properties, with regard to CTE, in the polyimide film containing AASQ1 at 2 mol % in the structure (Example 11) and the polyimide film containing AASQ1 at 5 mol % in the structure (Example 12), CTE tended to increase, but the degree of increase in CTE was an acceptable level (for this reason, in this discussion, CTE is also expressed as being “approximately the same.” The same applies below.) compared with that in the polyimide film not containing AASQ1 (Comparative Example 11).

In the composition system of CBDA and DABA as well, the polyimide film containing AASQ1 at 5 mol % in the structure (Example 13) had approximately the same total light transmittance, haze, yellow index, Rth, Tdᵢ(namely, thermal decomposition temperature), Tg, and CTE, a lower coefficient of static friction, and a superior tensile product compared with the polyimide film not containing AASQ1 (Comparative Example 12).

As presented in Table 3, in the composition system of PMDA and TFMB as well, the polyimide film containing AASQ1 at 2 mol % in the structure (Example 14) had approximately the same total light transmittance, haze, yellow index, Rth, Tdᵢ(namely, thermal decomposition temperature), Tg, and CTE, a lower coefficient of static friction, and a superior tensile product compared with the polyimide film not containing AASQ1 (Comparative Example 13).

In a case where the firing conditions for polyimide films are more severe than B1, specifically in the case of B2, which was set on the assumption that the polyimide film would be exposed to a far higher temperature environment during the TFT array fabricating process, the polyimide film containing AASQ1 at 2 mol % in the structure (Example 15) was inferior in the yellow index but had approximately the same total light transmittance, haze, Rth, Tg, and CTE, a lower coefficient of static friction, and a superior tensile product compared with the polyimide film not containing AASQ1 (Comparative Example 14) Incidentally,
in a case where the firing conditions for polyimide films are B3, which is slightly more severe than B1, the polyimide film containing AASQ1 at 2 mol % in the structure (Example 28) had approximately the same yellow index compared with the polyimide film not containing AASQ1 (Comparative Example 14).

In a case where the firing conditions are B1 or B2 as well, the polyimide containing AMSQ1 at 2 mol % in the structure films (Examples 16 and 17) had approximately the same total light transmittance, haze, yellow index, Rth, Tg, and CTE, a lower coefficient of static friction, and a superior tensile product compared with the polyimide films not containing AMSQ1 (Comparative Examples 13 and 14). With regard to Example 17 and Example 15 subjected to the same firing conditions of B2, AMSQ1 is less susceptible to thermal decomposition than AASQ1, and as a result, it is considered that the increase in yellow index (that is, the deterioration of yellow index) caused by thermal decomposition was suppressed in the polyimide film containing AMSQ1 at 2 mol % in the structure (Example 17) compared with the polyimide film containing AASQ1 at 2 mol % in the structure (Example 15).

Meanwhile, the polyimide films containing AMSQ1 at 10 mol % in the structure (Examples 18 and 19) had a lower elongation at break and were inferior in the tensile product but had a lower coefficient of static friction compared with the polyimide films not containing AMSQ1 (Comparative Examples 13 and 14). Incidentally, in Examples 20 and 21, CTE could not be measured since the films were brittle and broke during the measurement.

As in the case of AASQ1 and AMSQ1, in the case of AASQ2 and AASQ3 as well, the total light transmittance, haze, yellow index, Rth, Tdᵢ(namely, thermal decomposition temperature), Tg, and CTE were maintained, the coefficient of static friction could be decreased, and the tensile product could be improved. Specifically, the polyimide film containing AASQ2 at 1 mol % in the structure (Example 22) had approximately the same total light transmittance, haze, yellow index, Rth, Tdᵢ(namely, thermal decomposition temperature), Tg, and CTE, a lower coefficient of static friction, and a superior tensile product compared with the polyimide film not containing AASQ2 (Comparative Example 14). The polyimide film containing AASQ3 at 2 mol % in the structure (Example 23) had approximately the same total light transmittance, haze, yellow index, Rth, Tdᵢ(namely, thermal decomposition temperature), Tg, and CTE, a lower coefficient of static friction, and a superior tensile product compared with the polyimide film not containing AASQ3 (Comparative Example 14).

### Comparative Example 15: Production of Polyimide Film Roll F1

The polyamic acid solution C-1 was applied onto the lubricant-free surface of polyethylene terephthalate film A4100 (manufactured by TOYOBO CO., LTD.) using a comma coater. This was dried at 100° C. for 18 minutes in a nitrogen atmosphere to obtain a self-supporting film (that is, polyamic acid film). The polyamic acid film was peeled off from the the support (that is, A4100), allowed to pass through a pin tenter with a pin sheet having pins disposed, and gripped by inserting the polyamic acid film ends into the pins, the pin sheet interval was adjusted so that the polyamic acid film did not break and unnecessary slackening did not occur, and the polyamic acid film was transported and sequentially heated at 200° C. for 10 minutes, at 250° C. for 10 minutes, at 300° C. for 10 minutes, and at 350° C. for 10 minutes while the temperature was gradually increased at a rate of 10° C./min in a nitrogen atmosphere to conduct the imidization reaction. Thereafter, the film was cooled to room temperature for 2 minutes, the portions exhibiting poor flatness at both ends of the film were cut off using a slitter, and the film was then wound into a roll shape, thereby obtaining a polyimide film roll F1 having a width of 450 mm by 50 m.

### Examples 29 to 31: Production of Polyimide Film Rolls F2 to F4

Polyimide film rolls F2 to F4 were obtained in the same manner as for the polyimide film F1, except that the polyamic acid solution C-1 was changed to the polyamic acid solutions C-2, C-4 and C-8 in accordance with Table 4.

### Comparative Example 16: Preparation of Sample Si Fired on Glass Substrate (Coating with Spinner)

The polyamic acid solution C-2 was diluted with DMAc to an appropriate concentration and applied onto a glass substrate using a spinner. This was dried at 100° C. for 18 minutes in a nitrogen atmosphere and then further heated sequentially at 200° C. for 10 minutes, 250° C. for 10 minutes, 300° C. for 10 minutes, and 350° C. for 10 minutes while the temperature was gradually increased at a rate of 10° C./min in a nitrogen atmosphere to conduct the imidization reaction. Thereafter, the film was cooled to room temperature for 2 minutes and peeled off from the glass substrate to obtain a sample S1.

### Comparative Example 17: Preparation of Sample S2 Fired on Glass Substrate (Coating with Hand Coater)

The polyamic acid solution C-2 was applied onto a glass substrate using a hand coater, and this was dried at 100° C. for 18 minutes in a nitrogen atmosphere and then further heated sequentially at 200° C. for 10 minutes, 250° C. for 10 minutes, 300° C. for 10 minutes, and 350° C. for 10 minutes while the temperature was gradually increased at a rate of 10° C./min in a nitrogen atmosphere to conduct the imidization reaction. Thereafter, the film was cooled to room temperature for 2 minutes and peeled off from the glass substrate to obtain a sample S2.

TABLE 4

| | | Comparative | Comparative | Comparative | | | |
|---|---|---|---|---|---|---|---|
| | | Example 15 | Example 16 | Example 17 | Example 29 | Example 30 | Example 31 |
| Sample number | | F1 | S1 | S2 | F2 | F3 | F4 |
| Polyamic acid solution | | C-1 | C-2 | C-2 | C-2 | C-4 | C-8 |
| GF preparation condition | | GF1 | GF1 | GF1 | GF1 | GF1 | GF1 |
| Firing condition | | B1 | B1 | B1 | B1 | B1 | B1 |
| Sample shape during firing | | Roll-shaped | Flat | Flat | Roll-shaped | Roll-shaped | Roll-shaped |
| | | | plate-shaped | plate-shaped | | | |
| | | | (spin coating) | (hand coating) | | | |
| Properties | Film thickness μm | 16 | 15 | 22 | 23 | 18 | 15 |
| | Coefficient of static friction | 2.5 | 2.2 | 2.2 | 1.7 | 1.0 | 1.5 |
| | Roll slipperiness | Poor | — | — | Favorable | Favorable | Favorable |

In the polyimide film rolls F2 to F4 formed using the polyamic acid solutions C-2, C-4, and C-8, the coefficient of static friction was lower and the generation of scratches and wrinkles was suppressed compared with those in the polyimide film roll F1 produced using the polyamic acid solution C-1 (see Examples 29 to 31 and Comparative Example 15).

### INDUSTRIAL APPLICABILITY

According to the present invention, a polyimide film having improved easily slipping properties can be provided, and therefore the present invention is industrially applicable.

1. A polyimide film comprising a polyimide obtained through imidization of a polyamic acid that is a copolymerization reaction product of at least a carboxylic acid, a diamine, and a silsesquioxane derivative, wherein a coefficient of static friction is 2.0 or less.

2. The polyimide film according to claim 1, wherein the silsesquioxane derivative has two or more dicarboxylic anhydride groups.

3. The polyimide film according to claim 1, wherein the silsesquioxane derivative has two or more amino groups.

4. The polyimide film according to claim 3, wherein
each of the amino groups has a linking group that links the amino group to Si bonded closest to the amino group among Si's that constitute the silsesquioxane derivative, and
the linking groups each independently have a substituted or unsubstituted aromatic ring that is bonded to the amino group.

5. The polyimide film according to claim 1, wherein the polyamic acid does not have a structural unit derived from 3,3′,4,4′-biphenyltetracarboxylic dianhydride.

6. A laminated body comprising the polyimide film according to claim 1 and an inorganic substrate.

7. A method for producing a flexible electronic device, the method comprising:
a step of forming an electronic device on a polyimide film surface of the laminated body according to claim 6; and
a step of peeling off the inorganic substrate.

8. A flexible electronic device comprising the polyimide film according to claim 1 and an electronic device formed on the polyimide film.

9. The polyimide film according to claim 1, wherein the coefficient of static friction is 0.1 or more and 2.0 or less.

10. The polyimide film according to claim 2, wherein the polyamic acid does not have a structural unit derived from 3,3′,4,4′-biphenyltetracarboxylic dianhydride.

11. A laminated body comprising the polyimide film according to claim 2 and an inorganic substrate.

12. A method for producing a flexible electronic device, the method comprising:
a step of forming an electronic device on a polyimide film surface of the laminated body according to claim 11; and
a step of peeling off the inorganic substrate.

13. A flexible electronic device comprising the polyimide film according to claim 2 and an electronic device formed on the polyimide film.
